(19) United States
(12) Patent Application Publication
(10) Pub. No.: US 2017/0372902 A1
(43) Pub. Date: Dec. 28, 2017

(54) CRYSTAL PRODUCTION SYSTEMS AND METHODS

(71) Applicant: SITEC GMBH, Burghausen (DE)

(72) Inventors: Mark W. Dassel, Indianola, WA (US); Uwe Kerat, Starnberg (DE)

(73) Assignee: SITEC GMBH, Burghausen (DE)

(21) Appl. No.: 15/540,506

(22) PCT Filed: Dec. 23, 2015
(86) PCT No.: PCT/US2015/000293

§ 371 Date: Jun. 28, 2017

Related U.S. Application Data
(60) Provisional application No. 62/097,972, filed on Dec. 30, 2014.

(51) Int. Cl. H01L 21/205; C23C 16/44; H01L 29/04; C23C 16/442; C23C 16/46

(52) U.S. Cl. CPC H01L 21/205; C23C 16/4404; H01L 29/04; C23C 16/4401; C23C 16/4411; C23C 16/46; C23C 16/442

(57) ABSTRACT

Mechanically fluidized systems and processes allow for efficient, cost-effective production of silicon coated particles having very low levels of contaminants such as metals and oxygen. These silicon coated particles are produced, conveyed, and formed into crystals in an environment maintained at a low oxygen level or a very low oxygen level and a low contaminant level or very low contaminant level to minimize the formation of silicon oxides and minimize the deposition of contaminants on the coated particles. Such high purity coated silicon particles may not require classification and may be used in whole or in part in the crystal production method. The crystal production method and the resultant high quality of the silicon boules produced are improved by the reduction or elimination of the silicon oxide layer and contaminants on the coated particles.

### TECHNICAL FIELD

This disclosure generally relates to mechanically fluidized reactors and associated crystal production methods.

### BACKGROUND

Silicon, specifically polysilicon, is a basic material from which a large variety of semiconductor products are made. Silicon forms the foundation of many integrated circuit technologies, as well as photovoltaic transducers. Of particular industry interest is high purity silicon.

Processes for producing polysilicon may be carried out in different types of reaction devices, including chemical vapor deposition reactors and fluidized bed reactors. Various aspects of the chemical vapor deposition (CVD) process, in particular the Siemens or “hot wire” process, have been described, for example in a variety of U.S. patents or published applications (see, e.g., U.S. Pat. Nos. 3,011,877; 3,099,534; 3,147,141; 4,150,168; 4,179,530; 4,311,545; and 5,118,485).

Silane and trichlorosilane are both used as feed materials for the production of polysilicon. Silane is more readily available as a high purity feedstock because it is easier to purify than trichlorosilane. Production of trichlorosilane introduces boron and phosphorus impurities, which are difficult to remove because they tend to have boiling points that are close to the boiling point of trichlorosilane itself. Although both silane and trichlorosilane are used as feedstock in Siemens-type chemical vapor deposition reactors, trichlorosilane is more commonly used in such reactors. Silane, on the other hand, is a more commonly used feedstock for production of polysilicon in fluidized bed reactors.

Silane has drawbacks when used as a feedstock for either chemical vapor deposition or fluidized bed reactors. Producing polysilicon from silane in a Siemens-type chemical vapor deposition reactor may require up to twice the electrical energy compared to producing polysilicon from trichlorosilane in such a reactor. Further, the capital costs are high because a Siemens-type chemical vapor deposition reactor yields only about half as much polysilicon from silane as from trichlorosilane. Thus, any advantages resulting from higher purity of silane are offset by higher capital and operating costs in producing polysilicon from silane in a Siemens-type chemical vapor deposition reactor. This has led to the common use of trichlorosilane as feed material for production of polysilicon in such reactors.

Silane as feedstock for production of polysilicon in a fluidized bed reactor has advantages regarding electrical energy usage compared to production in Siemens-type chemical vapor deposition reactors. However, there are disadvantages that offset the operating cost advantages. In using the fluidized bed reactor, the process itself may result in a lower quality polysilicon product even though the purity of the feedstock is high. For example, polysilicon produced in a fluidized bed reactor may also include metal impurities from the equipment used in providing the fluidized bed due to the typically abrasive conditions found within a fluidized bed. Further, polysilicon dust may be formed, which may interfere with operation by forming ultra-fine particulate material within the reactor and may also decrease the overall yield. Further, polysilicon produced in a fluidized bed reactor may contain residual hydrogen gas, which must be removed by subsequent processing. Thus, although high purity silane may be available, the use of high purity silane as a feedstock for the production of polysilicon in either type of reactor may be limited by the disadvantages noted.

Chemical vapor deposition reactors may be used to convert a first chemical species, present in vapor or gaseous form, to solid material. The deposition may and commonly does involve the conversion or decomposition of the first chemical species to one or more second chemical species, one of which second chemical species is a substantially non-volatile species.

Decomposition and deposition of the second chemical species on a substrate is induced by heating the substrate to a temperature at which the first chemical species decomposes on contact with the substrate to provide one or more of the aforementioned second chemical species, one of which second chemical species is a substantially non-volatile species. Solids so formed and deposited may be in the form of successive annular layers deposited on bulk forms, such as immobile rods, or deposited on mobile substrates, such as beads, grains, or other similar particulate matter chemically and structurally suitable for use as a substrate.

Beads are currently produced, or grown, in a fluidized bed reactor where an accumulation of dust, comprised of the desired product of the decomposition reaction, acting as seeds for additional growth, and pre-formed beads, also comprised of the desired product of the decomposition reaction, are suspended in a gas stream passing through the fluidized bed reactor. Due to the high gas volumes needed to fluidize the bed within a fluidized bed reactor, where the volume of the gas containing the first chemical species is insufficient to fluidize the bed within the reactor, a supplemental fluidizing gas such as an inert or marginally reactive gas is used to provide the gas volume necessary to fluidize the bed. As an inert or only marginally reactive gas, the ratio of the gas containing the first chemical species to the supplemental fluidizing gas may be used to control or otherwise limit the reaction rate within or the product matrix provided by the fluidized bed reactor.

The use of a supplemental fluidizing gas however can increase the size of process equipment and also increases separation and treatment costs to separate any unreacted or decomposed first chemical species present in the gas exiting the fluidized bed reactor from the supplemental gas used within the fluidized bed reactor.

In a conventional fluidized bed reactor, silane and one or more diluents such as hydrogen are used to fluidize the bed. Since the fluidized bed temperature is maintained at a level sufficient to thermally decompose silane, the gases used to fluidize the bed, due to intimate contact with the bed, are necessarily heated to the same bed temperature. For example, silane gas fed to a fluidized bed reactor operating at a temperature exceeding 500° C. is itself heated to its auto-decomposition temperature. This heating causes some of the silane gas to undergo spontaneous thermal decomposition which creates an extremely fine (e.g., having a particle diameter of 0.1 micron or less) silicon powder that is often referred to as “amorphous dust” or “poly-powder.” Silane forming poly-powder instead of the preferred polysilicon deposition on a substrate represents lost yield and unfavorably impacts production economics. The very fine poly-powder is electrostatic and is fairly difficult to separate from product particles for removal from the system. Additionally, if the poly-powder is not separated, off-specification polysilicon granules (i.e., polysilicon granules having a particle size less than the desired diameter of about 1.5 mm) are formed, further eroding yield and further unfavorably impacting production economics.

In some instances, a silane yield loss to poly-powder is on the order of about 1%, but may range from about 0.5% to about 5%. The average poly-powder particle size is typically about 0.1 micron, but can range from about 0.05 microns to about 1 micron. A 1% yield loss can therefore create around 1×10¹⁶ poly-powder particles. Unless these fine poly-powder particles are removed from the fluidized bed, the poly-powder will provide particles having only 1/3,000^{th} of the industry desired diameter of 1.5 mm. Thus the ability to efficiently remove ultra-fine particles from the fluidized bed or from the fluid bed reactor off-gas is important. However, electrostatic forces often hinder filtering the ultra-fine poly-powder from a finished product or fluid bed reactor off-gas. Therefore, processes that minimize or ideally avoid the formation of the ultra-fine poly-powder are quite advantageous.

The silicon coated particles produced in the reactor are typically removed, and packaged for commercial shipment to producers of silicon boules that are used to manufacture a wide variety of semiconductor products. The handling, storage, and shipment of such silicon coated particles exposes the particles to atmospheric oxygen which quickly forms an oxide layer or shell on the exposed surfaces of the particles. This oxide layer adversely impacts the melting process and introduces unacceptable levels of contaminants into the crystal production process. As such, this oxide layer negatively impacts productivity and quality.

### BRIEF SUMMARY

A crystal production method may be summarized as including: separating a plurality of coated particles from a heated particulate bed; and conveying, in an environment having a low oxygen level and a low contaminant level, at least a first portion of the plurality of coated particles separated from the heated particulate bed to a coated particle melter.

Separating a plurality of coated particles from a heated particulate bed may include: fluidizing the heated particulate bed; and overflowing the plurality of coated particles from the fluidized heated particulate bed. Fluidizing the heated particulate bed may include: mechanically fluidizing the heated particulate bed by cyclically oscillating at one or more defined frequencies a retainment volume in which the heated particulate bed is retained through one or more physical displacements. The crystal production method may further include: conveying, in an environment having a low oxygen level, a second portion of the plurality of coated particles removed from the heated particulate bed back to the heated particulate bed. Conveying, in an environment having a low oxygen level, a second portion of the plurality of coated particles removed from the heated particulate bed to the heated particulate bed may include: conveying, in an environment having a low oxygen level, the second portion of the plurality of coated particles removed from the heated particulate bed, the second portion of the plurality of coated particles including coated particles having a dp₅₀ less than or equal to 1000 micrometers (μm). Conveying, in an environment having a low oxygen level, a first portion of the plurality of coated particles removed from the heated particulate bed to a melter may include: conveying, in an environment having a low oxygen level, the first portion of the plurality of coated particles removed from the mechanically fluidized particulate bed to a close coupled melter, the close coupled melter hermetically sealed to a vessel containing the heated particulate bed. Conveying, in an environment having a low oxygen level, a first portion of the plurality of coated particles separated from the heated particulate bed to a coated particle melter may include: conveying the first portion of the plurality of coated particles separated from the mechanically fluidized particulate bed to the coated particle melter via at least one hermetically sealed intermediate vessel that includes an environment having a low oxygen level. Separating a plurality of coated particles from a heated particulate bed may include: separating a plurality of coated particles having an oxide content of less than 50 ppm atomic from the heated particulate bed. The crystal production method may further include: prior to separating the plurality of coated particles from the heated particulate bed: heating the particulate bed to at least a thermal decomposition temperature of a first gaseous chemical species; and thermally decomposing the first gaseous chemical species in the heated particulate bed to provide the plurality of coated particles. The crystal production method may further include: adjusting at least one process condition to alter the conversion of the first gaseous chemical species to the non-volatile second chemical species in the heated particulate bed, the at least one process condition including at least one of: a temperature of the heated particulate bed; a temperature external to the heated particulate bed; a gas pressure within the heated particulate bed; or a flow rate of the first gaseous chemical species to the heated particulate bed. The crystal production method may further include: mixing the first gaseous chemical species with at least one diluent prior to thermally decomposing the first gaseous chemical species in the heated particulate bed to provide the plurality of coated particles; and adjusting at least one process condition to alter the conversion of the first gaseous chemical species to the non-volatile second chemical species in the heated particulate bed, the at least one process condition including at least one of: a temperature of the heated particulate bed; a temperature external to the heated particulate bed; a gas pressure within the heated particulate bed; a flow rate of the first gaseous chemical species to the heated particulate bed; or a ratio of the first gaseous chemical species to the at least one diluent in the mixture. Thermally decomposing the first gaseous chemical species in the heated particulate bed to provide the plurality of coated particles may include: thermally decomposing the first gaseous chemical species in the heated particulate bed to provide a non-volatile second chemical species, at least a portion of which deposits on a surface of the particulates to provide the plurality of coated particles, the second chemical species including at least one of: germanium, compounds containing silicon and germanium, silicon, silicon nanoparticles, silicon carbide, silicon nitride, or aluminum oxide sapphire glass. Heating the particulate bed to at least a thermal decomposition temperature of the first gaseous chemical species may include: disposing the particulate bed in a reaction vessel, the reaction vessel defining a chamber containing the heated particulate bed and an environment external to the heated particulate bed; heating the particulate bed to at least the thermal decomposition temperature of the first gaseous chemical species via one or more heaters thermally coupled to the particulate bed; and maintaining all points in the environment external to the particulate bed at a temperature below the thermal decomposition temperature of the first gaseous chemical species. The crystal production method may further include: causing a temperature of the first portion of the plurality of coated particles separated from the mechanically fluidized particulate bed to exceed a melting temperature of the non-volatile second chemical species to form a reservoir of molten second chemical species. The crystal production method may further include: growing at least one second chemical species crystal using at least a portion of the reservoir of molten second chemical species. Growing at least one second chemical species crystal using at least a portion of the reservoir of molten second chemical species may include: growing at least one monocrystalline second chemical species via a crystal production device that is hermetically sealed to the coated particle melter and operably coupled to the reservoir of molten second chemical species. Growing at least one second chemical species crystal using at least a portion of the reservoir of molten second chemical species may include: growing at least one second chemical species crystal having a silicon oxide content of less than 500 parts per million atomic oxygen. The crystal production method may further include: causing a thermal decomposition and a spontaneous self-nucleation of at least a portion of the first gaseous chemical species in the heated particulate bed to generate a plurality of seed particulates to replace at least a portion of the plurality of coated particles removed from the heated particulate bed. Causing a thermal decomposition and a spontaneous self-nucleation of at least a portion of the first gaseous chemical species in the heated particulate bed to generate a plurality of seed particulates may include: causing a thermal decomposition and a spontaneous self-nucleation of at least a portion of the first gaseous chemical species in the heated particulate bed to generate in situ a plurality of seed particulates having a diameter of less than 600 micrometers (μm). Thermally decomposing the first gaseous chemical species in the heated particulate bed to provide the plurality of coated particles may include: causing the first gaseous chemical species to flow from a first gaseous chemical species reservoir through a flow passage to a number of injectors, each of the injectors having at least one outlet disposed in the heated particulate bed; and causing a discharge of the first gaseous chemical species into the heated particulate bed via the at least one outlet. Causing the first gaseous chemical species to flow from supply first gaseous chemical species reservoir through a flow passage to a number of injectors may include: causing a temperature of the first gaseous chemical species in the flow passage and in each of the number of injectors to remain below the thermal decomposition temperature of the first gaseous chemical species. Thermally decomposing the first gaseous chemical species in the heated particulate bed to provide the plurality of coated particles may include: causing the non-volatile second chemical species generated by the decomposition of the first gaseous chemical species to deposit on at least the portion of the plurality of particulates to provide the plurality of coated particles, wherein each of the plurality of coated particles comprises an accumulation of the second chemical species on a particulate. Thermally decomposing the first gaseous chemical species in the heated particulate bed to provide the plurality of coated particles may include: flowing the first gaseous chemical species through at least a portion of the heated particulate bed using at least one of: a plug flow regime or a transitional flow regime. Conveying a first portion of the plurality of coated particles separated from the heated particulate bed to a coated particle melter may include: conveying the first portion of the plurality of coated particles separated from the heated particulate bed to the coated particle melter, the first portion of the plurality of coated particles having less than 500 parts per million atomic oxygen. The crystal production method may further include: causing a flow of at least one dopant to the heated particulate bed to provide a plurality of doped coated particles. Introducing at least one dopant to the mechanically fluidized particulate bed to provide a plurality of doped coated particles may include: mixing the at least one dopant with the first gaseous chemical species prior to thermally decomposing the first gaseous chemical species in the heated particulate bed. Introducing at least one dopant to the mechanically fluidized particulate bed to provide a plurality of doped coated particles may include: distributing the at least one dopant in the heated particulate bed contemporaneous with the thermal decomposition of the first gaseous chemical species in the heated particulate bed. Conveying a first portion of the plurality of coated particles separated from the heated particulate bed to a coated particle melter may include: collecting the plurality of separated coated particles in a coated particle collector maintained at a low oxygen level; and conveying in a low oxygen environment and at a defined rate, a first portion of the plurality of coated particles separated from the coated particle collector to the coated particle melter. Separating a plurality of coated particles from a heated particulate bed may include: selectively separating a plurality of coated particles having a diameter of greater than about 600 micrometers from the heated particulate bed.

A crystal production system may be summarized as including: a reactor housing that encloses at least one chamber; a pan that includes a major horizontal surface having an upper surface and a lower surface that at least partially defines a retainment volume disposed in the at least one chamber; a transmission that cyclically oscillates the pan at one or more defined frequencies and one or more defined displacements to produce a mechanically fluidized particulate bed in the retainment volume, the mechanically fluidized particulate bed including a plurality of coated particles, each of the plurality of coated particles including a non-volatile second chemical species deposited as a result of a thermal decomposition of a first gaseous chemical species in the mechanically fluidized particulate bed; a hermetically sealed second chemical species crystal production device that, in operation, causes the temperature of a first portion of the plurality of coated particles separated from the mechanically fluidized particulate bed to exceed a melting temperature of the non-volatile second chemical species to form at least one second chemical species crystal; and a hermetically sealed conveyance that couples the chamber to the second chemical species crystal production device such that, in operation, at least the first portion of the plurality of coated particles are conveyed in an environment having a low oxygen level and a low contaminant level from the mechanically fluidized particulate bed to the second chemical species crystal production device.

The second chemical species crystal production device may include a coated particle melter that is operably coupled and hermetically sealed to a coated particle melter. The second chemical species crystal production device may include a Float Zone crystal production device. The pan may include at least one heater thermally conductively coupled to the major horizontal surface of the oscillating pan. The pan may include at least one heat source thermally convectively coupled to the mechanically fluidized particulate bed in the retainment volume. The crystal production system may further include: a cover having an upper surface, a lower surface, and a peripheral edge, the cover disposed above the major horizontal surface of the pan with the peripheral edge of the cover spaced inwardly of a perimeter wall of the pan and a peripheral gap defined between the peripheral edge of the cover and the peripheral wall of the pan, the peripheral gap to, in operation, fluidly coupling the retainment volume to an exterior space about the pan; and a coated particle overflow conduit sealingly coupled to and projecting from the major horizontal surface of the pan, the coated particle overflow conduit to collect via overflow at least a portion of the plurality of coated particles from the mechanically fluidized particulate bed, the coated particle overflow conduit having an inlet and a passage extending therethrough from the inlet to a distal portion of the coated particle overflow conduit, the inlet of the coated particle overflow conduit positioned in the retainment volume. The crystal production system may further include: a plurality of baffles including at least one of: a plurality of baffles extending upward from the upper surface of the major horizontal surface at least partially into the retainment volume or extending downward from the lower surface of the cover at least partially into the retainment volume, each of the plurality of baffles disposed at least partially about the coated particle overflow conduit, spaced outwardly from the coated particle overflow conduit. The crystal production system may further include: a plurality of baffles including a plurality of baffles having a first portion of baffles that extend upward from the upper surface of the major horizontal surface at least partially into the retainment volume alternated with a second portion of baffles that extend downward from the lower surface of the cover at least partially into the retainment volume, the plurality of baffles defining a radial serpentine flow path through the retainment volume. The crystal production system may further include: a first gaseous chemical reservoir and distribution header fluidly coupled to each of a number of injectors, each of the number of injectors having at least one outlet positioned in the retainment volume. The crystal production system may further include: at least one diluent reservoir and distribution header fluidly coupled to the first gaseous chemical species distribution header; and a control system operably coupled to the diluent distribution header to modulate the feed of the at least one diluent to maintain a defined ratio of the feed rate of the first gaseous chemical species to the feed rate of the at least one diluent to the mechanically fluidized particulate bed. The crystal production system may further include: at least one dopant reservoir and distribution header fluidly coupled to mechanically fluidized particulate bed; and a control system operably coupled to the dopant distribution header to modulate the feed of the at least one dopant to maintain a defined ratio of the feed rate of the first gaseous chemical species to the feed rate of the at least one dopant to the mechanically fluidized particulate bed.

A crystal production method may be summarized as including: adjusting at least one of: an oscillatory frequency of a pan having a major horizontal surface that defines at least a portion of a retainment volume disposed in a chamber of a mechanically fluidized bed reactor, or an oscillatory displacement of the pan, the oscillatory displacement having a non-zero magnitude along at least a first axis; separating a plurality of coated particles from the mechanically fluidized particulate bed, each of the plurality of coated particles including a non-volatile second chemical species produced by a thermal decomposition of a first gaseous chemical species in the mechanically fluidized particulate bed; conveying, in an environment having a low oxygen level and a low contaminant level, a first portion of the plurality of coated particles separated from the mechanically fluidized particulate bed to a second chemical species crystal production device.

The crystal production method may further include: conveying in an environment having a low oxygen level and a low contaminant level a second portion of the plurality of coated particles back to the mechanically fluidized particulate bed. The crystal production method may further include: prior to separating the plurality of coated particles from the mechanically fluidized particulate bed: heating the mechanically fluidized particulate bed to a temperature at or above a thermal decomposition temperature of the first gaseous chemical species; distributing at least the first gaseous chemical species in the heated mechanically fluidized particulate bed; and causing the deposition of the non-volatile second chemical species generated by the decomposition of the first gaseous chemical species in the mechanically fluidized particulate bed on at least a portion of the plurality of particulates to provide the plurality of coated particles. Distributing at least the first gaseous chemical species in the heated mechanically fluidized particulate bed may include: causing a flow of the first gaseous chemical species from an external supply to a gas distribution header fluidly coupled to a number of injectors, each of the injectors having at least one outlet positioned in the retainment volume; and causing a flow of at least the first gaseous chemical species at a number of points in the heated mechanically fluidized particulate bed via the number of injectors. Distributing at least the first gaseous chemical species in the heated mechanically fluidized particulate bed via a number of injectors, each of the number of injectors including at least one outlet positioned in the retainment volume may include: causing a temperature of the first gaseous chemical species in the gas distribution header and in each of the number of injectors to remain below the thermal decomposition temperature of the first gaseous chemical species. Causing the deposition of the non-volatile second chemical species generated by the decomposition of the first gaseous chemical species in the mechanically fluidized particulate bed on at least a portion of the plurality of particulates to provide the plurality of coated particles may include: causing the deposition of the non-volatile second chemical species on at least a portion of the plurality of particulates in the mechanically fluidized particulate bed to provide the plurality of coated particles, at least a portion of the coated particles including an agglomeration of sub-particles that form the respective coated particles. Causing the deposition of the non-volatile second chemical species generated by the decomposition of the first gaseous chemical species in the mechanically fluidized particulate bed on at least a portion of the plurality of particulates to provide the plurality of coated particles may further include: generating, via spontaneous self-nucleation of the non-volatile second chemical species, a plurality of particulate seeds to replace at least some of the first portion of the plurality of coated particles separated from the mechanically fluidized particulate bed. Adjusting an oscillation of a pan disposed in a chamber of a mechanically fluidized bed reactor, the oscillation including a non-zero first magnitude along at least a first axis may include: adjusting an oscillation of a pan disposed in a chamber of a mechanically fluidized bed reactor housing, the oscillation including a non-zero displacement of first magnitude along the first axis and a non-zero displacement of second magnitude along a second axis that is orthogonal to the first axis. Adjusting at least one of: an oscillatory frequency of a pan having a major horizontal surface that defines at least a portion of a retainment volume disposed in a chamber of a mechanically fluidized bed reactor, or an oscillatory displacement of the pan, the oscillatory displacement having anon-zero magnitude along at least a first axis may include: adjusting at least one of the oscillatory frequency of the pan or the oscillatory displacement of the pan so that coated particles having a diameter greater than 100 micrometers overflow into a coated particle overflow conduit sealingly coupled to and projecting from the major horizontal surface into the retainment volume. The crystal production method may further include: causing a flow of an inert gas at a defined first velocity from an inert gas reservoir into the retainment volume via the coated particle overflow conduit. Causing a flow of an inert fluid at a first velocity from an inert fluid reservoir into the retainment volume via the coated particle overflow conduit may include: causing a flow of an inert fluid at a first velocity from an inert fluid reservoir into the retainment volume via the coated particle overflow conduit, the defined first velocity selected to entrain and return coated particles having a diameter less than a defined threshold to the retainment volume. Separating a plurality of coated particles from the mechanically fluidized particulate bed, each of the coated particles including a non-volatile second chemical species produced by a thermal decomposition of a first gaseous chemical species in the mechanically fluidized particulate bed may include: adjusting at least one of an oscillatory frequency of the pan or an oscillatory displacement of the pan so that coated particles having a diameter of less than about 600 micrometers are retained in the mechanically fluidized particulate bed. Adjusting an oscillation of a pan disposed in a chamber of a mechanically fluidized bed reactor may include: adjusting at least one of an oscillatory frequency or an oscillatory displacement along at least one of the first axis or the second axis so that, in operation, the mechanically fluidized particulate bed touches (e.g., lightly, firmly) a lower surface of a cover disposed a defined distance above the major horizontal surface of the pan. Conveying, in an environment having a low oxygen level and a low contaminant level, a first portion of the plurality of coated particles separated from the mechanically fluidized particulate bed to a second chemical species crystal production device may include: heating the first portion of the plurality of coated particles in an environment having a low oxygen level and a low contaminant level to a temperature at or above a melting temperature of the second chemical species to form a reservoir of molten second chemical species; and growing at least one second chemical species via second chemical species crystal production device that includes a crystal puller hermetically sealed to the coated particle melter, both of which maintain an environment having a low oxygen level and a low contaminant level. Growing at least one second chemical species via second chemical species crystal production device that includes a crystal puller hermetically sealed to the coated particle melter, both of which maintain an environment having a low oxygen level and a low contaminant level may include: growing at least one second chemical species via second chemical species crystal production device that includes a crystal puller hermetically sealed to the coated particle melter, both of which maintain an environment having a low oxygen level and a low contaminant level. Conveying, in an environment having a low oxygen level and a low contaminant level, a first portion of the plurality of coated particles separated from the mechanically fluidized particulate bed to a second chemical species crystal production device may include: growing at least one monocrystalline second chemical species via a fluid zone crystal production process. Conveying in an environment having a low oxygen level a first portion of the plurality of coated particles separated from the mechanically fluidized particulate bed to a coated particle melter may include: conveying in an environment having a low oxygen level a first portion of the plurality of coated particles less than 500 parts per million atomic oxygen from the mechanically fluidized particulate bed to the coated particle melter. Separating a plurality of coated particles from the mechanically fluidized particulate bed, each of the plurality of coated particles including a non-volatile second chemical species produced by a thermal decomposition of a first gaseous chemical species in the mechanically fluidized particulate bed may include: causing a flow of the first gaseous chemical species through the mechanically fluidized particulate bed in one of: a plug flow regime or a transitional flow regime; and separating the plurality of coated particles from the mechanically fluidized particulate bed, each of the plurality of coated particles including the non-volatile second chemical species produced by the thermal decomposition of the first gaseous chemical species in the mechanically fluidized particulate bed.

A crystal production system may be summarized as including: a pan disposed in a chamber of a mechanically fluidized bed reactor, the pan having a major horizontal surface having an upper surface and a lower surface and defining at least a portion of a retainment volume; a transmission operably coupled to the pan that cyclically oscillates the pan at one or more defined frequencies and one or more defined displacements to produce a mechanically fluidized particulate bed including a plurality of coated particles in the retainment volume, each of the plurality of coated particles containing a non-volatile second chemical species provided by a thermal decomposition of a first gaseous chemical species in the mechanically fluidized particulate bed, the one or more defined displacements including a non-zero first magnitude along a first axis and a non-zero second magnitude along a second axis that is not parallel to the first axis; a second chemical species crystal production device that, in operation, causes a temperature of a first portion of the plurality of coated particles separated from the mechanically fluidized particulate bed to exceed a melting temperature of the non-volatile second chemical species; and a hermetically sealed conveyance that couples the chamber to the second chemical species crystal production device such that, in operation, the first portion of the plurality of coated particles are conveyed from the retainment volume to the second chemical species crystal production device in an environment having a low oxygen level and a low contaminant level environment.

The second chemical species crystal production device may include: a coated particle melter that, in operation, causes a temperature of a first portion of the plurality of coated particles separated from the mechanically fluidized particulate bed to exceed a melting temperature of the non-volatile second chemical species to provide a reservoir of molten second chemical species; and a crystal grower operably coupled and hermetically sealed to the coated particle melter that, in operation, produces one or more second chemical species crystals using at least a portion of the liquid reservoir of molten second chemical species. The second chemical species crystal production device may include: a Float Zone crystal production device. The crystal production system may further include: at least one thermal energy producing device disposed proximate the lower surface of the major horizontal surface of the pan and thermally conductively coupled to the major horizontal surface of the pan. The crystal production system may further include: at least one thermal energy producing device thermally convectively coupled to the mechanically fluidized particulate bed retained in the retainment volume. The crystal production system wherein the first axis and the second axis may be orthogonal to each other. The crystal production system may further include: a cover having an upper surface, a lower surface, and a peripheral edge, the cover disposed above the major horizontal surface of the pan with the peripheral edge of the cover spaced inwardly of a perimeter wall of the pan and a peripheral gap defined between the peripheral edge of the cover and the peripheral wall of the pan, the peripheral gap to, in operation, fluidly couple the retainment volume to an exterior space about the pan; and a coated particle overflow conduit sealingly coupled to and projecting from the upper surface of the major horizontal surface of the pan, the coated particle overflow conduit to collect, via overflow, at least a portion of the plurality of coated particles from the mechanically fluidized particulate bed, the coated particle overflow conduit having an inlet and a passage extending therethrough from the inlet to a distal portion of the coated particle overflow conduit, the inlet of the coated particle overflow conduit is positioned a distance from the upper surface major horizontal surface of the pan and in the retainment volume of the pan. The crystal production system may further include: a plurality of baffles including at least one of: a plurality of baffles extending upward from the upper surface of the major horizontal surface at least partially into the retainment volume or extending downward from the lower surface of the cover at least partially into the retainment volume, each of the plurality of baffles disposed at least partially about the coated particle overflow conduit, spaced outwardly from the coated particle overflow conduit. The crystal production system may further include: a plurality of baffles including a plurality of baffles having a first portion of baffles that extend upward from the upper surface of the major horizontal surface at least partially into the retainment volume alternated with a second portion of baffles that extend downward from the lower surface of the cover at least partially into the retainment volume, the plurality of baffles defining a radial serpentine flow path through the retainment volume. The crystal production system may further include: at least one purge gas reservoir and distribution header fluidly coupled to the coated particle overflow conduit; and a control system operably coupled to the purge gas distribution header to modulate the feed of a purge gas from the purge gas reservoir to the coated particle overflow conduit, countercurrent to the flow of the plurality of coated particles to maintain a defined first gas velocity in the coated particle overflow conduit. The crystal production system may further include: a first gaseous chemical reservoir and distribution header fluidly coupled to each of a number of injectors, each of the number of injectors having at least one outlet positioned in the retainment volume. The crystal production system may further include: at least one diluent reservoir and distribution header fluidly coupled to the first gaseous chemical species distribution header; and a control system operably coupled to the diluent distribution header to modulate the feed of the at least one diluent to maintain a defined ratio of the flow rate of the first gaseous chemical species to the flow rate of the at least one diluent in the mechanically fluidized particulate bed. The crystal production system may further include: at least one dopant reservoir and distribution header fluidly coupled to the mechanically fluidized particulate bed; and a control system operably coupled to the dopant distribution header to modulate the feed of the at least one dopant to maintain a defined ratio of the flow rate of the first gaseous chemical species to the flow rate of the at least one dopant to the mechanically fluidized particulate bed.

### BRIEF DESCRIPTION OF SEVERAL VIEWS OF THE DRAWINGS

In the drawings, identical reference numbers identify similar elements or acts. The sizes and relative positions of elements in the drawings are not necessarily drawn to scale. For example, the shapes of various elements and angles are not drawn to scale, and some of these elements are arbitrarily enlarged and positioned to improve drawing legibility. Further, the particular shapes of the elements, as drawn, are not intended to convey any information regarding the actual shape of the particular elements, and have been solely selected for ease of recognition in the drawings.

FIG. 1 is a partial sectional view of an example mechanically fluidized reactor useful in chemical vapor deposition reactions in which a gaseous first chemical species decomposes within a mechanically fluidized particulate bed to deposit a non-volatile second chemical species on the particulates to form coated particles, according to an illustrated embodiment.

FIG. 2 is a partial sectional view of another example mechanically fluidized reactor useful in chemical vapor deposition reactions in which a gaseous first chemical species decomposes within a mechanically fluidized particulate bed to deposit a non-volatile second chemical species on the particulates to form coated particles, according to an illustrated embodiment.

FIG. 3A is a partial sectional view of another example mechanically fluidized reactor using a covered pan to contain the mechanically fluidized particulate bed using a coated particle collection system featuring a number of hollow coated particle overflow conduits positioned in the retention volume retaining the mechanically fluidized particulate bed; such reactors are useful in chemical vapor deposition reactions in which a gaseous first chemical species decomposes within the mechanically fluidized particulate bed to deposit a non-volatile second chemical species on the particulates to form coated particles, according to an illustrated embodiment.

FIG. 3B is a partial sectional view of a gas distribution system that includes a number of injectors fluidly coupled to a distribution header, each of the injectors surrounded by a close-ended void space containing one of either an insulative vacuum or an insulative material to prevent premature decomposition of the first gaseous chemical species in the injectors, according to an illustrated embodiment.

FIG. 3C is a partial sectional view of another gas distribution system that includes a number of injectors fluidly coupled to a distribution header, each of the injectors surrounded by an open-ended void space through which a cooling inert fluid is passed to prevent premature decomposition of the first gaseous chemical species in the injectors, according to an illustrated embodiment.

FIG. 3D is a partial sectional view of a gas distribution system that includes a number of injectors fluidly coupled to a distribution header, each of the injectors surrounded by an open-ended void space through which a cooling inert fluid is passed and a closed-ended second void space containing one of either an insulative vacuum or an insulative material to prevent premature decomposition of the first gaseous chemical species in the injectors, according to an illustrated embodiment.

FIG. 3E is a partial sectional view of a gas distribution system that includes a number of injectors fluidly coupled to a distribution header, each of the injectors surrounded by a close-ended void space through which a coolant fluid is passed to prevent premature decomposition of the first gaseous chemical species in the injectors, according to an illustrated embodiment.

FIG. 4A is a partial sectional view of an alternative covered pan featuring a peripheral vent and a “top hat” type chamber proximate the coated particle overflow and in which the first gaseous chemical species is introduced centrally and flows radially outward through the mechanically fluidized particulate bed, according to an illustrated embodiment.

FIG. 4B is a partial sectional view of an alternative covered pan featuring baffles disposed concentrically about the coated particle overflow and coupled to the cover and the pan in an alternating pattern to form a serpentine gas flow path from the first gaseous chemical species distribution header to the periphery of the pan, according to an illustrated embodiment.

FIG. 4C is a partial sectional view of an alternative covered pan featuring a central vent an a peripheral first gaseous chemical species distribution header in which the first gaseous chemical species is introduced peripherally and flows radially inward through the mechanically fluidized particulate bed, according to an illustrated embodiment.

FIG. 5A is a plan view of a cover used with a covered pan that is anchored to the pan and oscillates with the pan thereby maintaining a fixed volume mechanically fluidized bed, according to an illustrated embodiment.

FIG. 5B is a cross-sectional elevation of the cover depicted in FIG. 5A, according to an illustrated embodiment.

FIG. 5C is a plan view of a cover used with a covered pan that is anchored to the mechanically fluidized bed reactor vessel and does not oscillate with the pan thereby creating a variable volume mechanically fluidized bed, according to an illustrated embodiment.

FIG. 5D is a cross-sectional elevation of the cover depicted in FIG. 5C, according to an illustrated embodiment.

FIG. 6 is a partial sectional view of another example mechanically fluidized reactor using a plurality of covered pans each of which contains the mechanically fluidized particulate bed; such reactors are useful in chemical vapor deposition reactions in which a gaseous first chemical species decomposes within the mechanically fluidized particulate bed to deposit a non-volatile second chemical species on the particulates to form coated particles, according to an illustrated embodiment.

FIG. 7A is a partial sectional view of another example mechanically fluidized reactor using a covered pan to contain the mechanically fluidized particulate bed and in which the entire reaction vessel oscillates to mechanically fluidize the particulate bed carried in the covered pan; such reactors are useful in chemical vapor deposition reactions in which a gaseous first chemical species decomposes within the mechanically fluidized particulate bed to deposit a non-volatile second chemical species on the particulates to form coated particles, according to an illustrated embodiment.

FIG. 7B is a partial sectional view of an alternative covered pan featuring a peripheral vent and a “top hat” type chamber proximate the coated particle overflow and in which the first gaseous chemical species is introduced centrally and flows radially outward through the mechanically fluidized particulate bed; the covered pan positioned in a mechanically fluidized bed reactor in which the entire reaction vessel oscillates to mechanically fluidize the particulate bed carried in the covered pan, according to an illustrated embodiment.

FIG. 7C is a partial sectional view of an alternative covered pan featuring baffles disposed concentrically about the coated particle overflow and coupled to the cover and the pan in an alternating pattern to form a serpentine gas flow path from the first gaseous chemical species distribution header to the periphery of the pan; the covered pan positioned in a mechanically fluidized bed reactor in which the entire reaction vessel oscillates to mechanically fluidize the particulate bed carried in the covered pan according to an illustrated embodiment.

FIG. 7D is a partial sectional view of an alternative covered pan featuring a central vent an a peripheral first gaseous chemical species distribution header in which the first gaseous chemical species is introduced peripherally and flows radially inward through the mechanically fluidized particulate bed; the covered pan positioned in a mechanically fluidized bed reactor in which the entire reaction vessel oscillates to mechanically fluidize the particulate bed carried in the covered pan, according to an illustrated embodiment.

FIG. 8A is a partial sectional view of an example mechanically fluidized reactor in which the reactor itself functions as a covered pan to contain the mechanically fluidized particulate bed and in which the entire reaction vessel oscillates to mechanically fluidize the particulate bed; such reactors are useful in chemical vapor deposition reactions in which a gaseous first chemical species decomposes within the mechanically fluidized particulate bed to deposit a non-volatile second chemical species on the particulates to form coated particles, according to an illustrated embodiment.

FIG. 8B is a partial sectional view of another example mechanically fluidized reactor in which the reactor itself functions as a covered pan to contain the mechanically fluidized particulate bed and in which the entire reaction vessel oscillates to mechanically fluidize the particulate bed; such reactors are useful in chemical vapor deposition reactions in which a gaseous first chemical species decomposes within the mechanically fluidized particulate bed to deposit a non-volatile second chemical species on the particulates to form coated particles, according to an illustrated embodiment.

FIG. 9 is a schematic view of an example coated particle production process including three serially coupled mechanically fluidized bed reaction vessels suitable for the production of second chemical species coated particles using one or more of the mechanically fluidized bed reactors depicted in FIGS. 1-7B, according to an embodiment.

FIG. 10A is a schematic view of an illustrative crystal production method in which a reactor containing a particulate bed produced coated particles that are transported via a conveyance to a coated particle melter while maintained in a free oxygen reduced environment, according to an illustrated embodiment.

FIG. 10B is a block diagram of a conveyance configuration in which the conveyance includes only a hermetic coupling between a reactor containing a particulate bed from which coated particles are separated and a coated particle melter (i.e., a “close-coupled” configuration), according to an illustrated embodiment.

FIG. 10C is a block diagram of a conveyance configuration in which the conveyance includes a coated particle accumulator positioned between a reactor containing a particulate bed from which coated particles are separated and a coated particle melter, according to an illustrated embodiment.

FIG. 10D is a block diagram of a conveyance configuration in which the conveyance includes a coated particle classifier positioned between a reactor containing a particulate bed from which coated particles are separated and a coated particle melter, according to an illustrated embodiment.

FIG. 10E is a block diagram of a conveyance configuration in which the conveyance includes a coated particle accumulator and a coated particle classifier positioned between a reactor containing a particulate bed from which coated particles are separated and a coated particle melter, according to an illustrated embodiment.

FIG. 10F is a block diagram of a conveyance configuration in which the conveyance includes a coated particle classifier and a coated particle grinder positioned between a reactor containing a particulate bed from which coated particles are separated and a coated particle melter, according to an illustrated embodiment.

FIG. 10G is a block diagram of a conveyance configuration in which the conveyance includes a coated particle accumulator, a coated particle classifier, and a coated particle grinder positioned between a reactor containing a particulate bed from which coated particles are separated and a coated particle melter, according to an illustrated embodiment.

FIG. 11 is a schematic view of an illustrative crystal production method in which a mechanically fluidized bed reactor is close coupled and hermetically sealed to a melter that receives coated particles removed from the mechanically fluidized particulate bed; the mechanically fluidized bed reactor can include any of the mechanically fluidized bed reactors depicted in FIGS. 1-7B, according to an illustrated embodiment.

FIG. 12 is a high level flow diagram of an illustrative crystal production method in which coated particles separated from a particulate bed disposed in a reactor are transferred to a coated particle melter in an environment containing a reduced level of free oxygen, according to an illustrated embodiment.

FIG. 13 is a high level flow diagram of an illustrative crystal production method in which coated particles separated from a fluidized particulate bed disposed in a reactor are transferred to a coated particle melter in an environment containing a reduced level of free oxygen, according to an illustrated embodiment.

FIG. 14 is a high level flow diagram of an illustrative crystal production method in which coated particles are produced by supplying a thermally decomposable first gaseous chemical species and one or more diluents to a fluidized particulate bed, according to an illustrated embodiment.

FIG. 15 is a high level flow diagram of an illustrative crystal production method in which doped coated particles are produced by supplying a thermally decomposable first gaseous chemical species and one or more dopants to a fluidized particulate bed, according to an illustrated embodiment.

FIG. 16 is a high level flow diagram of an illustrative crystal production method in which a chamber in a reactor containing the particulate bed is maintained at a temperature below the thermal decomposition temperature of a first gaseous chemical species to limit the decomposition of the first gaseous chemical species external to the particulate bed, according to an illustrated embodiment.

FIG. 17 is a high level flow diagram of an illustrative crystal production method in which coated particles separated from a particulate bed are divided into a first portion and a second portion and at least some of the second portion of coated particles is returned to the particulate bed, according to an illustrated embodiment.

FIG. 18 is a high level flow diagram of an illustrative crystal production method in which coated particles are melted in a coated particle melter from which a crystal puller draws a second chemical species crystal, according to an illustrated embodiment.

FIG. 19 is a high level flow diagram of an illustrative crystal production method in which coated particles separated from a particulate bed disposed in a reactor are transferred to a coated particle melter in an environment containing a reduced level of free oxygen, according to an illustrated embodiment.

FIG. 20 is a high level flow diagram of an illustrative crystal production method in which coated particles separated from a particulate bed disposed in a reactor are transferred to a coated particle melter in an environment containing a reduced level of free oxygen, according to an illustrated embodiment.

### DETAILED DESCRIPTION

In the following description, certain specific details are included to provide a thorough understanding of various disclosed embodiments. One skilled in the relevant art, however, will recognize that embodiments may be practiced without one or more of these specific details, or with other methods, components, materials, etc. In other instances, well-known structures associated with systems for making silicon including, but not limited to, vessel design and construction details, metallurgical properties, piping, control system design, mixer design, separators, vaporizers, valves, controllers, or final control elements, have not been shown or described in detail to avoid unnecessarily obscuring descriptions of the embodiments.

Unless the context requires otherwise, throughout the specification and claims which follow, the word “comprise” and variations thereof, such as, “comprises” and “comprising” are to be construed in an open, inclusive sense, that is, as “including, but not limited to.”

Reference throughout this specification to “one embodiment,” or “an embodiment,” or “another embodiment,” or “some embodiments,” or “certain embodiments” means that a particular referent feature, structure, or characteristic described in connection with the embodiment is included in at least one embodiment. Thus, the appearance of the phrases “in one embodiment,” or “in an embodiment,” or “in another embodiment,” or “in some embodiments,” or “in certain embodiments” in various places throughout this specification are not necessarily all referring to the same embodiment. Furthermore, the particular features, structures, or characteristics may be combined in any suitable manner in one or more embodiments.

It should be noted that, as used in this specification and the appended claims, the singular forms “a,” “an,” and “the” include plural referents unless the content clearly dictates otherwise. Thus, for example, reference to a chlorosilane includes a single species of chlorosilane, but may also include multiple species of chlorosilanes. It should also be noted that the term “or” is generally employed as including “and/or” unless the content clearly dictates otherwise.

As used herein, the term “silane” refers to SiH₄. As used herein, the term “silanes” is used generically to refer to silane and/or any derivatives thereof. As used herein, the term “chlorosilane” refers to a silane derivative wherein one or more of hydrogen has been substituted by chlorine. The term “chlorosilanes” refers to one or more species of chlorosilane. Chlorosilanes are exemplified by monochlorosilane (SiH₃Cl or MCS); dichlorosilane (SiH₂Cl₂ or DCS); trichlorosilane (SiHCl₃ or TCS); or tetrachlorosilane, also referred to as silicon tetrachloride (SiCl₄ or STC). The melting point and boiling point of silanes increases with the number of chlorines in the molecule. Thus, for example, silane is a gas at standard temperature and pressure (0° C./273 K and 101 kPa), while silicon tetrachloride is a liquid. As used herein, the term “silicon” refers to atomic silicon, i.e., silicon having the formula Si. Unless otherwise specified, the terms “silicon” and “polysilicon” are used interchangeably herein when referring to the silicon product of the methods and systems disclosed herein. Unless otherwise specified, concentrations expressed herein as percentages should be understood to mean that the concentrations are in mole percent.

As used herein, the terms “chemical decomposition,” “chemically decomposed,” “thermal decomposition,” and “thermally decomposed” all refer to a process by which a first gaseous chemical species (e.g., silane) is heated to a temperature above a thermal decomposition temperature at which the first gaseous chemical species decomposes to at least a non-volatile second chemical species (e.g., silicon). In some implementations, the first gaseous chemical species may also yield one or more third gaseous chemical decomposition byproducts (e.g., hydrogen). Such reactions may be considered as a thermally initiated chemical decomposition or, more simply, as a “thermal decomposition.” It should be noted that the thermal decomposition temperature of the first gaseous chemical species is not a fixed value and varies with the pressure at which the first gaseous chemical species is maintained.

As used herein, the term “mechanically fluidized” refers to the mechanical suspension or fluidization of particles forming the particulate bed, for example by mechanically oscillating or vibrating the particulate bed in a manner promoting the flow and circulation (i.e., the “mechanical fluidization”) of the particles. Such mechanical fluidization, generated by a cyclical physical displacement (e.g., vibration or oscillation) of the one or more surfaces supporting the particulate bed or the retainment volume about the particulate bed, is therefore distinct from liquid or gaseous (i.e., hydraulic) bed fluidization generated by the passage of a liquid or gas through a particulate bed. It should be noted with particularity that a mechanically fluidized particulate bed is not reliant upon the passage of a fluid (i.e., liquid or gas) through the plurality of particulates to attain fluid-like behavior. As such, fluid volumes passed through a mechanically fluidized bed can be significantly smaller than the fluid volumes used in a hydraulically fluidized bed. In addition, a quiescent (i.e., non-fluidized) plurality of particles represents a “settled bed” which occupies a “settled volume.” When fluidized, the same plurality of particles occupies a “fluidized volume” which is greater than the settled volume occupied by the plurality of particles. The terms “vibration” and “oscillation,” and variations of such (e.g., vibrating, oscillating) are used interchangeably herein.

As used herein, the terms “particulate bed” and “heated particulate bed” refer to any type of particulate bed, including packed (i.e., settled) particulate beds, hydraulically fluidized particulate beds, and mechanically fluidized particulate beds. The term “heated fluidized particulate bed” can refer to either or both a heated hydraulically fluidized particulate bed and/or a heated mechanically fluidized particulate bed. The term “hydraulically fluidized particulate bed” refers specifically to a fluidized bed created by the passage of a fluid (i.e., liquid or gas) through a particulate bed. The term “mechanically fluidized particulate bed” refers specifically to a fluidized bed created by oscillating or vibrating a surface supporting the particulate bed at an oscillatory frequency and/or oscillatory displacement sufficient to fluidize the particulate bed.

The headings provided herein are for convenience only and do not interpret the scope or meaning of the embodiments.

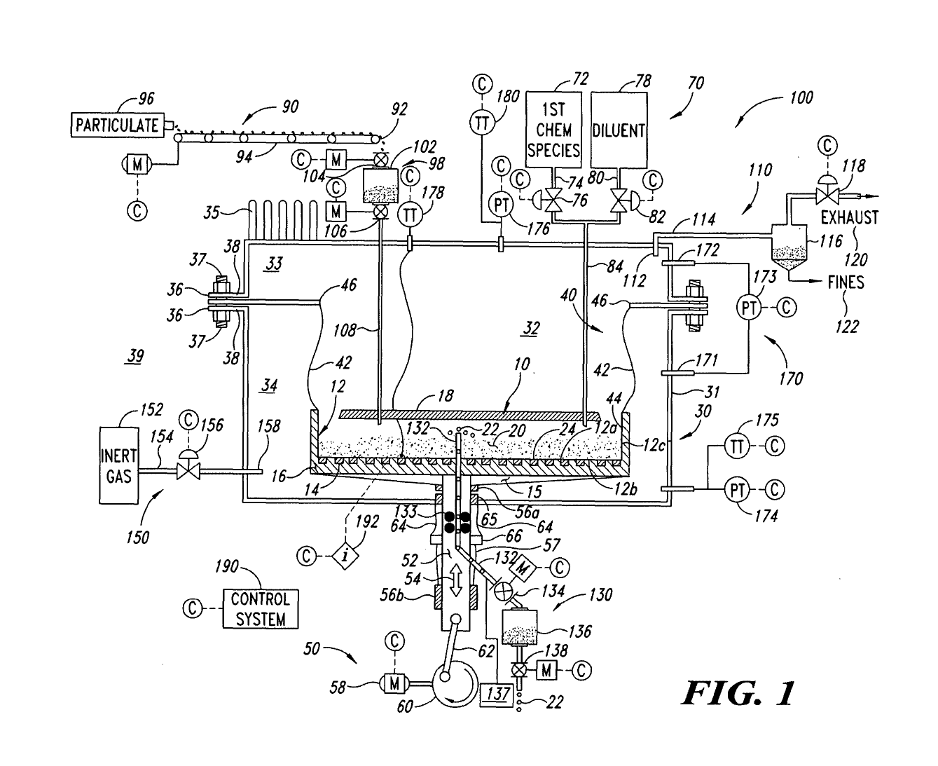

FIG. 1 shows a mechanically fluidized bed reactor system 100, according to one illustrated embodiment. In the mechanically fluidized bed reactor system 100, at least one gas including controlled quantities of a first gaseous chemical species and, optionally, controlled quantities of one or more diluent(s) is introduced to a mechanically fluidized particulate bed 20 carried by a pan 12. The interior of the mechanically fluidized bed reactor vessel 30 includes a chamber 32 that is, at times, apportioned into an upper chamber 33 and a lower chamber 34. In some instances, a flexible membrane 42 separates and hermetically seals all or a portion of the mechanically fluidized bed 20 in the upper chamber 33 from the lower chamber 34.

The mechanically fluidized bed reactor system 100 includes a mechanically fluidized bed apparatus 10 that is useful for mechanically fluidizing particles, seeds, dust, grains, granules, beads, etc. (hereinafter collectively referred to as “particulates” for clarity). The mechanically fluidized bed reactor system 100 also includes one or more thermal energy emitting devices 14, such as one or more heaters, that are thermally coupled to the pan 12 and/or the mechanically fluidized particulate bed 20, and are used to increase the temperature of the mechanically fluidized particulate bed 20 to a temperature in excess of the decomposition temperature of the first gaseous chemical species as the pan 12 oscillates or vibrates.

The heated, mechanically fluidized particles in the particulate bed 20 provide a substrate upon which the non-volatile second chemical species (e.g., polysilicon) formed by the thermal decomposition of the first gaseous chemical species (e.g., silane) deposits. At times, the thermal decomposition of the first gaseous chemical species occurs within the mechanically fluidized particulate bed 20 and either does not occur or occurs minimally in other locations within the chamber 32, even though the environment in the chamber 32 may be maintained at an elevated temperature and pressure (i.e., elevated relative to atmospheric temperatures and pressures).

One or more vessel walls 31 separate the chamber 32 from the vessel exterior 39. The reaction vessel 30 can feature either a unitary or multi-piece design. For example, as shown in FIG. 1 the reaction vessel 30 is a multi-piece vessel assembled using one or more fastener systems such as one or more flanges 36, threaded fasteners 37, and sealing members 38.

The mechanically fluidized bed apparatus 10 may be positioned in the chamber 32 in the reaction vessel 30. The system 100 further includes a transmission system 50, a gas supply system 70, a particle supply system 90, a gas recovery system 110, a coated particle collection system 130, an inert gas feed system 150, and a pressure system 170. The system 100 may also include an automated or semi-automated control system 190 that is communicably coupled to the various components and systems forming the system. For clarity, the communicative coupling of various components to the control system 190 is depicted using a dashed line and “©” symbol. Each of these structures, systems or systems is discussed in subsequent detail below.

During operation, the chamber 32 within the reaction vessel 30 is maintained at one or more controlled temperatures and/or pressures that are usually greater than the temperature and pressure found in the ambient environment 39 surrounding the vessel 30. Thus, the vessel wall 31 is of suitable material, design, and construction with adequate safety margins to withstand the expected working pressures and temperatures within the chamber 32, which may include repeated pressure and thermal cycling of the reaction vessel 30. Additionally, the overall shape of the reaction vessel 30 may be selected or designed to withstand such expected working pressures or to accommodate a preferred particle bed 20 configuration or geometry. In at least some instances, the reaction vessel 30 may be fabricated in conformance with the American Society of Mechanical Engineers (ASME) Section VIII code (latest version) covering the construction of pressure vessels. In some instances, the design and construction of the reaction vessel 30 may accommodate the partial or complete disassembly of the vessel for operation, inspection, maintenance, or repair. Such disassembly may be facilitated by the use of threaded or flanged connections on the reaction vessel 30 itself or the fluid connections made to the reaction vessel 30.

The reaction vessel 30 may optionally include one or more cooling features 35 physically and/or thermally coupled to all or a portion of an exterior surface of the vessel wall 31. Such cooling features 35 may be disposed at any location on the exterior surface of the reaction vessel 30 including the reaction vessel top, bottom, and/or sides. In some instances, the cooling features 35 may include passive cooling features such as extended surface area fins thermally conductively coupled to all or a portion of the exterior surface of the reaction vessel 30. In some instances, the cooling features 35 may include active cooling features such as a jacket and/or cooling coils through which a heat transfer media (e.g., thermal oil, boiler feed water) is circulated. In some instances, the cooling features 35, such as cooling jackets and/or cooling coils may be disposed at least partially within the chamber 32. In some instances, the cooling features 35 may be integral with the vessel wall 31 or may be thermally conductively coupled to the vessel wall 31.

Although depicted in FIG. 1 as a series of cooling fins (only a few shown) providing an extended surface area for convective heat dissipation to the ambient environment 39, such cooling features 35 may also include other passive or active thermal systems, devices, or combinations of systems and devices that aid in the addition or the removal of thermal energy from the upper chamber 33, the lower chamber 34, or both the upper and the lower chambers. Such cooling systems and devices may include active thermal transfer systems or devices such as cooling jackets having one or more heat transfer fluids circulated therein, or various combinations of surface features and cooling jackets.

One or more cooling features 35 may beneficially maintain a temperature in at least the upper chamber 33 below the thermal decomposition temperature of the first gaseous chemical species. In some instances, the cooling features 35 may be selectively disposed on portions of the chamber 32 or the reaction vessel 30 that are prone to localized concentrations of thermal energy to assist in the dissipation or distribution of such thermal energy. By maintaining the temperature in the upper chamber 33 below the thermal decomposition temperature of the first gaseous chemical species, spontaneous decomposition of the first gaseous chemical species in locations external to the mechanically fluidized bed 20 is advantageously minimized or even eliminated.

One or more cooling features 35 may maintain a temperature at some or all points in the upper chamber 33 external to the mechanically fluidized particulate bed 20 that is below a thermal decomposition temperature of the first gaseous chemical species. By maintaining the temperature below the thermal decomposition temperature of the first gaseous chemical species in the upper chamber external to the mechanically fluidized particulate bed 20, decomposition of the first gaseous chemical species and subsequent deposition of the second chemical species on surfaces external to the mechanically fluidized particulate bed 20 and/or the formation of second chemical species “dust” in the upper chamber 33 is beneficially reduced or even eliminated.

One or more cooling features 35 may maintain a temperature in the lower chamber 34 below the thermal decomposition temperature of the first gaseous chemical species. Additionally or alternatively, one or more passive or active cooling features 57 may be thermally and/or physically coupled to the transmission system 50 to maintain the temperature of the oscillatory transmission member at or below the thermal decomposition temperature of the first gaseous chemical species.

It is believed that one or more alloys (e.g., an alloy of molybdenum and Super Invar) may exist that is similar to, or ideally matches, the thermal expansion coefficient of silicon, or silicon carbide, or silicon nitride, or fused quartz. Such alloys may provide a liner material suitable for use on at least a portion of the interior surfaces of the reactor 30 and/or pan 12. In one instance, it is believed at least a portion of at least the upper chamber 33 of the reactor 30 may be formed from such an alloy and a quartz liner may be spray fused to at least a portion of such surfaces. Such construction would advantageously minimize the likelihood of the quart liner spalling from the surfaces in the upper chamber 33 of the reactor 30 when the reactor is cycled between room temperature an operating temperature.

The mechanically fluidized bed apparatus 10 includes at least one pan 12 having a bottom (i.e., a major horizontal surface) that supports the mechanically fluidized particulate bed 20 and defines at least one boundary of a retainment volume that retains the mechanically fluidized particulate bed 20. The bottom or major horizontal surface of the pan 12 includes at least an upper surface 12a, a lower surface 12b. The bottom of the pan 12 can include an integral, unitary, and single piece surface that is continuous without penetrations and/or apertures. In some instances, the bottom of the pan 12 may be formed integral with the remaining portion of the pan 12. In other instances, all or a portion of the bottom of the pan 12 may be selectively removable from the pan 12, thereby facilitating the repair, rejuvenation, or replacement of a worn pan bottom and/or providing access to one or more thermal energy emitting devices 14 positioned proximate and beneath the bottom of the pan 12.

The pan 12 further includes a perimeter wall 12c that extends at an upward angle from a peripheral edge or periphery of the bottom of the pan 12. The perimeter wall 12c defines at least a portion of at least one boundary of the retainment volume that retains the mechanically fluidized particulate bed 20. At times, the perimeter wall 12c extends about only a portion of the periphery of the bottom of the pan 12. At times, the perimeter wall 12c extends about the entire periphery of the bottom of the pan 12. In some implementations, the bottom and the perimeter wall 12c of the pan 12 form at least a portion of an open-topped retainment volume that retains or otherwise confines the mechanically fluidized particulate bed 20.

The perimeter wall 12c of the pan 12 may extend a fixed height above the bottom of the pan 12 for the entire length of the perimeter wall 12c. At other times, the perimeter wall 12c of the pan 12 may extend a first fixed height above the bottom of the pan 12 for a first portion of the length of the perimeter wall 12c and a second fixed height above the bottom of the pan 12 for a second portion of the length of the perimeter wall 12c. In some instances, all or a portion of the perimeter wall 12c may include a notch, weir, or similar aperture that permits removal of coated particles 22 from the mechanically fluidized particulate bed 20 via overflow.

In operation, the retention volume within the pan 12 retains the mechanically fluidized particulate bed 20. Where coated particles 22 overflow the perimeter wall 12c of the pan 12, the height of the lowest portion of the perimeter wall 12c determines the depth of the mechanically fluidized particulate bed 20. At times, the perimeter wall 12c extends at an upward angle of from about 30° to about 90° from the upper surface of the pan 12a.

In some implementations, the height of the perimeter wall 12c is the same as or slightly lower than the depth of the mechanically fluidized particulate bed 20 such that, in operation, at least some of the plurality of coated particles 22 carried on the surface of the mechanically fluidized particulate bed 20 overflow the perimeter wall 12c for capture by the coated particle removal system 130. In such implementations, the coated particle removal system 130 includes one or more collection devices, for example one or more funnel-shaped coated particle diverters positioned proximate and beneath the pan 12 to catch coated particles 22 overflowing the perimeter wall 12c of the pan 12.

In other implementations, the height of the perimeter wall 12c is greater than the depth of the mechanically fluidized particulate bed 20 such that, in operation, the entirety of the mechanically fluidized particulate bed 20 is retained internal to the retainment volume and proximate the upper surface 12a of pan 12. In such implementations the coated particle removal system 130 includes one or more open-ended, hollow, coated particle overflow conduits 132 positioned in the retainment volume. Coated particles 22 overflow from the surface of the mechanically fluidized particulate bed 20 into the open end of the one or more coated particle overflow conduits 132. In some implementations, the coated particle overflow conduits 132 may be sealed via one or more sealing devices 133, such as one or more 0-Rings or one or more mechanical seals. In such implementations, the perimeter wall 12c can extend above the upper surface of the mechanically fluidized particulate bed 20 (and the open end of the coated particle overflow conduit 132) by a distance of from about 0.125 inches (3 mm) to about 12 inches (30 cm); from about 0.125 inches (3 mm) to about 10 inches (25 cm); from about 0.125 inches (3 mm) to about 8 inches (20 cm); from about 0.125 inches (3 mm) to about 6 inches (15 cm); or from about 0.125 inches (3 mm) to about 3 inches (7.5 cm).

The pan 12 can have any shape or geometric configuration, including but not limited to: circular, oval, trapezoidal, polygonal, triangular, rectangular, square, or combinations thereof. For example, the pan 12 may have a generally circular shape with a diameter of from about 1 inch (2.5 cm) to about 120 inches (300 cm); from about 1 inch (2.5 cm) to about 96 inches (245 cm); from about 1 inch (2.5 cm) to about 72 inches (180 cm); from about 1 inch (2.5 cm) to about 48 inches (120 cm); from about 1 inch (2.5 cm) to about 24 inches (60 cm); or from about 1 inch (2.5 cm) to about 12 inches (30 cm).

The portions of the pan 12 contacting the mechanically fluidized particulate bed 20 are formed of an abrasion or erosion resistant material that is also resistant to chemical degradation by the first chemical species, the diluent(s), and the coated particles in the particulate bed 20. Use of a pan 12 having appropriate physical and chemical resistance reduces the likelihood of contamination of the fluidized particulate bed 20 by contaminants released from the pan 12. In some instances, the pan 12 can comprise an alloy such as a graphite alloy, a nickel alloy, a stainless steel alloy, or combinations thereof. In some instances, the pan 12 can comprise molybdenum or a molybdenum alloy.

In some applications, the pan 12 may include one or more layers or coatings of one or more resilient materials that resist abrasion or erosion, reduce unwanted product buildup, and/or reduce the likelihood of contamination of the mechanically fluidized particulate bed 20. In some instances, all or a portion of the bottom of the pan 12 and/or the perimeter walls 12c of the pan, may comprise substantially pure silicon (e.g., high purity silicon that is in excess of 99% silicon, 99.5% silicon, or 99.9% silicon). In at least some implementations, the substantially pure silicon layer can have at least one of: a uniform thickness or a uniform density. While the second chemical species may be deposited as a consequence of the decomposition of the first gaseous chemical species, it should be understood that the silicon comprising the bottom of the pan is present prior to the first use of the pan 12, in other words, the silicon comprising the pan 12 is different from the non-volatile second chemical species created by the thermal decomposition of the first gaseous chemical species in the mechanically fluidized particulate bed 20.

In some instances, the layer or coating in all or a portion of the pan 12 can include but is not limited to: a graphite layer, a quartz layer, a silicide layer, a silicon nitride layer, or a silicon carbide layer. In some instances, a metal silicide may be formed in situ by reaction of silane with iron, nickel, molybedenum, and other metals in the pan 12. A silicon carbide layer, for example, is durable and reduces the tendency of metal ions such as nickel, chrome, and iron from the metal comprising the pan to migrate into, and potentially contaminate, the plurality of coated particles 22 in the pan 12. In one example, the pan 12 comprises a 316 stainless steel pan with a silicon carbide layer deposited on at least a portion of the upper surface 12a of the bottom of the pan 12 and at least the portions perimeter wall 12c contacting the mechanically fluidized particulate bed 20.

In operation, one or more thermal energy emission devices 14 increase the temperature of the mechanically fluidized particulate bed 20 to a level in excess of the thermal decomposition temperature of the first gaseous chemical species at the operating pressure of the reactor. Heating the mechanically fluidized particulate bed 20 to a temperature in excess of thermal decomposition temperature of the first gaseous chemical species beneficially causes the preferential thermal decomposition of the first gaseous chemical species in the mechanically fluidized particulate bed 20 rather than in other locations within the reactor. Maintaining temperatures external to the mechanically fluidized particulate bed 20 below the thermal decomposition temperature of the first gaseous chemical species further reduces the likelihood of thermal decomposition of the first gaseous chemical species at locations in the reactor outside of the mechanically fluidized particulate bed 20. The thermal decomposition of the first gaseous chemical species (e.g., silane, dichlorosilane, trichlorosilane) causes deposition of a non-volatile second chemical species (e.g., silicon, polysilicon) on at least a portion of the plurality of particulates in the mechanically fluidized particulate bed 20 to provide the plurality of coated particles 22. The coated particles 22 circulate freely in the mechanically fluidized particulate bed 20 and, somewhat surprisingly, tend to rise within and “float” on the surface of the mechanically fluidized particulate bed 20. Such behavior allows for the selective separation and removal of coated particles 22 from the mechanically fluidized particulate bed 20.

At times, the gas within the chamber 32 is maintained at a low oxygen level (e.g., less than 20 volume percent oxygen) or at a very low oxygen level (e.g., less than 0.001 mole percent oxygen to less than 1 mole percent oxygen). Coated particles 22 in the chamber 32 are maintained in an environment having a low oxygen level (e.g., less than 20 volume percent oxygen) or a very low oxygen level (e.g., less than 1 mole percent oxygen to less than 0.001 mole percent oxygen) to reduce detrimental oxide formation on the exposed surfaces of the coated particles. In some instances, the gas within the chamber 32 is maintained at a low oxygen content that does not expose the coated particles 22 to atmospheric oxygen levels. In some instances, the gas within the chamber 32 is maintained at a low oxygen level of less than 20 volume percent (vol %). In some instances, the gas within the chamber 32 is maintained at a very low oxygen level of less than about 1 mole % (mol %) oxygen; less than about 0.5 mol % oxygen; less than about 0.3 mol % oxygen; less than about 0.1 mol % oxygen; less than about 0.01 mol % oxygen; or less than about 0.001 mol % oxygen.

By controlling the oxygen level in the chamber 32, oxide formation on exposed surfaces of the coated particles 22 is beneficially minimized, reduced, or even eliminated. For example, the formation of silicon oxides (e.g., silicon oxide, silicon dioxide) on the exposed surfaces of the silicon coated particles 22 is advantageously minimized, reduced, or even eliminated. In such an example, the silicon coated particles 22 can have a silicon oxides content of less than about 500 parts per million by weight (ppmw); less than about 100 ppmw; less than about 50 ppmw; less than about 10 ppmw; or less than about 1 ppmw.

At times, the one or more thermal energy emission devices 14 may be disposed proximate the lower surface of the bottom of the pan 12. For example, the one or more thermal energy emission devices may be disposed internal to the bottom of the pan 12. In other instances, the one or more thermal energy emission devices may be disposed proximate the lower surface of the bottom of the pan 12 in a sealed container or covered in an insulative blanket or similar insulative material. The thermally insulating material 16 or insulative blanket may be deposited about all sides of the one or more thermal energy emission devices 14 except for the portion of the one or more thermal energy emission devices 14 forming a portion of the pan 12. The thermally insulating material 16 may, for instance be a glass-ceramic material (e.g., Li₂O×Al₂O₃×nSiO₂-System or LAS System) similar that used in “glass top” stoves where the electrical heating elements are positioned beneath a glass-ceramic cooking surface. In some situations, the thermally insulating material 16 may include one or more rigid or semi-rigid refractory type materials such as calcium silicate.

Each of the plurality of coated particles 22 includes deposits or layers that include substantially pure second chemical species. At times, the coated particles 22 display morphology similar to an agglomeration of smaller second chemical species sub-particles. As mentioned previously, it has been observationally noted that the plurality of coated particles 22 tend to rise through and “float” on the surface of the mechanically fluidized particulate bed 20, particularly as the diameter of the coated particle increases.

Some or all of the plurality of coated particles 22 may be removed or extracted from the mechanically fluidized particulate bed 20 via overflow. In some instances, such coated particles 22 may overflow all or a portion of the perimeter wall 12c of the pan 12. In other instances, such coated particles 22 may overflow into one or more open-ended, hollow, coated particle overflow conduits 132 positioned at one or more defined locations in the pan 12 and projecting a defined distance above the upper surface 12a of the bottom of the pan 12. Regardless of the removal mechanism, the coated particle collection system 130 collects the plurality of coated particles 22 separated from the mechanically fluidized particulate bed 20. Collection of the coated particles 22 in the coated particle collection system 130 occurs continuously, intermittently, and/or periodically.

The one or more thermal energy emission devices 14 provide thermal energy to the mechanically fluidized particulate bed 20 sufficient to increase the temperature in the mechanically fluidized particulate bed 20 above the thermal decomposition temperature of the first gaseous chemical species. In some instances, the thermal energy emission devices 14 transfer thermal energy to the mechanically fluidized particulate bed 20 via conductive heat transfer, convective heat transfer, radiant heat transfer, or combinations thereof. In one instance, the one or more thermal energy emission devices 14 can be disposed proximate at least a portion of the pan 12, for example proximate all or a portion of the bottom of the pan 12. At times, the one or more thermal energy emission devices 14 used to increase the temperature of the mechanically fluidized particulate bed 20 above the thermal decomposition temperature of the first gaseous chemical species can include one or more resistive heaters, one or more radiant heaters, one or more convective heaters or combinations thereof. At times, the one or more thermal energy emission devices 14 may include one or more circulated heat transfer systems, for example one or more molten salt or thermal oil based heat transfer systems.

A transmission system 50 is physically and operably coupled to the pan 12 via one or more oscillatory transmission members 52. Although the oscillatory transmission member 52 is shown attached to the bottom surface of the pan 12 in FIG. 1, the oscillatory transmission member 52 may be operably coupled to any surface of the pan 12. One or more stiffening members 15 may be disposed about the lower surface 12b or about other surfaces of the pan 12 to increase rigidity and reduce operational flexing of the pan 12. In some instances, the one or more stiffening members 15 may be disposed on the upper surface of the pan 12a to improve the rigidity of the pan 12, or to improve the fluidization or flow characteristics of the mechanically fluidized particulate bed 20.

In at least some implementations, one or more thermal energy transfer devices 57 may be physically and/or thermally coupled to the transmission member 52 to transfer thermal energy from the transmission member 52. In some instances, the one or more thermal energy transfer devices 57 can include one or more passive thermal energy transfer devices, for example, one or more extended surface area heat sinks. In some instances, the one or more thermal energy transfer devices 57 can include one or more active thermal energy transfer devices, for example one or more coils and/or jackets through which a heat transfer media circulates.

The transmission system 50 is used to oscillate or vibrate the pan 12 along the one or more axes of motion 54a-54n (collectively, “one or more axes of motion 54”). FIG. 1 depicts a single axis of motion 54a that is perpendicular to the upper surface 12a of the bottom of the pan 12. The transmission system 50 includes any system, device, or any combination of systems and devices capable of providing an oscillatory or vibratory displacement of the pan 12 along the one or more axes of motion 54. In at least some instances, the one or more axes of motion 54 include a single axis that is normal (i.e., perpendicular) to the upper surface of the bottom of pan 12. The transmission system 50 can include at least one electrical system, mechanical system, electromechanical system, or combinations thereof capable of oscillating or vibrating the pan 12 along the one or more axes of motion 54. One or more bushings 56a, 56b (collectively, “bushings 56”) substantially align the vibratory or oscillatory motion of the pan 12 along the one or more axes of motion 54.

At times, the bushings 56 also restrict, constrain, or otherwise limit the uncontrolled or unintended displacement of the pan 12 either laterally or in other directions that are not aligned with the one or more axes of motion 54. Maintaining the vibratory or oscillatory motion of the pan 12 in substantial alignment with the one or more axes of motion 54 advantageously reduces the likelihood of forming of “fines” within the mechanically fluidized particulate bed 20. Additionally, maintaining the vibratory or oscillatory motion of the pan 12 in substantial alignment with the one or more axes of motion 54 advantageously increases the uniformity of coated particle distribution in the pan 12, thereby improving the overall conversion, yield, or particle size distribution within the particulate bed 20. Limiting the formation of ultra-small particles within the mechanically fluidized particulate bed 20 increases the overall yield of the second chemical species by increasing the available quantity of second chemical species for deposition on the particulates in the mechanically fluidized particulate bed 20. As used in this context, “ultra-small particles” represent those particles having physical properties such that they are removed from the mechanically fluidized particulate bed 20 by entrainment in the exhaust gas exiting the bed. Such “ultra-small particles” may have diameters, for example, of less than about 1 micron or less than about 5 microns.

The first bushing 56a is disposed about the oscillatory transmission member 52 and includes an aperture through which the oscillatory transmission member 52 passes. In some instances, the first bushing 56a may be disposed about the oscillatory transmission member 52 proximate the vessel wall 31. In other instances the first bushing 56a may be disposed about the oscillatory transmission member 52 remote from the vessel wall 31.

In some instances, a second bushing 56b is disposed along the one or more axes of motion 54 at a location remote from the first bushing 56a. The second bushing 56b also includes an aperture through which the oscillatory transmission member 52 passes. Such a spaced arrangement of the bushings 56 with passages aligned along the one or more axes of motion 54 assists in maintaining the alignment of the oscillatory transmission member 52 along the one or more axes of motion 54. Further, the spaced arrangement of the bushings 56 also advantageously limits or constrains the motion or displacement of the oscillatory transmission member 52 in directions other than the one or more axes of motion 54.

Any number of electrical, mechanical, electromagnetic, or electromechanical drivers 58 can be operably coupled to the oscillatory transmission member 52. In at least some situations, the driver can include an electromechanical system comprising a prime mover such as a motor 58, coupled to a cam 60 or similar device that is capable of providing a regular, repeatable, oscillatory or vibratory motion via a linkage 62 to the oscillatory transmission member 52. The transmission member 52 communicates the oscillatory or vibratory motion to the pan 12 via one or more couplings linking the oscillatory transmission member 52 to the pan 12.

In one illustrative embodiment, the one or more permanent magnets may be coupled or otherwise physically affixed to the pan 12. One or more electromagnetic force producing drivers may be disposed external to the reactor 30. The changes in the electromagnetic force producing drivers positioned external to the reactor 30 may cause a cyclical displacement of the magnets coupled to the pan 12, thereby oscillating the pan and fluidizing the particulate bed 20 thereupon.

The oscillation or vibration of the pan 12 along the one or more axes of motion 54 may occur at one or at any number of frequencies and have any displacement. At times, the pan 12 oscillates or vibrates at a first frequency for a first interval and at a second frequency for a second interval. In some instances, the second frequency may be 0 Hz (i.e., no oscillatory motion) thereby creating a cycle where the pan 12 is oscillated at the first frequency for the first interval and remains stationary for the second interval. The first interval can have any duration and may be shorter or longer than the second interval.

In at least some instances, the pan 12 can have a frequency of oscillation or vibration of from about 1 cycle per second (Hz) to about 4,000 Hz; about 500 Hz to about 3,500 Hz; or about 1,000 Hz to about 3,000 Hz.

The oscillatory or vibratory magnitude and direction of the pan 12 may, at times, lie along a single axis of motion 54a, for example an axis that is substantially normal (i.e., perpendicular) to the upper surface 12a of the bottom of the pan 12. At other times, the oscillatory or vibratory magnitude and direction of the pan 12 may include components that lie along two orthogonal axes of motion 54a, 54b. For example, the oscillatory or vibratory magnitude and direction of the pan 12 may include a first component in a direction along the first axis of motion 54a and having a magnitude normal to the upper surface of the bottom of the pan 12 (i.e., a vertical component) and a second component in a direction along the second axis of motion 54b (not shown in FIG. 1) and having a magnitude parallel to the upper surface of the bottom of the pan 12 (i.e., a horizontal component). At times, a horizontal component that is lesser in magnitude than the vertical component has been found to advantageously assist in the selective removal of coated particles from the mechanically fluidized particulate bed 20.

Further, the magnitude of the oscillatory or vibratory displacement of the pan 12 along the one or more axes of motion 54 may be fixed or varied based at least in part upon the desired properties of the second chemical species coating the particles in the mechanically fluidized particulate bed 20. In at least some instances, the pan 12 can have an oscillatory or vibratory displacement of from about 0.01 inches (0.3 mm) to about 2.0 inches (50 mm); 0.01 inches (0.3 mm) to about 0.5 inches (12 mm); or from about 0.015 inches (0.4 mm) to about 0.25 inches (6 mm); or from about 0.03 inches (0.8 mm) to about 0.125 inches (3 mm). In at least one implementation, the displacement of the pan 12 may be about 0.1 inches. In at least some instances, either or both the frequency of the oscillation or vibration of the pan 12 or the oscillatory or vibratory displacement of the pan 12 may be continuously adjustable over one or more ranges or values, for example using the control system 190. Altering or adjusting the frequency or displacement of the oscillation or vibration of the pan 12 can provide conditions conducive to the deposition of a second chemical species having a preferred depth, structure, composition, or other physical or chemical properties, on the surface of the particles in the mechanically fluidized particulate bed 20.

In some instances, a bellows or boot 64 is disposed about the oscillatory transmission member 52. In some instances, an internal gas seal 65 may be disposed about the oscillatory transmission member 52. The boot 64 can be fluidly coupled to the vessel 30, for example at the vessel wall 31, the oscillatory transmission member 52, or both the vessel 30 and the oscillatory transmission member 52. The boot 64 isolates the lower portion of the chamber 34 from exposure to the external environment 39 about the vessel 30. In some instances, the boot 64 can be replaced or augmented using a shaft seal 65to prevent the emission of gas from the lower portion of the chamber 34 to the external environment 39. The boot 64 provides a secondary sealing member (in addition to the flexible membrane 42 and shaft seal 65) that prevents the escape of the gas containing the first chemical species to the external environment 39. In some instances, the first chemical species can include silane which is pyrophoric at atmospheric oxygen levels such as those typically found in the external environment 39. In such an instance, the second seal provided by the boot 64 can minimize the likelihood of a leak to the external environment even in the event of a failure of the flexible membrane 42 and shaft seal 65.

In some instances, the boot 64 can include a bellows-type seal or a similar flexibly pleated membrane-like structure. In other instances, the boot 64 can include an elastomeric flexible-type coupling or similar elastomeric membrane-like structure. A first end of the boot 64 may be temporarily or permanently affixed, attached, or otherwise bonded to the exterior surface of the vessel wall 31 and the second end of the boot 64 may be similarly temporarily or permanently affixed, attached, or otherwise bonded to a ring 66 or similar structure on the oscillatory transmission member 52. At times, one or more gas detection devices responsive to the first gaseous chemical species (not shown in FIG. 1) may be disposed at a location internal to the lower chamber 34 or at a location external to the boot 64 to detect leakage of the first gaseous chemical species from the upper chamber 33 of the reaction vessel 30.

To improve the permeation of the first gaseous chemical species into the particulate bed 20, the particulate bed 20 is mechanically fluidized to increase the volume of the bed and increase the distance between the particles (i.e., the number or size of the interstitial voids between the particulates) forming the mechanically fluidized particulate bed 20. Additionally, the mechanical fluidization of the particulate bed 20 causes the particulates within the bed to flow and circulate throughout the bed, thereby drawing the first gaseous chemical species throughout the bed and hastening the permeation and mixing of the first chemical species with the plurality of particulates forming the mechanically fluidized particulate bed 20. The intimate contact achieved between the first gaseous chemical species and the heated particulates forming the mechanically fluidized particulate bed 20 results in the thermal decomposition of at least a portion of the first gaseous chemical species within the mechanically fluidized particulate bed 20. The intimate proximity of the first gaseous chemical species to the particulate bed 20 causes at least a portion of the non-volatile second chemical species to deposit on the exterior surface of the particles forming the mechanically fluidized particulate bed 20. Further, the fluid nature of the fluidized particulate bed 20 permits gaseous byproducts (e.g., a third gaseous chemical species such as hydrogen) to escape from the particulate bed 20.

An initial charge of small diameter “seed particulates” are initially added to the pan 12 to form the plurality of particulates on which the second chemical species deposits. In operation, additional fine particulates, or “fines,” may be formed within the particulate bed 20 by the abrasion and fracturing of the particles in the particulate bed 20 and/or spontaneous self-nucleation of the second chemical species (e.g., polysilicon seeds) from the first gaseous chemical species. At times, such autonomously or spontaneously formed particulate “fines” are sufficient to replace the particulate volume lost from the mechanically fluidized particulate bed 20 in the form of coated particles 22.

At times, it is particularly advantageous to retain the particulate fines generated by spontaneous self-nucleation and physical abrasion within the mechanically fluidized particulate bed 20 to provide additional second chemical species deposition sites and/or to reduce dust formation within the housing 30: The retention of such small diameter particulate fines in the mechanically fluidized particulate bed 20 is attributable, in whole or in part, to the relatively low first gaseous chemical species flow rate or flow velocity through the mechanically fluidized particulate bed 20. The retention of smaller diameter fine particulates in the mechanically fluidized particulate bed 20 can beneficially minimize, reduce, or even eliminate the need to feed seed particulates from an external source such as the particulate feed system 90.

Since traditional hydraulically fluidized particulate beds rely upon relatively high superficial gas flow rates or velocities to suspend the particulates and create the fluidized bed, the low gas velocities possible in a mechanically fluidized particulate bed 20 are simply not possible. Thus a mechanically fluidized particulate bed 20 can provide a significant advantage over hydraulically fluidized beds by retaining small diameter particulate fines. For example, a mechanically fluidized particulate bed 20 may retain particulate fines having particulate diameters as small as 1 micrometer (μm); 5 μm; 10 μm; 20 μm; 30 μm; 50 μm; 70 μm; 80 μm; 90 μm; or 100 μm; while a hydraulically fluidized particulate bed may only retain particulates having particulate diameters in excess of 100 μm; 150 μm; 200 μm; 250 μm; 300 μm; 350 μm; 400 μm; 450 μm; 500 μm; or 600 μm.

At other times, spontaneous self-nucleation of particulates in the mechanically fluidized particulate bed 20 may be insufficient to make-up for the particulates lost in the plurality of coated particles 22. In such instances, the particle supply system 90 may provide additional, new, particulates to the mechanically fluidized particulate bed 20 on a periodic, intermittent, or continuous basis.

Sometimes, it is advantageous to remove at least a portion of very fine particulates, for example those whose diameter is smaller than 10 micrometers (μm), from the mechanically fluidized bed reactor 10. Such particulate fine removal may be at least partially accomplished, for example, by removing and filtering at least a portion of the gas present in the upper portion 33 of the chamber 32 on an intermittent, periodic, or continuous basis. Such removal may also be at least partially accomplished, for example, by filtering at least a portion of the exhaust gas removed from the upper portion 33 of the chamber 32. Selective removal from system 100 of fines, for example based on particulate, particle, or fine diameter, may be accomplished by filtration of the gas mixture or the exhaust gas. The selective presence of fines in the exhaust gas removed from the upper chamber 33 of the reactor 30 may be caused by entrainment of the fines in the off-gas exiting the mechanically fluidized particulate bed 20. For example, by controlling the velocity of the off-gas exiting the mechanically fluidized bed 20, fines having a particular range of diameters may be selectively removed from the mechanically fluidized particulate bed 20 and carried, entrained in the exhaust gas, into the upper portion 33 of the chamber 32. For example, increasing the off-gas velocity from the mechanically fluidized particulate bed 20 tends to entrain and remove larger diameter fine particles from the mechanically fluidized particulate bed 20. Conversely, decreasing the off-gas velocity from the mechanically fluidized particulate bed 20 tends to entrain and remove move smaller diameter fine particles from the mechanically fluidized particulate bed 20.

Product in the form of the plurality of coated particles 22 is removed periodically, intermittently, or continuously from the mechanically fluidized particulate bed 20. At times such coated particles 22 are selectively removed from the mechanically fluidized particulate bed 20 based on one or more physical properties, such as a coated particles 22 having a diameter in excess of a defined value (e.g., greater than about 100 micrometers (μm): greater than about 500 micrometers (μm); greater than about 1000 micrometers (μm); greater than about 1500 micrometers (μm)). In other instances, a physical property such as coated particle density may be used to selectively remove the coated particles 22 from the mechanically fluidized particulate bed 20.

As mentioned above, somewhat unexpectedly, coated particles 22 having a larger diameter (i.e., those having greater deposits of the second chemical species) tend to “rise” within the bed 20 and “float” on the surface of the mechanically fluidized particulate bed 20 while particulates having a smaller diameter (i.e., those having lesser deposits of the second chemical species) tend to “sink” and are consequently retained within the bed 20. In some instances, this effect can be enhanced by placing an electrostatic charge on all or a portion of the pan 12 to attract the smaller particulates towards the pan 12 and thus to the bottom of the bed 20. Attracting smaller particulates to the bottom of the pan beneficially retains smaller particles or fines within the bed 20 and reduces the transfer of fine particulates from the mechanically fluidized particulate bed 20 to the upper chamber 33.

A partitioning system 40 partitions the chamber 32 into the upper portion 33 and the lower portion 34. The partitioning system 40 includes a flexible member 42 that is physically affixed, attached, or coupled 44 to the pan 12 and physically affixed, attached or coupled 46 to the reaction vessel 30. In at least some implementations, the flexible member 42 hermetically seals the upper chamber 33 from the lower chamber 34. The flexible member 42 apportions the chamber 32 such that the upper surface of the pan 12a is exposed to the upper portion of the chamber 33 and not to the lower portion of the chamber 34. Similarly, the lower surface of the pan 12b is exposed to the lower portion of the chamber 34 and not to the upper portion of the chamber 33.

To accommodate the relative motion between the pan 12 and the reaction vessel 30, the flexible member 42 can include a material or be of a geometry and/or construction able to withstand the potentially extended and repeated oscillation or vibration of the pan 12 along the one or more axes of motion 54. In some instances, the flexible member 42 can be of a bellows type construction that accommodates the displacement of the pan 12 along the one or more axes of 54. In other instances, the flexible member 42 can include a “boot” or similar flexible coupling or membrane that incorporates or includes a resilient material that is both chemically and thermally resistant to the physical and chemical environment in both the upper 33 and lower 34 portions of the chamber 32. In some implementations, the flexible member 42 can be insulated to retain heat within the upper chamber 33 and/or to limit the transfer of heat from the upper chamber 33 to the lower chamber 34. The insulation is on the 34 side of the flexible member 42. In at least some implementations, the insulation is on the side of the flexible member 42 exposed to the lower chamber 34. Such positioning advantageously precludes contamination of the mechanically fluidized particulate bed 20 by the insulation.

In at least some instances, the flexible member 42 may be in whole or in part a flexible metallic member, for example a flexible 316SS member. In at least some embodiments, the physical coupling 46 of the flexible member 44 to the reaction vessel 30 may include a flange or similar structure adapted for insertion between two or more reaction vessel 30 mating surfaces, for example between the flanges 36 as shown in FIG. 1. The physical coupling 44 between the flexible membrane 42 and the pan 12 can be made along one or more of: the upper surface of the pan 12a, the lower surface of the pan 12b, or the perimeter wall of the pan 12c. In some instances, all or a portion of the flexible member 42 may be integrally formed with at least a portion of the pan 12 or at least a portion of the reaction vessel 30. In some instances, where some or all of the flexible member 42 comprises a metallic member, the flexible membrane 42 may be welded or similarly thermally bonded to the pan 12 the vessel 30, or both the pan 12 and the vessel 30.

Gases, including the first gaseous chemical species and, optionally, one or more diluent(s) may be added to the upper chamber 33 either individually or as a bulk gas mixture. In some instances, only the first gaseous chemical species is added to the upper chamber 33. In some instances, some or all of the first gaseous chemical species and some or all of any optional diluents are added via a fluid conduit 84 that fluidly couples the upper chamber 33 to the first gaseous chemical species feed system 72 and to the one or more diluent(s) feed systems 78. At times, the first gaseous chemical species and the optional diluent are mixed and supplied via the fluid conduit 84 to the upper portion of the chamber 33 as a bulk gas mixture by the gas supply system 70.

Although depicted as feeding from above the mechanically fluidized particulate bed 20 through the upper chamber 33, the fluid conduit 84 may also feed from below the mechanically fluidized particulate bed 20 passing through the lower chamber 34. Feeding the first gaseous chemical species and the one or more diluent(s) from below, through the lower chamber 34, may advantageously permit the passage of the first gaseous chemical species via the fluid conduit 84 through the relatively low temperature lower chamber 84. Passing the first gaseous chemical species through the relatively low temperature lower chamber beneficially reduces the likelihood of thermal decomposition of the first gaseous chemical species outside of the mechanically fluidized particulate bed 20.

The bulk gas mixture supplied to the upper portion of-the chamber 33 produce a pressure that is measurable, for example using a pressure transmitter 176. If pressure were permitted to build within only the upper portion of the chamber 33 the amount of force required from the transmission system 50 to oscillate or vibrate the pan 12 along the one or more axes of motion 54 would increase as the pressure of the bulk gas mixture in the upper portion of the chamber 33 is increased due to the pressure exerted by the gas in the upper chamber 33 on the upper surface of the pan 12a. To reduce the force required to oscillate or vibrate the pan 12, an inert gas or inert gas mixture may be introduced to the lower portion of the chamber 34 using an inert gas supply system 150. Introducing an inert gas into the lower portion of the chamber 34 can reduce the pressure differential between the upper portion of the chamber 33 and the lower portion of the chamber 34. Reducing the pressure differential between the upper portion of the chamber 33 and the lower portion of the chamber 34 reduces the output force required from the transmission system 50 to oscillate or vibrate the pan 12.

The pan 12 oscillates or vibrates and mechanically fluidizes the plurality of particulates carried by the upper surface 12a of the bottom of the pan 12. The repetitive motion of the oscillatory transmission member 52 through the bushing 56a can create contaminants during normal operation. Such contaminants may include, inter alia, shavings from or pieces of the bushing 56a, metallic shavings from the oscillatory transmission member 52, and the like which may be expelled into the chamber 32. In the absence of the flexible member 44, such contaminants expelled into the chamber 32 may enter the mechanically fluidized particulate bed 20, potentially contaminating all or a portion of the plurality of coated particles 22 contained therein. The presence of the flexible member 44 therefore reduces the likelihood of contamination within the mechanically fluidized particulate bed 20 from metal or plastic shavings, lubricants, or similar debris or materials generated as a consequence of the routine operation of the transmission system 50.

The inert gas supply system 150 that is fluidly coupled to the lower chamber 34 can include an inert gas reservoir 152, any number of fluid conduits 154, and one or more inert gas final control elements 156, such as one or more flow or pressure control valves. The inert gas final control elements 156 are adjusted, controlled or otherwise modulated to maintain a desired inert gas pressure within the lower chamber 34. The one or more inert gas final control elements 156 can modulate, regulate, or otherwise control the admission rate or pressure of the inert gas in the lower portion of the chamber 34. The inert gas provided from the inert gas reservoir 152 can include one or more gases displaying non-reactive properties in the presence of the first chemical species. In some instances, the inert gas can include, but is not limited to, at least one of: argon, nitrogen, or helium. The inert gas introduced to the lower portion of the chamber 34 can be at a pressure of from about 5 psig to about 900 psig; from about 5 psig to about 600 psig; from about 5 psig to about 300 psig; from about 5 psig to about 200 psig; from about 5 psig to about 150 psig; or from about 5 psig to about 100 psig.

In some implementations, the pressure of the inert gas in the lower chamber 34 is greater than the pressure of the gas in the upper chamber 33. In various implementations, the control system 190 may maintain the gas pressure in the lower chamber 34 at a level greater than the gas pressure in the upper chamber 33, by about 10 inches of water or less (0.02 atm.); about 20 inches of water (0.04 atm.) or less; about 1.5 psig (0.1 atm.) differential or less; about 5 psig (0.3 atm.) differential or less; about 10 psig (0.7 atm.) differential or more; about 25 psig (1.7 atm.) differential or more; about 50 psig (3.4 atm.) differential or more; about 75 psig (5 atm.) differential or more; or about 100 psig (7 atm.) differential or more. In one specific embodiment, the pressure in the lower chamber 34 may be about 600 psig (40 atm.) and the pressure in the upper chamber 33 can be about 550 psig (37.5 atm.). By maintaining the pressure in the lower chamber 34 at a level greater than the pressure in the upper chamber 33, any breach of or leakage through the flexible membrane 42 will result in passage of the inert gas from the lower chamber 34 to the upper chamber 33.

In some instances, an analyzer or detector responsive to at least the inert gas in the lower chamber 34 may be placed in or fluidly coupled to the upper chamber 33. Detection of inert gas leakage to the upper chamber 33 can indicate a failure of the flexible member 42. Beneficially, the lower pressure of the gas in the upper chamber 33 prevents the escape of the potentially flammable first gaseous chemical species to the lower chamber 34. In some instances, an analyzer or detector responsive to the inert gas in the lower chamber 34 may be placed in the exterior environment 39 about the vessel 10 to detect an external leak of non-reactive gas from the lower chamber 34.

In other implementations, the pressure of the inert gas in the lower chamber 34 is less than the pressure of the gas in the upper chamber 33. In various implementations, the control system 190 may maintain the gas pressure in the upper chamber 33 at a level lower than the gas pressure in the lower chamber 34, by about 10 inches of water or less (0.02 atm.); about 20 inches of water (0.04 atm.) or less; about 1.5 psig (0.1 atm.) differential or less; about 5 psig (0.3 atm.) differential or less; about 10 psig (0.7 atm.) differential or less; about 25 psig (1.7 atm.) differential or less; about 50 psig (3.4 atm.) differential or less; about 75 psig (5 atm.) differential or less; or about 100 psig (7 atm.) differential or less. In one specific embodiment, the pressure in the lower chamber 34 may be about 600 psig (40 atm.) and the pressure in the upper chamber 33 can be about 550 psig (37.5 atm.). In an illustrative embodiment, the pressure in the lower chamber 34 may be about 600 psig (40 atm.) and the pressure in the upper chamber 33 can be about 550 psig (37.5 atm.). By maintaining the pressure in the upper chamber 33 at a level lower than the pressure in the lower chamber 34, any breach of or leakage through the flexible membrane 42 will result in passage of the gas from the lower chamber 34 to the upper chamber 33. By maintaining the upper chamber 33 at a lower pressure than the lower chamber 34 the reactive gas from the upper chamber 33 cannot enter the lower chamber with its moving parts and pressure sealing systems.

In some instances, an analyzer or detector responsive to at least the gas in the lower chamber 34 may be placed in or fluidly coupled to the upper chamber 33. Detection of gas leakage to the upper chamber 33 can indicate a failure of the flexible member 42. In some instances, an analyzer or detector responsive to at least the gas in the upper chamber 33 may be placed in or fluidly coupled to the lower chamber 34. Detection of gas leakage to the lower chamber 34 can indicate a failure of the flexible member 42. In some instances, an analyzer or detector responsive to the gas in the upper chamber 33 may be placed in the exterior environment 39 about the vessel 10 to detect an external leak of gas from the upper chamber 33.

One or more temperature transmitters 175 measure the temperature of the inert gas in the lower chamber 34. At times, the temperature of the inert gas in the lower chamber 34 may be maintained below the thermal decomposition temperature of the first gaseous chemical species. Maintaining the temperature of the inert gas below the thermal decomposition temperature of the first gaseous chemical species can advantageously reduce the likelihood of second chemical species deposition on the flexible member 44 since the relatively cool inert gas will tend to limit the buildup of heat within the flexible member 44 during routine operation of the system 100. Further, it prevents the seals on the drive mechanism from over-heating resulting in seal failure. The temperature of the inert gas in the lower section 34 can be controlled by means of cooling coils placed inside the lower section 34, cooled by a cooling medium. It can also be controlled by introducing the inert gas to the lower chamber 34 at a temperature of from about 25° C. to about 375° C.; from about 25° C. to about 300° C.; from about 25° C. to about 225° C.; from about 25° C. to about 150° C.; or from about 25° C. to about 75° C. At times, the inert gas introduced to the lower chamber 34 can be at a temperature of less than the thermal decomposition temperature of the first gaseous chemical species. At such times, the inert gas introduced to the lower chamber 34 can be at least about 100° C.; at least about 200° C.; at least about 300° C.; at least about 400° C.; at least about 500° C.; or at least about 550° C. below the thermal decomposition temperature of the first gaseous chemical species.

One or more temperature transmitters 180 measure the temperature of the gas in the upper chamber 33. At times, the temperature of the gas in the lower chamber 33 may be maintained below the thermal decomposition temperature of the first gaseous chemical species. Maintaining the temperature of the gas below the thermal decomposition temperature of the first gaseous chemical species can advantageously reduce the likelihood of second chemical species deposition on surfaces external to the mechanically fluidized bed 20 since the relatively cool gas will tend to limit surface temperatures within the upper chamber 33 during routine operation of the system 100. The temperature of the inert gas in the upper section 33 can be controlled by means of cooling coils placed inside the upper section 33, cooled by a cooling medium. It can also be cooled by means of cooling fins place on the external wall of vessel 30.

Gas in the upper chamber 33 can be at a temperature of from about 25° C. to about 500° C.; from about 25° C. to about 300° C.; from about 25° C. to about 225° C.; from about 25° C. to about 150° C.; or from about 25° C. to about 75° C. At times, the gas in the upper chamber 33 can be at a temperature of less than the thermal decomposition temperature of the first gaseous chemical species. At such times, the gas in the upper chamber 33 can be at least about 100° C.; at least about 200° C.; at least about 300° C.; at least about 400° C.; at least about 500° C.; or at least about 550° C. below the thermal decomposition temperature of the first gaseous chemical species.

One or more differential pressure measurement systems 170 monitor and if necessary, control the pressure differential between the upper chamber 33 and the lower chamber 34. At times, the differential pressure measurement systems 170 maintains the maximum differential pressure between the upper chamber 33 and the lower chamber 34 below the maximum working differential pressure of the flexible member 44. As discussed above, an excessive differential pressure between the upper chamber 33 and the lower chamber 34 can increase the force and consequently the power required to oscillate or vibrate the pan 12. The differential pressure system 170, including a lower chamber pressure sensor 171 and an upper chamber pressure sensor 172 coupled to a differential pressure transmitter 173 can be used to provide a process variable signal indicative of the pressure differential between the upper chamber 33 and the lower chamber 34. The differential pressure between the upper chamber 33 and the lower chamber 34 can be maintained at less than about 25 psig; less than about 10 psig; less than about 5 psig; less than about 1 psig; less than about 20 inches of water; or less than about 10 inches of water.

The differential pressure between the upper chamber 33 and the lower chamber 34 of the chamber 32 can be monitored, adjusted, and/or controlled by the control system 190. For example, the control system 190 may adjust the pressure in the upper chamber 33 by adjusting the flow or pressure of the first gaseous chemical species and/or the optional diluent to the upper chamber 33 by modulating or controlling final control elements 76 or 82, respectively, or by modulating or controlling exhaust valve 118. The control system 190 may adjust the pressure in the lower chamber 34 by adjusting the flow or pressure of the inert gas introduced to the lower chamber 34 from the inert gas reservoir 152 by modulating or controlling final control element 156.

The one or more thermal energy emission devices 14 may take a variety of forms, for example one or more radiant or resistive elements that emit or otherwise produce thermal energy in the form of heat in response to the passage of an electrical current provided by a source 192. The one or more thermal energy emission devices 14 increase the temperature of mechanically fluidized particulate bed 20 carried by the pan 12 via the conductive, convective, and/or radiant transfer of thermal energy provided by the one or more thermal energy emission devices 14. The one or more thermal energy emission devices 14 may for instance, be similar to the nickel/chrome/iron (“nichrome” or Calrod®) electric coils commonly found in electric cook top stoves, or immersion heaters.

One or more temperature transmitters 178 measure the temperature of the mechanically fluidized particulate bed 20. In some instances, the control system 190 may variably adjust the current output of the source 192 responsive to the measured temperature of the mechanically fluidized particulate bed 20, to maintain a particular bed temperature. The control system 190 can maintain the mechanically fluidized particulate bed 20 at or above a particular temperature that is greater than the thermal decomposition temperature of the first chemical species at the measured process conditions (e.g., pressure, gas composition, etc.) in the upper chamber 33.

For example, where the first chemical species comprises silane and the measured gas pressure within the upper chamber 33 is about 175 psig (12 atm.), a temperature of about 550° C. will result in the thermal decomposition of the silane and the deposition of polysilicon (i.e., the second chemical species) on the particles in the particulate bed 20. Where chlorosilanes form at least a portion of the first chemical species, a temperature commensurate with the thermal decomposition temperature of the particular chlorosilane or chlorosilane mixture is used.

Dependent at least in part on the composition of the first chemical species, the mechanically fluidized particulate bed 20 can be controlled to a range from a minimum temperature of about 100° C., about 200° C.; about 300° C.; about 400° C.; or about 500° C. to a maximum temperature of about 500° C.; about 600° C.; about 700° C.; about 800° C.; or about 900° C. In at least some instances, the temperature of the mechanically fluidized particulate bed 20 may be manually, semi-automatically, or automatically adjustable over one or more ranges or values, for example using the control system 190. Such adjustable temperature ranges provide a thermal environment within the particulate bed 20 conducive to the deposition of the second chemical species having a preferred thickness, structure, or composition on the surface of the particles in the mechanically fluidized particulate bed 20. In at least one implementation, the control system 190 maintains a first temperature in the mechanically fluidized particulate bed 20 (e.g., 650° C.) that is greater than the thermal decomposition temperature of the first gaseous chemical species and a temperature elsewhere in the upper chamber 33 and/or lower chamber 34 (e.g., 300° C.) that is below the thermal decomposition temperature of the first gaseous chemical species.

In some instances, a thermally reflective material may be included in the thermally insulating material 16 to reflect at least a portion of the thermal energy emitted by the one or more thermal energy emission devices 14 towards the pan 12.

In at least some instances, at least one thermally reflective member 18 may be located within the upper chamber 33 and positioned to return at least a portion of the thermal energy radiated by the mechanically fluidized particulate bed 20 back to the bed. Such thermally reflective members 18 may advantageously assist in reducing the quantity of energy consumed by the one or more thermal energy emission devices 14 in maintaining the temperature of the mechanically fluidized particulate bed 20. Additionally, the at least one thermally reflective member 18 may also advantageously assist in maintaining a temperature in the upper chamber 33 that is below the thermal decomposition temperature of the first chemical species by limiting the quantity of thermal energy radiated from the mechanically fluidized particulate bed 20 to the upper chamber 33. In at least some instances, the thermally reflective member 18 may be a polished thermally reflective stainless steel or nickel alloy member. In other instances, the thermally reflective member 18 may be a member having a polished thermally reflective coating comprising one or more precious metals such as silver or gold.

It is noted, however, that while called a thermally reflective member, the member 18 does not have to comprise a thermally reflective surface. It may serve to reduce heat flux to from bed 20 to upper section 33 by means of an insulation layer placed on the upper surface of member 18. This layer may be sealed inside a metal or, alternatively, a non-thermally conductive container to prevent contamination of the particulates and coated particles in the mechanically fluidized bed 20. Further, this layer may function in concert with a thermally reflective surface on the under-side of member 18.

In operation, the first chemical species (e.g., silane or one or more chlorosilanes) is transferred from the first chemical species reservoir 72 and optionally mixed with one or more diluent(s) (e.g., hydrogen) transferred from the diluent reservoir 78. The gas or bulk gas mixture is introduced to the upper chamber 33. Surfaces in the upper chamber 33 at temperatures exceeding the thermal decomposition temperature of the first gaseous chemical species promote the thermal decomposition of the first gaseous chemical species and the deposition of the second chemical species (e.g., polysilicon) on those surfaces. Thus, by maintaining the plurality of particulates in the mechanically fluidized particulate bed 20 at temperatures greater than the thermal decomposition temperature of the first gaseous chemical species, the first gaseous chemical species thermally decomposes within the mechanically fluidized particulate bed 20. The second chemical species deposits on the exterior surfaces of the plurality of particulates in the fluidized bed 20 to form the plurality of coated particles 22.

If the temperature of the upper chamber 33 and the various components within the upper chamber 33 are maintained below the thermal decomposition temperature of the first gaseous chemical species, then the likelihood of deposition of the second chemical species on those surfaces is reduced. Advantageously, if the temperature of the mechanically fluidized particulate bed 20 is the only location within the upper chamber 33 that is maintained above the decomposition temperature of the first chemical species, then the likelihood of deposition of the second chemical species within the mechanically fluidized particulate bed 20 is increased while the likelihood of deposition of the second chemical species outside of the particulate bed 20 is reduced.

In at least some instances, the control system 190 can vary or adjust the operation of the mechanically fluidized particulate bed 20 to advantageously alter or affect the yield, composition, or structure of the second chemical species deposited on the plurality of coated particles 22. At times, the control system 190 may oscillate the pan 12 at a displacement and/or frequency that minimizes the fluctuation in gas pressure in the upper chamber 33. The displacement volume of the pan 12 is given by the area of the bottom of the pan 12 multiplied by the displacement distance. For example, a 12 inch diameter circular pan having a displacement of one-tenth of an inch has a displacement volume of approximately 11.3 cubic inches. One method of minimizing the fluctuation in gas pressure in the upper chamber is to ensure the ratio of the volume of the upper chamber to the displacement volume exceeds a defined value. For example, to minimize the pressure fluctuation in the upper chamber 33 attributable to the oscillation of the pan 12, the ratio of the volume of the upper chamber to the displacement volume may exceed about 5:1; about 10:1; about 20:1; about 50:1; about 80:1; or about 100:1.

In other instances, the control system 190 may oscillate or vibrate the mechanically fluidized particulate bed 20 at a first frequency for a first interval, followed by stopping or halting the oscillation or vibration the bed for a second interval. Alternating an interval of bed circulation with a regular or irregular interval without bed circulation can advantageously promote the permeation of the first gaseous chemical species into the interstitial spaces within the plurality of particulates forming the mechanically fluidized particulate bed 20. When the oscillation or vibration of the particulate bed 20 is halted, all or a portion of the first gaseous chemical species can be trapped within the settled bed. The ratio of the first time (i.e., the time the bed is fluidized) to the second time (i.e., the time the bed is settled) can be less than about 10,000:1; less than about 5,000:1; less than about 2,500:1; less than about 1,000:1; less than about 500:1; less than about 250:1; less than about 100:1; less than about 50:1; less than about 25:1; less than about 10:1; or less than about 1:1.

In other instances, the control system 190 alters, adjusts, or controls at least one of an oscillatory frequency and/or an oscillatory displacement along at least one axis of motion. In one example, the control system 190 may alter, adjust, or control the oscillatory frequency of the pan 12 for example by adjusting the frequency upward or downward to achieve a desired coated particle 22 separation from the mechanically fluidized particulate bed 20. In another example, the control system 190 may alter, adjust, or control the oscillatory displacement of the pan 12 along a single axis of motion (e.g., an axis normal to the bottom of the pan 12) or along a plurality of orthogonal axes of motion (e.g., an axis normal to the bottom of the pan 12, and at least one axis parallel to the bottom of the pan 12).

In other implementations, the oscillation or vibration of the pan 12 is maintained more or less constant while the first gaseous chemical species is introduced to the upper chamber 33 and/or the mechanically fluidized particulate bed 20. The oscillatory displacement and/or oscillatory frequency of the pan 12 can be varied intermittently or continuously to favor the deposition of the second chemical species on the plurality of particles forming the mechanically fluidized particulate bed 20. The second chemical species deposits on the exterior surfaces of the plurality of particulates forming the mechanically fluidized particulate bed 20. All or a portion of the resultant plurality of coated particles 22 may be removed from the bed mechanically fluidized particulate bed 20 on a batch, semi-continuous, or continuous basis.

The particulate supply system 90 includes a particulate transporter 94, for example a conveyor, to deliver the fresh particulates 92 from the particulate reservoir 96 directly to the mechanically fluidized particulate bed 20 or one or more intermediate systems such as a particulate inlet system 98. In some embodiments, a particle feed vessel 102 in the particulate inlet system 98 may serve as a reservoir of fresh particulates 92.

The fresh particulates 92 may have any of a variety of forms. For example, the fresh particulates 92 may be provided as regularly or irregularly shaped particulates that serve as a nucleation points for the deposition of the second chemical species in the mechanically fluidized particulate bed 20. At times, the fresh particulates 92 may include particulates formed from the second chemical species. The fresh particulates 92 supplied to the mechanically fluidized particulate bed 20 can have a diameter of from about 0.01 mm to about 2 mm; 0.1 mm to about 2 mm; from about 0.15 mm to about 1.5 mm; from about 0.25 mm to about 1.5 mm; from about 0.25 mm to about 1 mm; or from about 0.25 mm to about 0.5 mm.

The sum of the surface areas of each of the particulates in the mechanically fluidized particulate bed 20 provides an aggregate bed surface area. In at least some instances, the quantity of particles added to the mechanically fluidized particulate bed 20 may be controlled, for example using the control system 190, to maintain a target ratio of aggregate bed surface area to the surface area of the upper surface of the pan bottom 12a. The aggregate bed surface area to surface area of the upper surface of the pan bottom 12a can be a ratio of from about 10:1 to about 10,000:1; about 10:1 to about 5,000:1; about 10:1 to about 2,500:1; about 10:1 to about 1,000:1; about 10:1 to about 500:1; or about 10:1 to about 100:1.

In other instances, the number of fresh particulates 92 added to the mechanically fluidized particulate bed 20 may be based on the overall area of the upper surface of the bottom of the pan 12a. It has been unexpectedly found that the size of the coated particles 22 produced in the mechanically fluidized particulate bed 20 operating at a given production rate, is a strong function of the number of fresh (i.e., seed) particulates 92 generated or added per unit time per unit area of the upper surface of the bottom of the pan 12a. In fact, the number of fresh particulates 92 added per unit time per unit area of the upper surface of the bottom of the pan 12a is at least one identified controlling factor establishing one or more physical properties (e.g., size or diameter) of the plurality of coated particles 22. The particulate supply system 90 can add particles to the particulate bed 20 at a rate of from about 1 particle/minute-square inch of upper surface 12a area (p/m-in²) to about 5,000 p/m-in²; about 1 particle/minute-square inch of upper surface 12a area (p/m-in²) to about 2,000 p/m-in²; about 1 particle/minute-square inch of upper surface 12a area (p/m-in²) to about 1,000 p/m-in²; about 2 p/m-in² to about 200 p/m-in²; about 5 p/m-in² to about 150 p/m-in²; about 10 p/m-in² to about 100 p/m-in²; or about 10 p/m-in² to about 80 p/m-in².

The particulate transporter 94 can include at least one of: a pneumatic feeder (e.g., a blower); a gravimetric feeder (e.g., a weigh-belt feeder); a volumetric feeder (e.g., a screw type feeder); or combinations thereof. In at least some instances, the volumetric or gravimetric delivery rate of the particulate transporter 94, may be continuously adjusted or varied over one or more ranges, for example the control system 190 may continuously control the weight or volume of fresh particulates 92 delivered by the particulate supply system 90 and by correlation with the weight of the average coated particle 22, the number of particulates added per unit time.

The particulate inlet system 98 receives fresh particulates 92 from the particulate transporter 94 and includes: a particulate inlet valve 104, a particulate feed vessel 102, and a particulate outlet valve 106. Particulates are discharged from the particulate transporter 94 through the particle inlet valve 104 and into the particulate feed vessel 102. The accumulated fresh particulates 92 may be discharged from the particle feed vessel 102 continuously, intermittently, or periodically via the particulate outlet valve 106. The particulate inlet valve 104 and the particulate outlet valve 106 can include any type of flow control device, for example one or more motor driven, variable speed, rotary valves.

In at least some instances, the fresh particulates 92 flowing into the upper portion of the chamber 33 are deposited in mechanically fluidized particulate bed 20 using a conduit or hollow member 108 such as a dip-tube, pipe, or the like. The control system 190 may coordinate or synchronize volume or weight of fresh particles 92 supplied by the particulate supply system 90 to the volume or weight of the coated particles 22 removed by the coated particle collection system 130. Using the control system 190 to coordinate or synchronize the feed rate of fresh particulates 92 to the mechanically fluidized particulate bed 20 with the removal rate of coated particles 22 from the mechanically fluidized particulate bed 20 provides a system capable of controlling the average particle diameter of discharged coated particles 22. Adding a greater amount of fresh particles—measured as the number of particles, the volumetric rate of particles, or the mass of particles measured as the number of particles, the volumetric rate of particles, or the mass of particles—decreases the average size of discharged particles 22.

The gas supply system 70 includes a first gaseous chemical species reservoir 72 containing the first gaseous chemical species. In some instances, the first gaseous chemical species reservoir 72 may be optionally fluidly coupled to a diluent reservoir 78 containing the one or more optional diluent(s). Where the first gaseous chemical species is provided to the mechanically fluidized particulate bed 20 as a mixture with the optional diluent gas, flow from each of the reservoirs 72, 78 mixes and enters the upper chamber 33 as a bulk gas mixture via the fluid conduit 84.

The gas supply system 70 also includes various conduits 74, 80, a first gaseous chemical species final control element 76, a diluent final control element 82, and other components that, for clarity, are not shown in FIG. 1 (e.g., blowers, compressors, eductors, block valves, bleed systems, environmental control systems, etc.). Such equipment and ancillary systems permit the delivery of the bulk gas mixture containing the first chemical species to the upper portion of the chamber 33 in a controlled, safe, and environmentally conscious manner.

The gas containing the first gaseous chemical species may optionally include one or more diluents (e.g., hydrogen) pre-mixed with the first gaseous chemical species. The first gaseous chemical species can include, but is not limited to silane, monochlorosilane, dichlorosilane, trichlorosilane, or tetrachlorosilane to provide a non-volatile second chemical species that includes silicon. However, other alternative gaseous chemical species may also be used, including gases or gas mixtures that upon decomposition provide a variety of non-volatile second chemical species such as silicon carbide, silicon nitride, or aluminum oxide (sapphire glass).

The one or more optional diluent(s) stored in the diluent reservoir 78 can be the same as or different from the third gaseous chemical species produced as a byproduct of the thermal decomposition of the first gaseous chemical species. Although hydrogen provides an illustrative optional diluent, other diluents may be used in the upper chamber 33. In at least some implementations, the one or more optional diluents may include one or more dopants such as arsenic and arsenic containing compounds, boron and boron containing compounds, phosphorus and phosphorus containing compounds, gallium and gallium containing compounds, germanium or germanium containing compounds, or combinations thereof.

Although shown in FIG. 1 as entering at the top of the upper chamber 33, the first gaseous chemical species and/or the bulk gas mixture may be introduced, in whole or in part, at any number of points and/or locations within the upper chamber 33. For example, at least a portion of the first gaseous chemical species and/or the bulk gas mixture may be introduced to the sides of the upper chamber 33. In another example, at least a portion of the first gaseous chemical species and/or the bulk gas mixture may be discharged directly into the mechanically fluidized particulate bed 20, for example using one or more flexible connections to a gas distributor located on the upper surface of the pan 12a. The first gaseous chemical species and/or bulk gas mixture may be added intermittently or continuously to the upper chamber 33 and/or the mechanically fluidized particulate bed 20. In at least some instances, the first gaseous chemical species and/or the bulk gas mixture is received by the mechanically fluidized particulate bed 20 via one or more apertures 10 in the thermally reflective member 18.

The control system 190 varies, alters, adjusts or controls the flow and/or pressure of the first gaseous chemical species and/or the bulk gas mixture to the upper chamber 33. One or more pressure transmitters 176 monitor gas pressure within the upper chamber 33. In one example, a first gaseous chemical species that includes silane gas is introduced to the upper chamber 33 and/or to the heated, mechanically fluidized particulate bed 20. As the silane thermally decomposes within the mechanically fluidized particulate bed 20, polysilicon deposits on the surface of the particulates in the mechanically fluidized particulate bed 20 to provide the plurality of coated particles 22. As the coated particles 22 increase in diameter the depth of the mechanically fluidized particulate bed 20 increases and at least some of the coated particles 22 fall into the coated particle overflow conduit 132.

In such an example, the control system 190 may introduce the first gaseous chemical species and optional dopants at a controlled rate to maintain a defined first gaseous chemical species partial pressure in the upper chamber 33 and/or in the mechanically fluidized particulate bed 20. In some instances, the first gaseous chemical species can have a partial pressure of from about 0 atmospheres (atm.) to about 40 atm. in the upper chamber 33 or in the mechanically fluidized particulate bed 20. In some instances, the optional diluent (e.g., hydrogen) can have a partial pressure of from about 0 atm. to about 40 atm in the upper chamber 33 or in the mechanically fluidized particulate bed 20. In some instances, the optional diluent can have a mole fraction of from about 0 mol % to about 99 mol % in the upper chamber 33 or in the mechanically fluidized particulate bed 20.

In some instances, the upper chamber 33 can be maintained at a pressure of from about 5 psia (0.33 atm.) to about 600 psia (40 atm.); from about 15 psia (1 atm.) to about 220 psia (15 atm.); from about 30 psia (2 atm.) to about 185 psia (12.5 atm.); or from about 75 psia (5 atm.) to about 175 psia (12 atm.). Within the upper chamber 33, the first gaseous chemical species can have a partial pressure of from about 0 psi (1 atm.) to about 600 psi (40 atm.); from about 5 psi (0.33 atm.) to about 150 psi (10 atm.); from about 15 psi (1 atm.) to about 75 psi (5 atm.); or from about 0.1 psi (0.01 atm.) to about 45 psi (3 atm.). Within the upper chamber 33, the one or more optional diluent(s) can be at a partial pressure of from about 1 psi (0.067 atm.) to about 600 psi (40 atm.); from about 15 psi (1 atm.) to about 220 psi (15 atm.); from about 15 psi (1 atm.) to about 150 psi (10 atm.); from about 0.1 psi (0.01 atm.) to about 220 psi (15 atm.); or from about 45 psi (3 atm.) to about 150 psi (10 atm.).

In one illustrative continuous operation example, the operating pressure within the upper chamber 33 is maintained at about 165 psia (11.2 atm.), with the partial pressure of silane (i.e., the first gaseous chemical species) in the off-gas from the upper section 33 maintained at about 0.5 psi (0.35 atm.), and the partial pressure of hydrogen (i.e., the diluent which can be as a third gaseous chemical species) maintained at about 164.5 psi (11.1 atm.). The diluent may be added as a feed gas to the upper chamber 33 or in the case of silane decomposition may be produced as a third gaseous chemical species byproduct of the thermal decomposition of silane according to the formula SiH₄→Si+2H₂.

The environment in the upper chamber 33, overflow conduit 132, and product receiver 130 is maintained at a low oxygen level (e.g., less than 20 volume percent oxygen) or a very low oxygen level (e.g., less than 0.001 mole percent oxygen to less than 1.0 mole percent oxygen). In some instances, the environment within the upper chamber 33 is maintained at a low oxygen content that does not expose the coated particles 22 to atmospheric oxygen. In some instances, the environment within the upper chamber 33, overflow conduit 132, and product receiver 130 is maintained at a low oxygen level of less than 20 volume percent (vol %). In some instances, the environment within the upper chamber 33 is maintained at a very low oxygen level of less than about 1 mole % (mol %) oxygen; less than about 0.5 mol % oxygen; less than about 0.3 mol % oxygen; less than about 0.1 mol % oxygen; less than about 0.01 mol % oxygen; or less than about 0.001 mol % oxygen.

Since the oxygen concentration in the upper chamber 33 is limited, oxide formation of the surface of the coated particles 22 is beneficially minimized or even eliminated. In one example, if the coated particles 22 include silicon coated particles, the formation of a layer containing silicon oxides (e.g., silicon oxide, silicon dioxide) is advantageously minimized or even eliminated. In such an example, the silicon coated particles 22 produced in the mechanically fluidized particulate bed 20 can have a silicon oxides content of less than about 500 parts per million by weight (ppmw); less than about 100 ppmw; less than about 50 ppmw; less than about 10 ppmw; or less than about 1 ppmw.

The control system 190 varies, alters, adjusts, modulates, and/or controls the composition of the gas in the upper chamber 33. The control system 190 makes such adjustments on an intermittent, periodic, or continuous basis to maintain any desired gas composition (i.e., first gaseous chemical species/optional diluent/third gaseous chemical species) in the upper chamber 33. In some instances, one or more gas analyzers (e.g., an online gas chromatograph) sample the gas composition in the upper chamber 33 on an intermittent, periodic, or continuous basis. The use of such analyzers may advantageously provide an indication of the conversion and rate at which the second chemical species deposits on in the mechanically fluidized particulate bed 20 and the quantity of third gaseous chemical species produced.

The control system 190 can intermittently, periodically or continuously adjust, alter, vary and/or control the flow or the pressure of either or both the first gaseous chemical species and the optional diluent added to the upper chamber 33 and/or the mechanically fluidized particulate bed 20. The control system 190 can maintain the concentration of the first gaseous chemical species in the upper chamber 33 and/or mechanically fluidized particulate bed 20 from about 0.1 mole percent (mol %) to about 100 mol %; about 0.5 mol % to about 50 mol %; from about 5 mol % to about 40 mol %; from about 10 mol % to about 40 mol %; from about 10 mol % to about 30 mol %; or from about 20 mol % to about 30 mol %. The control system 190 can maintain the concentration of the optional diluent in the upper chamber 33 and/or mechanically fluidized particulate bed 20 from about 0 mol % to about 95 mol %; from about 50 mol % to about 95 mol %; from about 60 mol % to about 95 mol %; from about 60 mol % to about 90 mol %; from about 70 mol % to about 90 mol %; or from about 70 mol % to about 80 mol %.

When the mechanically fluidized particulate bed 20 is designed according to the teachings contained herein most, if not essentially all, of the first gaseous chemical species (e.g., silane) is thermally decomposed in the mechanically fluidized particulate bed 20 to provide the plurality of coated particles 22 containing the second chemical species (e.g., polysilicon). The required pan 12 size can be calculated using the surface are of the particles comprising the bed, the bed temperature, hold-up time in the bed, system pressure in chamber 33, gas/granule contracting efficiency, bed action, and the partial pressure of first gaseous chemical species in the gas contained in the upper portion of the chamber 33.

In at least some instances, the first gaseous chemical species is maintained at a temperature below its decomposition temperature at all points in the upper chamber 33 external to the mechanically fluidized particulate bed 20. The control system 190 maintains the temperature of the first gaseous chemical species below its thermal decomposition temperature to reduce the likelihood of auto-decomposition of the first gaseous chemical species outside of the mechanically fluidized particulate bed 20. Further, the control system 190 maintains the temperature sufficiently high to reduce the thermal energy demand placed on the thermal energy emitting device 14 to maintain the mechanically fluidized particulate bed 20 at a temperature greater than the thermal decomposition temperature of the first chemical species.

In some instances, the first gaseous chemical species and any optional diluents may be added to the upper chamber 33 at a temperature that is between a minimum temperature of about 10° C.; about 20° C.; about 50° C.; about 70° C.; about 100° C.; about 150° C.; or about 200° C. to a maximum temperature of about 250° C.; about 300° C.; about 350° C.; about 400° C.; or about 450° C. In some instances, the first gaseous chemical species and any optional diluents added to the upper chamber may be maintained a minimum of about 10° C.; about 20° C.; about 50° C.; about 70° C.; about 100° C.; about 150° C.; about 200° C.; about 250° C.; or about 300° C. below the thermal decomposition temperature of the first gaseous chemical species.

The thermal energy used to increase the temperature of the first gaseous chemical species and, optionally, any diluents may be source from any thermal energy emitting device. Such thermal energy emitting devices may include, but are not limited to, one or more external electric heaters, one or more external fluid heaters, or one or more heat interchanges/exchangers where hot gases are used to increase the temperature of the first gaseous chemical species and, optionally, any diluents.

In some instances, the first gaseous chemical species and, optionally, any diluents may be passed through the upper chamber 33 which supplies the thermal energy to preheat the first gaseous chemical species prior to introduction to the mechanically fluidized particulate bed 20. In such instances, the first gaseous chemical species and, optionally, any diluents are apportioned into two portions. The first portion passes through a heat interchanger/heat exchanger (e.g., a coil) positioned in the upper chamber 33 of the reactor 30. The second portion bypasses the heat interchanger/heat exchanger and is combined with the heated gas exiting the heat interchanger/heat exchanger. The combined first gaseous chemical species and any optional diluents are injected into the mechanically fluidized particulate bed 20. The proportion of gas in the first portion and the second portion will determine the temperature of the combined stream that is injected into the mechanically fluidized particulate bed 20. If the temperature of the combined gas stream approaches the decomposition temperature of the first gaseous chemical species, the gas allocated to the second portion (i.e., the portion bypassing the heat interchanger/heat exchanger) can be increased. Such an approach advantageously controls and/or maintains the temperature of the first gaseous chemical species introduced to the mechanically fluidized particulate bed 20 at an optimal temperature and controls and/or maintains the temperature in the upper chamber 33 below the thermal decomposition temperature of the first gaseous chemical species to minimize or eliminate the thermal decomposition of the first gaseous chemical species at locations external to the mechanically fluidized particulate bed 20.

In some instances, the first portion that is passed through the heat interchanger/heat exchanger is maintained below the thermal decomposition temperature of the first gaseous chemical species because auxiliary cooling in the upper zone (e.g., a fluid cooler and cooling coil) controls and/or maintains the temperature of the gas in the upper chamber 33 below the thermal decomposition temperature of the first gaseous chemical species.

In at least some instances, the addition of the first gaseous chemical species to the upper chamber 33 may advantageously permit the use of a pure or near pure first gaseous chemical species (e.g., silanes) to achieve an overall polysilicon conversion of greater than about 70%; greater than about 75%; greater than about 80%; greater than about 85%; greater than about 90%; greater than about 95%; greater than about 99%; or greater than about 99.7%.

The gas recovery system 110 removes byproducts such as a byproduct third gaseous chemical species generated during the thermal decomposition of the first gaseous chemical species. The gas recovery system 110 includes an exhaust port 112 and conduit 114 fluidly coupled to the upper chamber 33 to remove gaseous byproducts and entrained fines from the upper chamber 33. The gas recovery system 110 further includes various exhaust fines separators 116, exhaust control devices 118, and other components (e.g., blowers, compressors—not shown in FIG. 1) useful in removing or expelling as an exhaust 120 at least a portion of the gas removed from the upper portion of the chamber 33.

The gas recovery system 110 may be useful in removing any unreacted first gaseous chemical species, optional diluent(s), and/or byproducts present in the upper chamber 33 for recovery or additional processing. In one example, at least a portion of the gas removed from the upper chamber 33 in a first reaction vessel 30a may be introduced to the upper chamber 33 in a second reaction vessel 30b. In some instances, all or a portion of the diluent(s) present in the gas removed from the upper chamber 33 may be recycled to the upper chamber 33. In some instances, the gas removed from the upper chamber 33 by the gas recovery system 110 may be treated, separated, or otherwise purified prior to discharge, disposal, sale, or recovery. In some instances, a portion of the gas separated by the gas recovery system (e.g., first gaseous chemical species, one or more diluents, one or more dopants or the like) may be recovered for reuse in reactor 30. In such instances, the pressure of any recovered gas can be increased using one or more gas compressors 340 or similar devices.

At times, the gas removed from the upper chamber 33 contains suspended fines 122 such as amorphous silica (a.k.a. “poly-powder”), other decomposition byproducts, and physical erosion byproducts. The exhaust fines separator 116 separates at least some of the fines 122 present in the gas removed from the upper chamber 33. The exhaust fines separator 116 can include at least one separation stage, and may include multiple separation stages each using the same or a different solid/gas separation technology. In one example, the exhaust fines separator 116 includes a cyclonic separator followed by one or more particulate filters.

The coated particle collection system 130 collects at least a portion of the plurality of coated particles 22 that overflow from the mechanically fluidized particulate bed 20. As the diameter of coated particles 22 present in the mechanically fluidized particulate bed 20 increase, the coated particles “float” to the surface of the mechanically fluidized particulate bed 20.

In some instances, the coated particle collection system 130 collects coated particles 22 that overflow the perimeter wall 12c of the pan 12 and fall into one or more coated particle overflow collection devices positioned at least partially about the perimeter wall 12c of the pan 12. In such instances, the height of the perimeter wall 12c of the pan 12 determines the depth of the mechanically fluidized particulate bed 20.

In other instances, the coated particle collection system 130 collects coated particles 22 that overflow into one or more hollow coated particle overflow conduits 132 positioned at defined locations (e.g., in the center) of the pan 12. In such instances, the distance the inlet of the hollow coated particle overflow conduit 132 extends above the upper surface 12a of the bottom of the pan 12 determines the depth of the mechanically fluidized particulate bed 20. The distance the inlet of the hollow coated particle overflow conduits 132 above the upper surface 12a of the bottom of the pan 12 can be about 0.25 inches (6 mm) or more; about 0.5 inches (12 mm) or more; about 0.75 inches (18 mm) or more; about 1 inch (25 mm) or more; about 1.5 inches (37 mm) or more; about 2 inches (50 mm) or more; about 2.5 (65 mm) inches or more; about 3 inches (75 mm) or more; about 4 inches (100 mm) or more; about 5 inches (130 mm) or more; about 6 inches (150 mm) or more; about 7 inches (180 mm) or more; or about 15 inches (180 mm) or more.

The mechanically fluidized particulate bed 20 can have a settled (i.e., in a non-mechanically fluidized state) bed depth of from about 0.10 inches (3 mm) to about 10 inches (255 mm); from about 0.25 inches (6 mm) to about 6 inches (150 mm); from about 0.50 inches (12 mm) to about 4 inches (100 mm); from about 0.50 inches (12 mm) to about 3 inches (75 mm); or from about 0.75 inches (18 mm) to about 2 inches (50 mm).

When needed, the number of fresh particles 92 added by the particulate feed system 90 is sufficiently small that the impact on the volume of the mechanically fluidized particulate bed 20 is minimal. Substantially all of the volumetric increase experienced by the mechanically fluidized particulate bed 20 is attributable to the deposition of the second chemical species (e.g. silicon) on the particulates in the mechanically fluidized particulate bed 20 and the resultant increase in diameter (and volume) of the plurality of coated particles 22.

The number of fresh particles 92 generated within the mechanically fluidized particulate bed 20 and/or added to the mechanically fluidized particulate bed 20 determines the size and number of the plurality of coated particles 22 produced. The size of the fresh particles 92 generated within the mechanically fluidized particulate bed 20 and/or added to the mechanically fluidized particulate bed 20 minimally impacts on the size of the final coated particles 22 produced in the mechanically fluidized particulate bed 20. Instead, the number of fresh particles generated within the mechanically fluidized particulate bed 20 and/or added to the mechanically fluidized particulate bed 20 has a much greater impact on the size of the coated particles 22.

At times the open-ended inlet of the hollow coated particle overflow conduit 132 is positioned or projects a fixed distance above the upper surface 12a of the bottom of the pan 12. For example, the open-ended inlet of the hollow coated particle overflow 132 can project from the upper surface 12a of the pan 12 a distance of about 0.25 inches (6 mm); about 0.5 inches (12 mm); about 0.75 inches (18 mm); about 1 inch (25 mm); about 1.5 inches (37 mm); about 2 inches (50 mm); about 2.5 inches (60 mm); about 3 inches (75 mm); about 4 inches (100 mm); about 5 inches (125 mm); about 6 inches (150 mm); about 7 inches (175 mm); about 8 inches (200 mm); or about 15 inches (380 mm). The hollow coated particle overflow conduit 132 can have an inside diameter of about 3 mm to about 55 mm; about 6 mm to about 25 mm; or about 13 mm. In some instances, the control system 190 intermittently, periodically, or continuously adjusts the depth of the mechanically fluidized particulate bed 20 by varying the projection of the coated particle overflow conduit 132 above the upper surface 12a of the bottom of the pan 12. Such adjustment of the projection of the coated particle overflow conduit 132 above the upper surface 12a of the bottom of the pan 12 may be accomplished using an electromechanical system such as a motor and transmission assembly, or an electromagnetic system such as magnetically coupling the hollow member to an electric coil.

The depth of the mechanically fluidized particulate bed 20 can influence one or more physical parameters such as particle diameter, particle composition, particle morphology, and/or particle density of the coated particles 22 separated from the mechanically fluidized particulate bed 20. Thus, mechanically fluidized particulate bed 20 bed depth may be adjusted to produce coated particles 22 having one or more desirable physical or compositional characteristics. For example, adjusting the hold-up time in the mechanically fluidized particulate bed 20 can reduce or lower the residual hydrogen content as either bonded hydrogen on the surface or as encapsulated hydrogen in at least a portion of the plurality of coated particles 22 separated from the bed. The projection of the coated particle overflow conduit 132 above the upper surface of the pan 12a can be less than the height of the perimeter walls 12c of the pan 12 to reduce the likelihood of spillage of the coated particles 22 from the pan 12 or to retain the mechanically fluidized particulate bed 20 and the plurality of coated particles 22 in the bed. In some instances, the coated particles 22 removed from the mechanically fluidized particulate bed 20 can have a diameter of from about 0.01 mm to about 5 mm; from about 0.5 mm to about 4 mm; from about 0.5 mm to about 3 mm; from about 0.5 mm to about 2.5 mm; from about 0.5 mm to about 2 mm; from about 1 mm to about 2.5 mm; or from about 1 mm to about 2 mm.

Coated particles 22 removed via the coated particle overflow conduit 132 pass through one or more coated particle inlet valves 134 and accumulate in the coated particle discharge vessel 136. Coated particles 22 accumulated in the coated particle discharge vessel 136 are periodically or continuously removed as product coated particles 22 via one or more coated particle outlet valves 138. The coated particle inlet valve 134 and the coated particle outlet valve 138 can include any type of flow control device, for example one or more prime motor driven, variable speed, rotary valves. In at least some instances, the control system 190 can limit, control, or otherwise vary the discharge of finished coated particles 22 from the coated particle collection system 130. In at least some instances, the control system 190 can adjust the removal rate of the coated particles 22 from the mechanically fluidized particulate bed 20 to match the addition or generation rate of seed or fresh particles 92 in the mechanically fluidized particulate bed 20. In some instances, the coated particles 22 may pass through one or more post-treatment processes on a continuous or on an “as-needed” basis, for example a diluent gas purging process or a heating process, e.g., heating at 500 C to 700 C, to de-gas hydrogen from the coated particles 22. Although not shown in FIG. 1, all or a portion of such post-treatment processes may be integrated into the particle collection system 130.

In some implementations the coated particle collection system can include one or more purge gas systems 137 that supplies a chemically inert purge gas to the mechanically fluidized particulate bed 20 via countercurrent flow through the particle removal conduit 132. Such countercurrent purge gas flow assists in reducing the entry of the first gaseous chemical species into the coated particle overflow conduit 132. In some instances, the chemically inert purge gas can include the same gas used as a diluent (e.g., hydrogen) that is used to dilute the first gaseous chemical species in the upper chamber 33.

Such countercurrent purge gas also can be used to selectively separate coated particles 22 having one or more desirable properties (e.g., coated particle diameter) from the mechanically fluidized particulate bed 20. For example, increasing the flow of purge gas tends to increase countercurrent gas velocity within the coated particle overflow tube 132 which tends to return smaller diameter coated particles back to the mechanically fluidized particulate bed 20. Conversely, decreasing the flow of purge gas tends to decrease countercurrent gas velocity within the coated particle overflow tube 132 which tends to separate smaller diameter coated particles from the mechanically fluidized particulate bed 20.

The control system 190 may be communicably coupled to control one or more other elements of the system 100. The control system 190 may include one or more temperature, pressure, flow, or analytical sensors and transmitters to provide process variable signals indicative of an operating parameter of one or more components of the system 100. For instance, the control system 190 may include a number of temperature transmitters (e.g., thermocouples, resistive thermal devices) to provide one or more process variable signals indicative of a temperature of the lower surface 12b of the bottom of the pan 12, or of the upper surface 12a of the bottom of the pan, or of the particulates in mechanically fluidized particulate bed 20. The control system 190 may also receive process variable signals from sensors associated with various valves, blowers, compressors, and other equipment. Such process variable signals may be indicative of a position or state of operation of the specific pieces of equipment or indicative of the operating characteristics within the specific pieces of equipment such as flow rate, temperature, pressure, vibration frequency, vibration amplitude, density, weight, or size.

The second chemical species diameter, bulk density, and/or volume of the coated particles 22 may be increased by increasing deposition rate of the second chemical species, by adjusting one or more of: the mechanically fluidized particulate bed 20 depth; the addition rate of the first gaseous chemical species; the concentration of the optional diluents in the mechanically fluidized particulate bed 20; the number of fresh particles 92 added to or generated in the mechanically fluidized particulate bed 20 per unit time; the temperature of the mechanically fluidized particulate bed 20, the temperature of the first gaseous chemical species in the mechanically fluidized particulate bed 20; the gas pressure in the upper chamber 33; or combinations thereof.

In at least some instances, increasing the temperature of the mechanically fluidized particulate bed 20 can increase the thermal decomposition rate of the first gaseous chemical species, advantageously increasing the deposition rate of the second chemical species. However, such increases in bed temperature will increase the electrical energy consumed by the one or more thermal energy emission devices 14 used to heat the mechanically fluidized particulate bed 20 which may result in a disadvantageous higher electrical usage per unit of polysilicon product (i.e., result in higher kilo-watt hours per kilogram of polysilicon produced). As such, an optimal mechanically fluidized particulate bed 20 temperature may be selected for any given system and set of operational objectives and cost factors, balancing production rate with electrical cost by adjusting the temperature of the mechanically fluidized particulate bed 20.

The control system 190 may use the various process variable signals to generate one or more control variable outputs useful for controlling one or more of the elements of the system 100 according to a defined set of machine executable instructions or logic. The machine executable instructions or logic may be stored in one or more non-transitory storage locations that are communicably coupled to the control system 190. For example, the control system 190 may produce one or more control signal outputs for controlling various elements such as valve(s), thermal energy emission devices, motors, actuators or transducers, blowers, compressors, etc. Thus, for instance, the control system 190 may be communicatively coupled and configured to control one or more valves, conveyors or other transport mechanisms to selectively provide fresh particles 92 to the mechanically fluidized particulate bed 20. Also for instance, the control system 190 may be communicatively coupled and configured to control a frequency of vibration or oscillation of the pan 12 or the oscillatory or vibratory displacement of the pan 12 along the one or more axes of motion 54 to produce the desired level of fluidization within the mechanically fluidized particulate bed 20.

The control system 190 may be communicatively coupled and configured to control a temperature of all or a portion of the pan 12 or of the mechanically fluidized particulate bed 20 retained therein. Such control may be accomplished by controlling a flow of current through the one or more thermal energy emission devices 14. Also for instance, the control system 190 may be communicatively coupled and configured to control a flow of the first chemical species from the first gaseous chemical species reservoir 72 or one or more optional diluent(s) from the diluent reservoir 78 into the upper chamber 33. Such control may be accomplished using one or more variably adjustable final control elements such as control valves, solenoids, relays, actuators, valve positioners and the like or by controlling the delivery rate or pressure of one or more blowers or compressors, for example by controlling a speed of an associated electric motor.

Also for instance, the control system 190 may be communicatively coupled and configured to control the withdrawal of gas from the upper chamber 33 via the gas recovery system 110. Such control may be accomplished by providing suitable control signals including information obtained from an on-line analyzer (e.g., a gas chromatograph) monitoring the concentration of the first gaseous chemical species in the upper chamber 33 or a pressure transmitter, to control one or more valves, dampers, back-pressure control valve, blowers, exhaust fans, via one or more solenoids, relays, electric motors or other actuators.

In some instances, the control system 190 may be communicatively coupled and configured to control a back-pressure control valve to alter, adjust, and/or control system pressure in the upper chamber 33. At times, the control system 190 can control the feed rate of the first gaseous chemical species (e.g., silane) into the mechanically fluidized particulate bed 20 based at least in part on the measured pressure in the upper chamber 33 and the concentration of the first gaseous chemical species in the gas present in the upper chamber 33.

The control system 190 may take a variety of forms. For example, the control system 190 may include a programmed general purpose computer having one or more microprocessors and memories (e.g., RAM, ROM, Flash, rotating media). Alternatively, or additionally, the control system 190 may include a programmable gate array, application specific integrated circuit, and/or programmable logic controller.

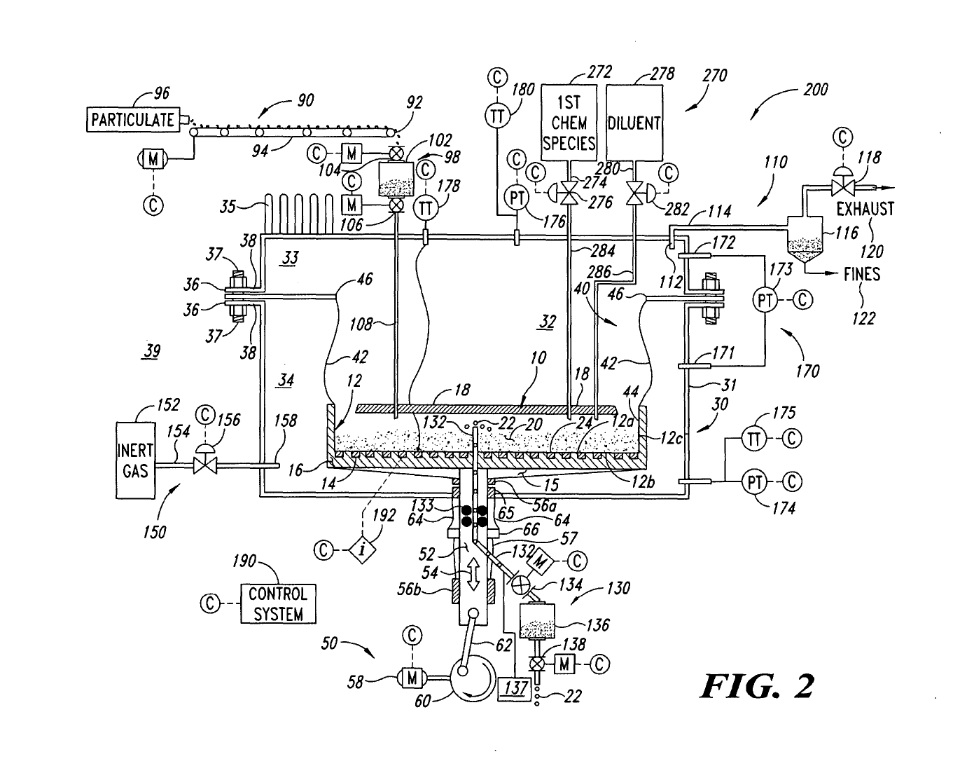

FIG. 2 shows another mechanically fluidized bed reactor system 200, according to one illustrated embodiment. In the continuously operated mechanically fluidized bed reactor system 200, fresh particles 92 are fed on an as needed basis to the mechanically fluidized particulate bed 20 and quantities of the first gaseous chemical species and one or more optional diluent(s) are introduced to the upper chamber 33, according to an embodiment. As the first gaseous chemical species permeates the heated mechanically fluidized particulate bed 20, the thermal decomposition of the first gaseous chemical species within the particulate bed 20 deposits a second chemical species on the particulates to form the plurality of coated particles 22. Some or all of the plurality of coated particles 22 are removed from the mechanically fluidized particulate bed 20 via the coated particle collection system 130.

Within the mechanically fluidized bed reactor, all or a portion of the first gaseous chemical species and all or a portion of the one or more optional diluent(s) are introduced via separate fluid conduits 284, 286 (respectively) to the upper chamber 33 and/or the mechanically fluidized particulate bed 20. In such a manner, the flow and pressure of the first gaseous chemical species and the one or more diluent(s) may be individually controlled, altered, or adjusted to provide a wide range of operating environments within the upper chamber 33.

In at least some operating modes, no diluent is added to the upper chamber 33 or the mechanically fluidized particulate bed 20. At such times, the first gaseous chemical species may be added to the upper chamber 33 and/or the mechanically fluidized particulate bed 20 in the absence of separate diluent feed. At other times, the first gaseous chemical species may be added to the upper chamber 33 and/or the mechanically fluidized particulate bed 20 either premixed with or separate but contemporaneous with a diluent.

Prior to flowing into the upper chamber 33 via fluid conduit 284, the first gaseous chemical species and any diluent(s) premixed therewith are transferred from a reservoir 272 via one or more conduits 274 and one or more final control elements 276, such as one or more flow or pressure control valves. In a similar manner, when used and prior to flowing into the upper chamber 33 via fluid conduit 286, the one or more optional diluent(s) are transferred from a reservoir 278 via one or more conduits 280 and one or more final control elements 282, such as one or more flow or pressure control valves. The first gaseous chemical species and any diluent(s) flow into the upper chamber 33 in a controlled, safe, and environmentally conscious manner.

The control system 190 intermittently, periodically, or continuously adjusts, alters, modulates, or controls the flow or pressure of either or both the first gaseous chemical species or the one or more diluent(s) to achieve a desired gas composition in the upper chamber and/or the mechanically fluidized particulate bed 20. The control system 190 intermittently, periodically, or continuously adjusts, alters, modulates, or controls the concentration of the first gaseous chemical species in the upper chamber 33 and/or mechanically fluidized particulate bed 20 from about 0.1 mole percent (mol %) to about 100 mol %; from about 0.1 mol % to about 40 mol %; from about 0.1 mol % to about 30 mol %; from about 0.01 mol % to about 20 mol %; or from about 20 mol % to about 30 mol %. The control system 190 intermittently, periodically, or continuously adjusts, alters, modulates, or controls the concentration of the diluent(s) in the upper chamber 33 from about 1 mol % to about 99.9 mol %; from about 50 mol % to about 99.9 mol %; from about 60 mol % to about 90 mol %; from about 70 mol % to about 99 mol %; or from about 70 mol % to about 80 mol %.

The first gaseous chemical species is added to the upper portion of the chamber 33 via fluid conduit 284 at a temperature below its thermal decomposition temperature. The fluid conduit 284 may introduce the first gaseous chemical species at one or more points in the upper chamber 33 including one or more points in the vapor space of the upper chamber 33 and/or one or more points submerged in the mechanically fluidized particulate bed 20. The thermal decomposition temperature and consequently the temperature at which the first gaseous chemical species is added to the upper portion of the chamber 33 depends upon both the operating pressure of the upper portion of the chamber 33 and the composition of the first gaseous chemical species. In some instances, the first gaseous chemical species may be added to the upper chamber 33 and/or the mechanically fluidized particulate bed 20 at a temperature that is about 10° C. to about 500° C.; about 10° C. to about 400° C.; about 10° C. to about 300° C.; about 10° C. to about 200° C.; or about 10° C. to about 100° C. less than its thermal decomposition temperature. In other instances, the first gaseous chemical species can be introduced to the upper chamber 33 and/or the mechanically fluidized particulate bed 20 at a temperature of from about 10° C. to about 450° C.; about 20° C. to about 375° C.; about 50° C. to about 275° C.; about 50° C. to about 200° C.; or about 50° C. to about 125° C.

In some instances, the temperature of the first gaseous chemical species and the one or more diluent(s) may be selected to maintain a desired temperature in the upper chamber 33. In some instances, the temperature of the first gaseous chemical species and the one or more diluent(s), if present, may be introduced to the mechanically fluidized particulate bed 20 at a temperature slightly below the thermal decomposition temperature of the first gaseous chemical species. Such advantageously minimizes the heat load on the heater 14. In some instances, the control system 190 maintains the temperature in the upper chamber 33 using one or more cooling features 35. At times, the control system 190 maintains the temperature of the gas in the upper chamber 33 below the thermal decomposition temperature of the first gaseous chemical species to reduce the likelihood of second species deposition or of poly-powder formation within the upper chamber 33 in locations external to the mechanically fluidized particulate bed 20. In some instances, the control system 190 maintains the temperature in the upper chamber 33 below the thermal decomposition temperature of the first chemical species by controlling the rate of heat removal through cooling features 35 and/or other thermal energy transfer systems or devices. The control system 190 can maintain the temperature of the gas in the upper chamber at less than about 500° C.; less than about 400° C., or less than about 300° C. In some instances, to reduce the power required by the thermal energy emission device 14, the control system 190 can maintain the temperature of the gas in the upper chamber 33 at the highest temperature at which substantially no second species deposits or polysilicon powder forms.

The control system 190 controls the addition of the one or more diluent(s) to the upper chamber 33 and/or the mechanically fluidized particulate bed 20 via inlet 286. At times, the control system 190 may halt the flow of the one or more diluent(s) to the upper chamber 33 and/or mechanically fluidized particulate bed 20. The control system 190 can maintain the temperature of the one or more diluent(s) added to the upper chamber 33 and/or mechanically fluidized particulate bed 20 at the same or different from the temperature of the first gaseous chemical species added to the upper chamber and/or the mechanically fluidized particulate bed 20.

In at least some instances, the control system 190 maintains the temperature of the one or more diluent(s) added to the upper chamber 33 and/or the mechanically fluidized particulate bed 20 below the thermal decomposition temperature of the first gaseous chemical species. The control system 190 maintains the temperature of the one or more diluent(s) added to the upper chamber 33 at about 10° C. to about 500° C.; about 10° C. to about 400° C.; about 10° C. to about 300° C.; about 10° C. to about 200° C.; or about 10° C. to about 100° C. less than the thermal decomposition temperature of the first chemical species. In other instances, the control system 190 maintains the temperature of the one or more diluent(s) added to the upper chamber 33 and/or the mechanically fluidized particulate bed 20 from about 10° C. to about 450° C.; about 20° C. to about 375° C.; about 50° C. to about 325° C.; about 50° C. to about 200° C.; or about 50° C. to about 125° C.

At times, the first gaseous chemical species and the one or more optional diluent(s) may be added to the upper chamber 33 and/or mechanically fluidized particulate bed 20 on a continuous or near-continuous basis. When introduced to the mechanically fluidized particulate bed 20 and then heated to a temperature in excess of the thermal decomposition temperature of the first gaseous chemical species, the first chemical species thermally decomposes, depositing the second chemical species on the surface of the particulates in the mechanically fluidized particulate bed 20.

Measuring the partial pressure of the first gaseous chemical species in the gas contained in the upper chamber 33 in combination with the total pressure in the upper chamber 33 and the feed rates of first gaseous chemical species to the upper chamber 33, provides an indication of the quantity of first chemical species thermally decomposed. As the partial pressure of the first gaseous chemical species varies in the upper chamber 33, the control system 190 may intermittently, periodically, or continuously introduce less or additional first gaseous chemical species to the upper chamber to maintain a desired gas composition. The control system 190 may intermittently, periodically, or continuously transfer additional first chemical species from the reservoir 272 or one or more diluent(s) from the reservoir 278 to the upper portion of the chamber 33 to maintain a desired first chemical species partial pressure or gas composition in the upper chamber 33.

As the second chemical species deposits on the surface of the particles in the particulate bed 20, at least some of the plurality of coated particles 22 (i.e., those having greater quantities of second chemical species disposed thereupon and hence larger diameter) will tend to “float” within, or rise to the surface of, the particulate bed 20. The control system 190 removes coated particles 22, which particles may be removed on from the mechanically fluidized particulate bed 20 on an intermittent, periodic or continuous basis via the coated particle overflow conduit 132.

At times, spontaneous self-nucleation of the second chemical species and physical abrasion of the second chemical species within the mechanically fluidized particulate bed 20 generate sufficient seed particulates for continuous operation of the mechanically fluidized particulate bed 20. In such instances, the control system 190 may suspend the addition of fresh particulates 92 from the particle feed system 90 to the mechanically fluidized particulate bed 20. At other times, spontaneous self-nucleation of the second chemical species and physical abrasion of the second chemical species within the mechanically fluidized particulate bed 20 may be insufficient for continuous operation of the mechanically fluidized particulate bed 20. In such instances, the control system 190 intermittently, periodically, or continuously adds fresh particulates 92 from the particle feed system 90 to the mechanically fluidized particulate bed 20.

The substantially continuous addition of the first gaseous chemical species to the upper chamber 33 and/or the mechanically fluidized particulate bed 20 advantageously permits the substantially continuous production of coated particles 22. The substantially continuous addition of the first gaseous chemical species to the upper chamber 33 and/or the mechanically fluidized particulate bed 20 advantageously achieves a single stage overall conversion of the first gaseous chemical species to the second chemical species of greater than about 50%; greater than about 55%; greater than about 60%; greater than about 65%; greater than about 70%; greater than about 75%; greater than about 80%; greater than about 85%; greater than about 90%; greater than about 95%; or greater than about 99%.

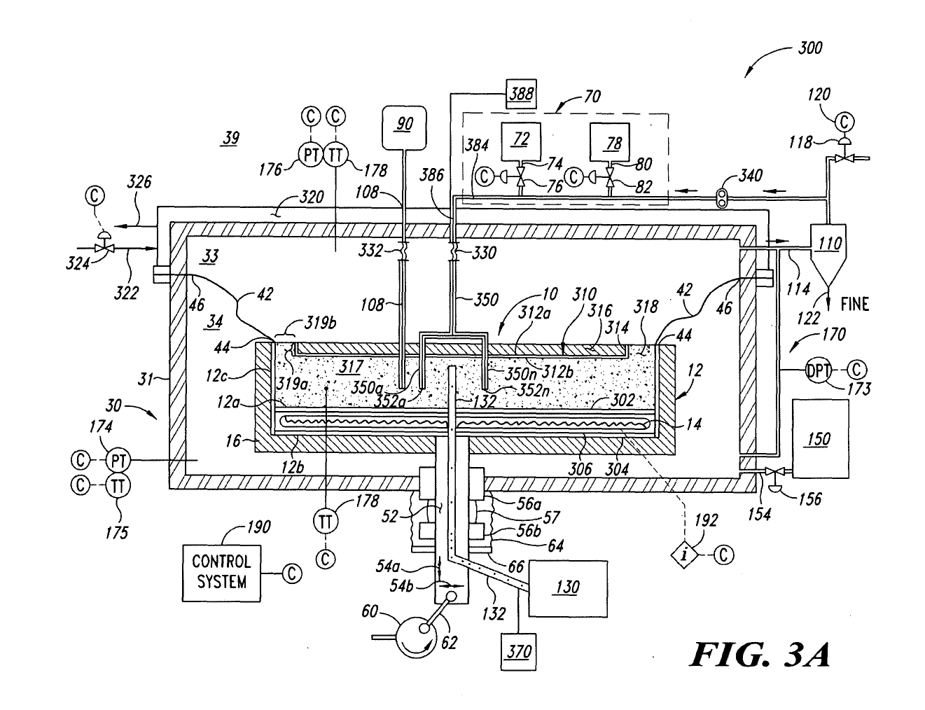

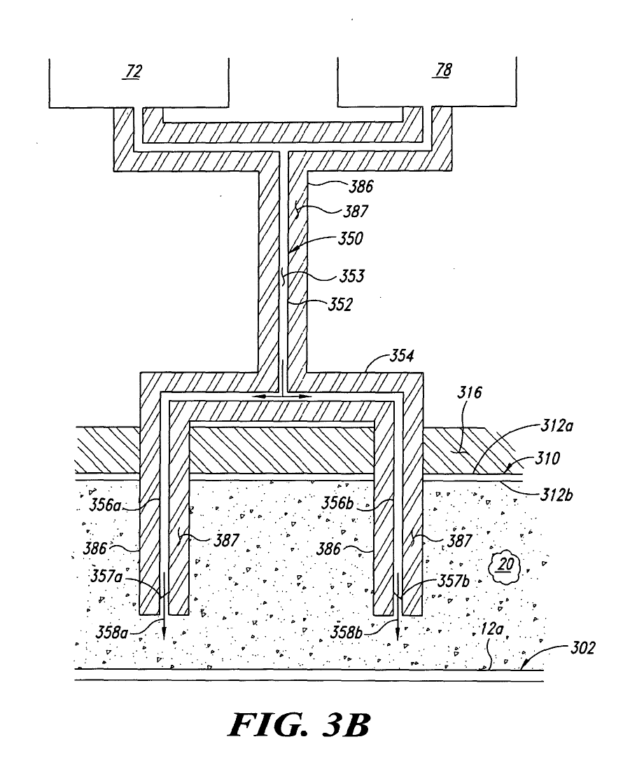

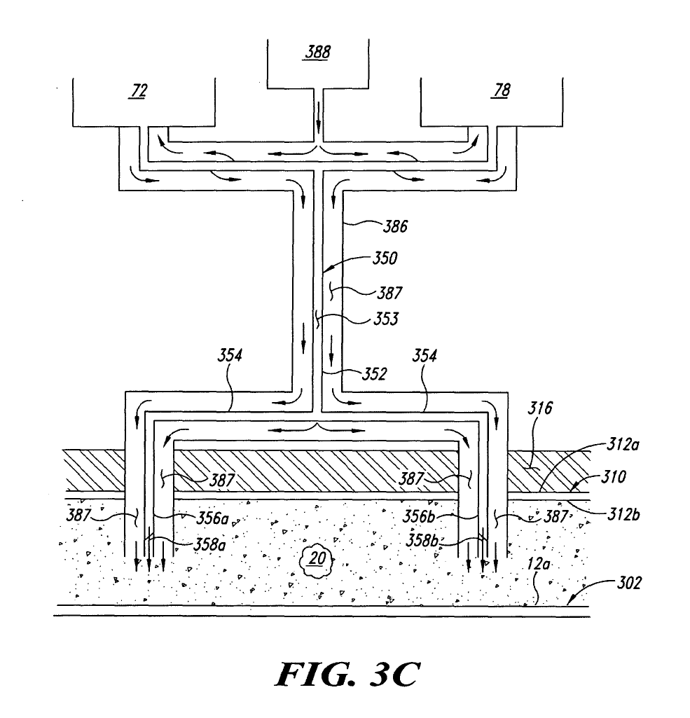

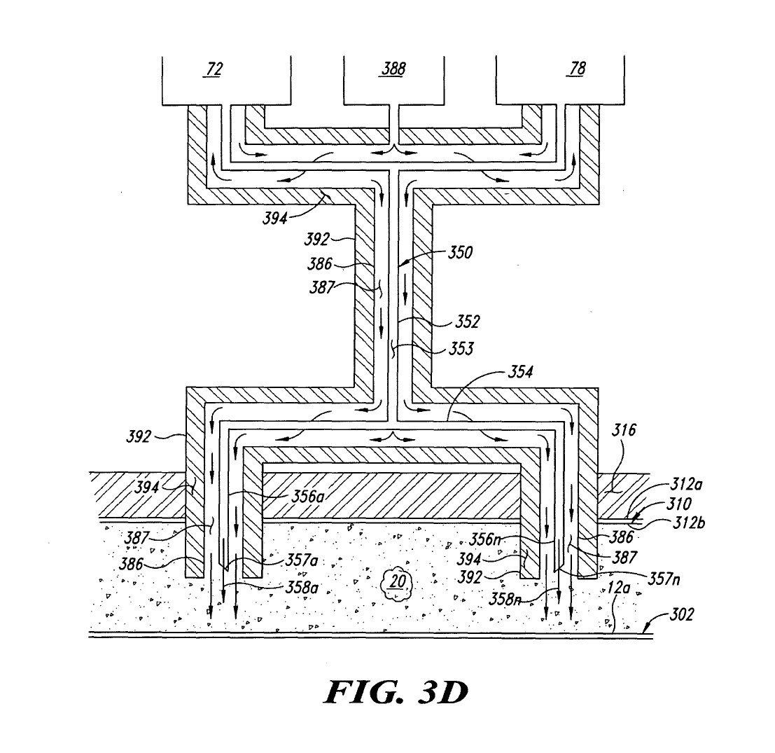

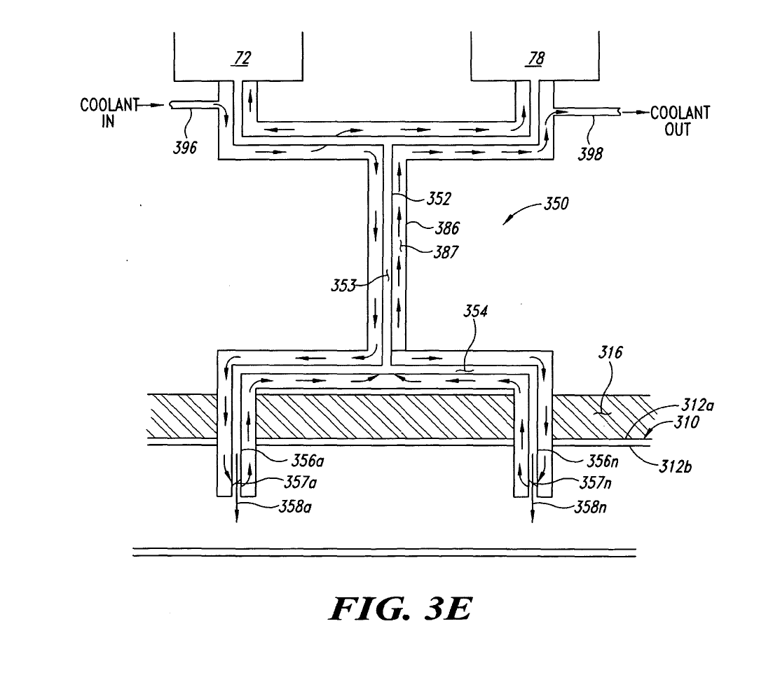

FIG. 3A shows another illustrative mechanically fluidized bed reactor 300 that includes a different configuration in which the pan 12 includes a major horizontal surface 302 and a second horizontal surface 304 having an interstitial space 306 formed therebetween in which the one or more thermal energy emission devices 14 are located, according to an embodiment. In addition, the pan 12 further includes a cover 310 that includes a raised lip 314 and at least one insulative layer 316. The cover 310 is geometrically similar to, but smaller, than the peripheral wall 12c of the pan 12, forming an annular gap 318 having a gap height 319a and a gap width 319b between the cover 310 and the peripheral wall 12c of the pan 12. The cover 310 and the pan 12 define at least some of the boundaries about a retention volume 317 that retains the mechanically fluidized particulate bed 20.

The pan 12 includes a major horizontal surface 302 that supports the mechanically fluidized particulate bed 20. In at least some implementations, the major horizontal surface 302 is a silicon or silicon coated surface that is provided prior to the introduction of any particulates or first gaseous chemical species to the reactor 300. At times, the major horizontal surface 302 may be substantially pure silicon. In some instances the major horizontal surface 302 may be selectively removable from the pan 12, for example to replace a worn surface or to provide access for maintenance, repair, or replacement of the one or more thermal energy emission devices 14 disposed in the space 306 beneath the major horizontal surface 302. At other times, the major horizontal surface 302 may be integrally formed and non-removable from the pan 12. At times, the perimeter wall 12c of the pan extends beyond the major horizontal surface 302 and terminates at the second horizontal surface 304, forming the interstitial space 306 between the major horizontal surface 302 and the second horizontal surface 304.The pan 12 may have any shape or geometric configuration. For example, the pan 12 may have a generally circular shape with a diameter of from about 1 inch to about 120 inches; about 1 inch to about 96 inches; about 1 inch to about 72 inches; about 1 inch to about 48 inches; about 1 inch to about 24 inches; or about 1 inch to about 12 inches. The perimeter wall of the pan 12c can extend upwardly from the upper surface 12a of the second horizontal surface 304 the pan 12 to a height greater than the depth of the mechanically fluidized particulate bed 20 retained on the major horizontal surface 302.

In some instances, the height of the perimeter wall 12c may be set at a distance from the upper surface 12a of the major horizontal surface 302 of the pan 12 such that a portion of the particulates forming the particulate bed 20 flow over the top of the perimeter wall for capture by the coated particle collection system 130. The perimeter wall 12c can extend above the upper surface 12a of the major horizontal surface 302 by a distance of from about 0.25 inches to about 20 inches; about 0.50 inches to about 10 inches; about 0.75 inches to about 8 inches; about 1 inch to about 6 inches; or about 1 inch to about 3 inches.

The portions of the pan 12 contacting the mechanically fluidized particulate bed 20, including at least a portion of the perimeter wall 12c and the major horizontal surface 302 may include one or more abrasion or erosion resistant materials that are also resistant to chemical degradation. In at least some instances, the major horizontal surface 302 can be an integral (i.e., without open perforations, apertures or similar open penetrations), unitary and single piece member that is either selectively removable from the pan 12 or integrally formed with the pan 12. Alternatively, the pan 12 may have one or more sealed apertures, for example where the hollow coated particle overflow conduit 132 passes through the bottom of the pan 12. In such instances, the joint between the bottom of the pan 12 and the penetrating member (e.g., the hollow coated particle overflow conduit 132) can be sealed using an appropriate sealer and/or via thermal fusion, welding, or similar. Use of a pan 12 having appropriate physical and chemical resistance reduces the likelihood of contamination of the mechanically fluidized particulate bed 20 by contaminants, such as metal ions, that are released from the pan 12. In some instances, the pan 12 can comprise an alloy such as a graphite alloy, a nickel alloy, a stainless steel alloy, or combinations thereof. In at least some instances, the pan 12 can comprise molybdenum or a molybdenum alloy.

At times, a liner or similar layer or coating of resilient material that resists abrasion or erosion, reduces unwanted product buildup, or reduces the likelihood of contamination of the mechanically fluidized particulate bed 20 may be deposited on all or a portion of the major horizontal surface 302 and/or pan walls 12c that contact the mechanically fluidized particulate bed 20. In some instances, all or a portion of at least the upper surface 12a of the major horizontal surface 302 and/or the perimeter walls 12c of the pan, may comprise silicon or high purity silicon (e.g., >99.0% Si, >99.9% Si, or >99.9999% Si). It should be understood that the silicon comprising the bottom of the pan is present prior to the first use of the pan 12, in other words, the silicon comprising the pan is different from the non-volatile second chemical species created by the thermal decomposition of the first gaseous chemical species in the mechanically fluidized particulate bed 20.

In some instances, the liner, layer, or coating in all or a portion of the pan 12 can include: a graphite layer, a quartz layer, a silicide layer, a silicon nitride layer, or a silicon carbide layer. In some instances, a metal silicide may be formed in situ by reaction of silane with iron, nickel, and other metals in the pan 12. A silicon carbide layer, for example, is durable and reduces the tendency of metal ions such as nickel, chrome, and iron from the metal comprising the pan to migrate into, and potentially contaminate, the plurality of coated particles 22 in the pan 12. In one example, the pan 12 comprises a 316 stainless steel pan with a silicon carbide layer deposited on at least a portion of the upper surface 12a of the major horizontal surface 302 and the perimeter wall 12c contacting the mechanically fluidized particulate bed 20. In another example, the pan 12 comprises a 316 stainless steel major horizontal surface 302 that is overlaid with a selectively removable silicon liner that is substantially pure silicon (i.e., >99.9% Si).

At times, the liner or layer may be physically coupled to the major horizontal surface 302 and/or pan 12 using one or more mechanical fasteners, for example one or more threaded fasteners, bolts, nuts, or the like. At other times, the liner or layer may be physically coupled to the major horizontal surface 302 and/or pan 12 using one or more spring clips, clamps, or similar devices. At yet other times, the liner or layer may be physically coupled to the major horizontal surface 302 and/or pan 12 using metal fusion, one or more adhesives or similar bonding agents.

One or more thermal energy emission devices 14 are disposed in the chamber 306 formed by the major horizontal surface 302, the second horizontal surface 304 and the perimeter wall 12c of the pan 12. At times, the thermal output of the one or more thermal energy emission devices 14 may be limited, regulated, or controlled by the control system 190 to prevent thermal damage to the pan 12. This is of particular importance when a non-metallic major horizontal surface 302 or a non-metallic lined major horizontal surface 302 is used. In at least some implementations, the interstitial space 306 can be hermetically sealed from the upper chamber 33, the lower chamber 34, or both the upper and the lower chambers to prevent the ingress of polysilicon or other gases or gas borne particulates into the interstitial space 306 or the egress of insulation materials from interstitial space into the upper chamber 33 or the lower chamber 34. In operation, the thermal energy emission devices 14 are controlled by the control system 190 to increase the temperature of the mechanically fluidized particulate bed 20 above the thermal decomposition temperature of the first gaseous chemical species.

An insulative layer 16 may be disposed about all or a portion of the exterior surfaces of the pan 12 and flexible membrane 42, including the perimeter wall 12c and the lower surface 12b of the second horizontal surface 304. The insulative layer 16 can limit or otherwise restrict the flow or transfer of thermal energy from the thermal energy emission devices 14 to the upper chamber 33 and lower chamber 34. Further, the at least one insulative layer 316 positioned on the cover 310 can limit or otherwise restrict the flow or transfer of thermal energy from the mechanically fluidized particulate bed 20 to the upper chamber 33. At times, a gas impermeable, rigid, covering, for example a metallic cover or structure, may at least partially enclose the insulative layer 16. At other times, the insulative layer 16 may include a gas impermeable flexible insulative layer 16, for example insulation blankets with or without jacketing. Such gas impermeable coverings or jackets minimize the likelihood of deposition of polysilicon or other gas-borne contaminants in the insulative layer 16. At times, the temperature of the exterior surface of the insulative layer 16 exposed to the lower chamber 34 is less than the thermal decomposition temperature of the first gaseous chemical species. The cover 310 is disposed in the upper chamber 34 and is positioned a distance above the upper surface 12a of the major horizontal surface 302 of the pan 12. In operation, the cover 310 advantageously assists in both retaining thermal energy in the mechanically fluidized particulate bed 20 and promoting extended contact and plug flow contact between the first gaseous chemical species and the mechanically fluidized particulate bed 20.

The cover includes an upper surface 312a, a lower surface 312b and a peripheral edge 314, some or all of which may be upturned to provide a peripheral wall. The peripheral edge 314 of the cover 310 is spaced inward of the peripheral wall 12c of the pan 12 forming a peripheral gap 318 between the peripheral edge 314 of the cover 310 and the perimeter wall 12c of the pan 12. In at least some implementations, the peripheral gap 318 can have a gap height 319a equal to the height of the wall formed by the upturned peripheral edge 314 of the cover 310. At least a portion of the lower surface 312b of the cover 310 may include a continuous layer of at least one of: graphite, quartz, silicon, silicon carbide, or silicon nitride disposed on at least a portion of the lower surface of the cover exposed to the mechanically fluidized particulate bed.

The volumetric displacement of the mechanically fluidized particulate bed 20 in operation may be used to determine one or more dimensions of the peripheral gap 318. Such prevents expelling hot gas from the mechanically fluidized particulate bed 20 to the upper chamber 33 on the upstroke of each oscillation or vibration cycle and permits the mechanically fluidized particulate bed 20 to draw any such expelled hot gas retained in the volume formed by the peripheral gap 318 back into the particulate bed 20 on the downstroke of each oscillation or vibration cycle.

By way of example, assuming a mechanically fluidized particulate bed 20 diameter of 12 inches and an operating displacement of 0.1 inch, the total displacement volume of the mechanically fluidized particulate bed 20 is given by the following equation:

Volume=πr₍ₚₐₙ₎²×displacement=11.3 in³ (1)

Assuming a peripheral gap width 319b of 0.5 inches (i.e., a cover diameter of 11 inches), the peripheral gap height 319a is determined using the following equation:

height=Volume/(πr₍ₚₐₙ₎²−πr_{(cover)}²)=0.626 in. (2)

At times, the dimensions of the peripheral gap 318 (e.g., the width 319a) are determined based on the gas flow of the unreacted first gaseous chemical species and any byproduct gases from the mechanically fluidized particulate bed 20. For example, the width 319a may be determined based on maintaining a gas flow velocity through the peripheral gap 318 less than a defined threshold at which particles having one or more physical properties are retained in the mechanically fluidized particulate bed 20. In at least one embodiment, the width 319b may be based at least in part on maintaining a gas velocity below a threshold at which particulates are entrained and carried from the mechanically fluidized particulate bed 20. For example, the gap width 319a may be determined based on not entraining particulates having at least one physical property greater than one or more defined parameters (e.g., a particulate diameter greater than a defined diameter, a particulate density greater than a defined density). At times, the gas velocity in the peripheral gap 318 can be low enough to retain coated particles having a diameter greater than about 1 micron; about 5 microns; about 10 microns; about 20 microns; about 50 microns; about 80 microns; or about 100 microns to about 50 microns; about 80 microns; about 100 microns; about 120 microns; about 150 microns; or about 200 microns in the mechanically fluidized particulate bed 20. In various embodiments, the peripheral gap width 319b can be about 1/16 inch or more; about ⅛ inch or more; about ¼ inch or more; about ½ inch or more; or about 1 inch or more.

Selective removal of fines from system 300, based on particle diameter, by filtration of the gas mixture or the exhaust gas is possible because the velocity of the off-gas exiting the mechanically fluidized bed can be controlled by adjusting the size of the peripheral gap 318 that fluidly connects the mechanically fluidized particulate bed 20 with the upper portion 33 of the chamber 32. Increasing the off-gas velocity by reducing the size of the peripheral gap 318 will tend to entrain and remove larger diameter fine particles and/or particulates from the mechanically fluidized particulate bed 20 into upper portion 33 of the chamber 32. Conversely, decreasing the off-gas velocity by increasing the size of the peripheral gap 318 will tend to entrain and remove smaller diameter particles and/or particulates from the mechanically fluidized particulate bed 20 into upper portion 33 of the chamber 32.

At times, the cover 310 includes a thermally reflective material to return at least a portion of the thermal energy radiated by the mechanically fluidized particulate bed 20 back to the mechanically fluidized particulate bed 20. To further reduce the flow of thermal energy from the mechanically fluidized particulate bed 20 to the upper chamber 34, a thermally insulating material 316 may be disposed proximate the cover 310 on the surface opposite the mechanically fluidized particulate bed 20. At other times, at least a portion of the lower surface 312b of the cover 310 contacting the mechanically fluidized particulate bed 20 may include silicon or high-purity silicon (e.g., 99+%, 99.5+%, or 99.9999+% silicon). Such silicon construction is present prior to the first use of the cover 310 and is not attributable to deposition of the second chemical species on the lower surface 312b of the cover 310.

The thermally insulating material 316 may, for instance be a glass-ceramic material (e.g., Li₂O×Al₂O₃×nSiO₂-System or LAS System) similar that used in “glass top” stoves where the electrical heating elements are positioned beneath a glass-ceramic cooking surface. In some situations, the thermally insulating material 316 may include one or more rigid or semi-rigid refractory type materials such as calcium silicate. In some situations, the thermally insulating material 316 may include one or more flexible insulative materials, for example ceramic insulation blankets or other similar non-thermally conductive rigid, semi-rigid, or flexible coverings.

In operation, although the settled particulate bed typically does not contact the lower surface 312b of the cover 310, it is advantageous of the mechanically fluidized particulate bed 20 touches (e.g., lightly, firmly) the lower surface 312b of the cover 310 when the bed is fluidized. In such instances the contact of the mechanically fluidized particulate bed 20 with the lower surface 312b of the cover 310 beneficially prevents short circuiting of the first gaseous chemical species around (as opposed to through) the mechanically fluidized particulate bed 20. Additionally, by contacting the lower surface 312b of the cover 310, deposition of the second chemical species on the lower surface 312b of the cover 310 is beneficially reduced. Further, by only lightly touching or by just contacting the lower surface 312b of the cover 310, the fluid nature of the mechanically fluidized particulate bed 20 is not compromised or limited in any way.

FIG. 3B depicts an illustrative gas distribution system 350, according to an embodiment. In some implementations, the gas distribution system 350 includes at least one inner tube member 352 that defines a fluid passage 353. The fluid passage 353 fluidly couples to one or more distribution headers 354. One or more injectors 356a-356n (collectively “injectors 356”) each having a least one respective outlet 357a-357n at a distal end thereof, fluidly couple at a proximal end to the one or more distribution headers 354. The injectors 356 project through the cover member 310 and extend a distance into the mechanically fluidized particulate bed 20. Gas flow 358a-358n from the one or more outlets 357 enters the mechanically fluidized particulate bed 20 at a location between the upper surface 12a of the major horizontal member 302 and the lower surface 312b of the cover 310. The injectors 356 can be disposed in any random or geometric pattern or configuration in the mechanically fluidized particulate bed 20. At times, the outlets on each respective one of the injectors 356 may be positioned at the same or different elevations within the mechanically fluidized particulate bed 20.

The injectors 356 are formed using one or more materials providing satisfactory chemical/corrosion resistance and structural integrity at the operating pressures and temperatures of the mechanically fluidized particulate bed 20. For example, the injectors may be fabricated using a high temperature stainless steel or nickel alloy. For example, an INSULON® shaped-vacuum thermal barrier using a sealed vacuum chamber about the injector as provided by Concept Group Incorporated (West Berlin, N.J.). In some implementations the interior and/or exterior surfaces of the injector 356 may be coated, lined, or layered with a coating such as silicon, silicon carbide, graphite, silicon nitride, or quartz.

An outer tube member 386 surrounds at least the injector 356 and may optionally surround all or a portion of the one or more distribution headers 354 and/or all or a portion of the inner tube member 352. The inner tube member. 352 and the outer tube member 386 do not contact each other except at the end of the outer tube member 386 in the mechanically fluidized particulate bed 20, thereby forming a close-ended void space 387 between the inner tube member 352 and the outer tube member 386. At times, the close-ended void space 387 contains an insulative vacuum. At other times, the close-ended void space 387 contains one or more insulative materials. The close-ended void space 387 advantageously insulates the inner tube member from the high temperature mechanically fluidized particulate bed 20 and optionally the elevated temperature upper chamber 33, thereby minimizing or preventing the thermal decomposition of the first gaseous chemical species prior to introduction to the mechanically fluidized particulate bed 20. In some implementations, the close-ended void space 387 extends beyond the one or more outlets 357 of each of the injectors 356.

In some instances, the injectors 356 sealingly attach or are physically coupled to the cover 310 to prevent the escape of gases from the mechanically fluidized particulate bed 20. The gas distribution system 350 can include one or more flexible connectors 330 (shown in FIG. 3A, omitted from FIG. 3B for clarity) to isolate the gas feed system 70 from the vibratory or oscillatory movement of the pan 12 during operation.

FIG. 3C depicts another gas distribution system 350, according to an illustrative embodiment. In FIG. 3C, the inner tube member 352 and the outer tube member 386 do not contact each other, thereby forming an open-ended void space 387 between the inner tube member 352 and the outer tube member 386. An inert fluid (i.e., liquid or gas) flows from an inert fluid reservoir 388 through the open-ended void space 387. The inert fluid passing through the open-ended void space 387 insulates the first gaseous chemical species in the fluid passage 353 from heating when the first gaseous chemical species passes through the inner tube member 352, the distribution header 354 and the injectors 356. The inert fluid exits the open-ended void space 387 and flows into the mechanically fluidized particulate bed 20.

FIG. 3D depicts another gas distribution system 350, according to an illustrative embodiment. In FIG. 3D, the inner tube member 352 and the outer tube member 386 do not contact each other, thereby forming an open-ended void space 387 between the inner tube member 352 and the outer tube member 386. A second outer tube member 392 is disposed about all or a portion of the outer tube member 386. The second outer tube member 392 and the outer tube member 386 contact each other at a location proximate the one or more outlets 357 on each of the injectors 356 to form a close-ended void space 394 that surrounds the open-ended void space 387 that surrounds the inner tube member 352, the distribution header 354, and the injectors 356.

In some instances, the close-ended void space 394 contains an insulative vacuum. In some instances, the close-ended void space 394 contains an insulative material. An inert fluid (i.e., liquid or gas) flows from an inert fluid reservoir 388 through the open-ended void space 387. In some implementations, the close-ended void space 394 extends beyond the one or more outlets 357 of each of the injectors 356. The insulative vacuum or insulative material in the close-ended void space 394, in conjunction with the inert fluid passing through the open-ended void space 387 insulates the first gaseous chemical species in the fluid passage 358 from heating when the first gaseous chemical species passes through the inner tube member 352, the distribution header 354 and the injectors 356. The inert fluid exits the open-ended void space 387 and flows into the mechanically fluidized particulate bed 20.

FIG. 3E depicts another illustrative gas distribution system 350, according to an embodiment. In some implementations, the gas distribution system 350 includes at least one inner tube member 352 that defines a fluid passage 353. The fluid passage 353 fluidly couples to one or more distribution headers 354. Gas flow 358a-358n from the one or more outlets 357 on each of the injectors 356 enters the mechanically fluidized particulate bed 20 at a location between the upper surface 12a of the major horizontal member 302 and the lower surface 312b of the cover 310. The injectors 356 can be disposed in any random or geometric pattern or configuration in the mechanically fluidized particulate bed 20. At times, the outlets on each respective one of the injectors 356 may be positioned at the same or different elevations within the mechanically fluidized particulate bed 20.

The outer tube member 386 surrounds at least the injector 356 and may optionally surround all or a portion of the one or more distribution headers 354 and/or all or a portion of the inner tube member 352. The inner tube member 352 and the outer tube member 386 do not contact each other except at the end of the outer tube member 386 in the mechanically fluidized particulate bed 20, thereby forming a close-ended void space 387 between the inner tube member 352 and the outer tube member 386. A fluid (i.e., liquid and/or gas) coolant is introduced via one or more inlets 396 to the close-ended loop. The coolant passes through the close-ended void and cools the injectors 356 and, optionally, the inner tube member 352 and/or the distribution header 354. The fluid coolant is removed from the close-ended void space via one or more fluid outlets 398.

The coolant flowing through the close-ended void space 387 advantageously insulates the inner tube member from the high temperature mechanically fluidized particulate bed 20 and optionally the elevated temperature upper chamber 33, thereby minimizing or preventing the thermal decomposition of the first gaseous chemical species prior to introduction to the mechanically fluidized particulate bed 20. Returning to FIG. 3A, the gas distribution system 350 can include any number of distribution headers 354 and any number of injectors 356 fluidly coupled to the distribution headers 354 and extending at least partially into the mechanically fluidized particulate bed 20. Each of the injectors 356 can include one or more outlets 357 through which the first gaseous chemical species is introduced to the mechanically fluidized particulate bed 20. In some instances, the injectors 356 are insulated to prevent the premature thermal decomposition of the first gaseous chemical species prior to discharge into the mechanically fluidized particulate bed 20. In some instances, one or more fluid coolants are passed across at least the injectors 356 to prevent the premature thermal decomposition of the first gaseous chemical species prior to discharge into the mechanically fluidized particulate bed 20. If the first gaseous chemical species prematurely decomposes in the injector 356, the second chemical species can deposit within, and ultimately foul the internal passages of some or all of the number of injectors 356.

At times, the injectors 356 are positioned to discharge the first gaseous chemical species and any diluent(s) at one or more central locations within the mechanically fluidized particulate bed 20 such that the first gaseous chemical species flows radially outward through the mechanically fluidized particulate bed 20. At times, the injectors 356 are positioned about the periphery of the cover 310 to discharge the first gaseous chemical species and any diluents at peripheral locations within the mechanically fluidized particulate bed 20 such that the first gaseous chemical species flows radially inward through the mechanically fluidized particulate bed 20. At times, the first gaseous chemical species can flow in a plug flow regime radially inward or radially outward through the mechanically fluidized particulate bed 20.

An optional inert gas system 370 can provide a flow of inert gas as a purge in the coated particle overflow conduit 132. Although not shown in FIG. 3A, the optional inert gas system can include an inert gas reservoir, fluid conduits, gas flow, pressure, and/or temperature monitor and control devices. The inert gas can include, but is not limited to one or more of the following: include at least one of: hydrogen, nitrogen, helium, or argon. The inert purge gas flows countercurrent to the coated particles 22 removed from the mechanically fluidized particulate bed 20 and discharges into the mechanically fluidized particulate bed 20 via the particle overflow tube. The use of an inert purge gas beneficially limits the removal of small diameter coated particles from the mechanically fluidized particulate bed 20 and also reduces the quantity of first gaseous chemical species and any diluent(s) removed from the mechanically fluidized particulate bed 20 via the coated particle overflow conduit 132.

At times, the flow rate and/or velocity of the inert gas through the coated particle overflow conduit 132 can be altered, adjusted, or controlled, for example using control system 190, to control the size of the coated particles 22 removed from the mechanically fluidized particulate bed 20, or alternatively to control the size of coated particles 22 returned to the mechanically fluidized particulate bed 20 via entrainment in the inert gas flowing countercurrent in the coated particle overflow conduit 132. For example, the flow rate or velocity of the inert gas through the coated particle overflow conduit 132 may be altered, adjusted, or controlled, for example by the control system 190, such that coated particles 22 having a diameter of less than about 600 micrometers (μm); less than about 500 μm; less than about 300 μm; less than about 100 μm; less than about 50 μm; less than about 20 μm; less than about 10 μm; or less than about 5 μm are entrained in the inert gas and returned to the mechanically fluidized particulate bed 20 via the coated particle overflow conduit 132.

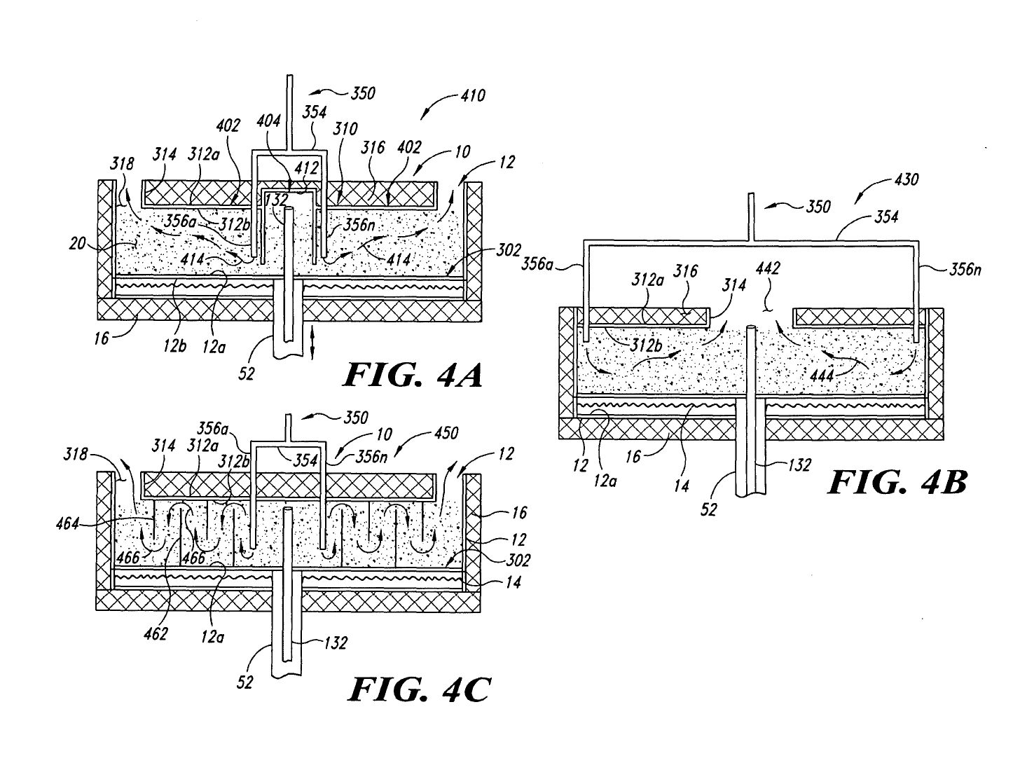

FIG. 4A shows an alternative cover 410 having a configuration useful with a mechanically fluidized bed reactor, according to one embodiment. For clarity, the gas distribution system 350 is depicted without outer tube member 386, however it should be understood that the gas distribution system 350 depicted in FIG. 4A may include any of the insulation or cooling systems depicted in FIGS. 3B-3E. The cover 410 includes a first portion 402 in which the lower surface 312b is positioned a first distance above the upper surface 12a of the major horizontal surface 302. The cover 410 also includes a second “top hat” portion 404 in which the lower surface 312b is positioned a second distance that is greater than the first distance above the upper surface 12a of the major horizontal surface 302. The second portion 404 is disposed about the coated particle overflow conduit 132. The second portion 404 of the cover 310 permits the mechanically fluidized particulate bed 20 to contact (e.g., lightly, firmly) the lower surface 312b of the first portion 402 of the cover 310 while still permitting the overflow of coated particles 22 into the coated particle overflow conduit 132.

The injectors 356a-356n discharge the first gaseous chemical species at one or more central locations in the mechanically fluidized particulate bed 20. The first gaseous chemical species and any diluent(s) follow a radially outward flow path 414 through the mechanically fluidized particulate bed 20. Exhaust gases, primarily any diluent(s) present in the gas feed and inert decomposition byproducts escape from the mechanically fluidized particulate bed 20 via the peripheral gap 318 between the cover 410 and the perimeter wall 12c. In at least some implementations, the velocity of the first gaseous chemical species and any diluent(s) through the mechanically fluidized particulate bed 20 establishes a substantially plug or transitional radially outward flow regime through the mechanically fluidized particulate bed 20.

FIG. 4B shows another alternative cover 430 having a configuration useful with a mechanically fluidized bed reactor, according to one embodiment. For clarity, the gas distribution system 350 is depicted without outer tube member 386, however it should be understood that the gas distribution system 350 depicted in FIG. 4B may include any of the insulation or cooling systems depicted in FIGS. 3B-3E. The cover 430 is disposed proximate or fixed to the perimeter wall 12c of the pan 12 and the upturned peripheral edge 314 of the cover 310 forms an aperture 442 above a portion of the mechanically fluidized particulate bed 20, for example above the central portion of the mechanically fluidized particulate bed 20 about the coated particle overflow conduit 132. In operation, the mechanically fluidized particulate bed 20 contacts (e.g., lightly, firmly) the lower surface 312b of cover 430.

The injectors 356a-356n discharge the first gaseous chemical species at one or more peripheral locations in the mechanically fluidized particulate bed 20. The first gaseous chemical species and any diluent(s) follow radially inward flow path 444 through the mechanically fluidized particulate bed 20. Exhaust gases, primarily any diluent(s) present in the gas feed and inert decomposition byproducts escape from the mechanically fluidized particulate bed 20 via the aperture 442. In such an implementation, the volume formed by the aperture 442 area multiplied by the height 319b of the upturned peripheral edge 314 of the cover 310 may be equal to the displacement volume of the mechanically fluidized particulate bed 20. In at least some implementations, the velocity of the first gaseous chemical species and any diluent(s) through the mechanically fluidized particulate bed 20 establishes a substantially plug or transitional radially inward flow regime through the mechanically fluidized particulate bed 20.

By way of example, assuming the cover is proximate but not fixed to the peripheral wall, a mechanically fluidized particulate bed 20 diameter of 12 inches and an operating displacement of 0.1 inch, the total displacement volume of the mechanically fluidized particulate bed 20 is given by the following equation:

Volume=πr₍ₚₐₙ₎²×displacement=11.3 in³ (3)

Assuming a central aperture 452 diameter of 4 inches, the height 319b is determined using the following equation:

Height=Volume/πr₍ₐₚₑᵣₜᵤᵣₑ₎²)=0.9 in. (4)

FIG. 4C shows an alternative cover 450 having a configuration useful with a mechanically fluidized bed reactor, according to one embodiment. For clarity, the gas distribution system 350 is depicted without outer tube member 386, however it should be understood that the gas distribution system 350 depicted in FIG. 4C may include any of the insulation or cooling systems depicted in FIGS. 3B-3E. The cover 450 includes a number of concentric baffles 462 physically coupled to the upper surface 12a of the pan 12 and a number of concentric baffles 464 physically coupled to the lower surface 312b of the cover 310. At times, the lower concentric baffles 462 and the upper concentric baffles 464 may be configured concentric with the coated particle overflow conduit 132. At times, at least some of the concentric baffles 462 and at least some of the concentric baffles 464 may be wholly or partially constructed of silicon or high-purity silicon (e.g., >99% Si, >99.9% Si, or >99.9999% Si). At times, at least some of the concentric baffles 462 and at least some of the concentric baffles 464 may comprise silicon having a uniform thickness or a uniform density. Silicon on the concentric baffles 462 and concentric baffles 464 is present prior to the first use of the cover 310 and is not attributable to deposition of the second chemical species on the concentric baffles 462 and concentric baffles 464. Such baffles may be used in conjunction with the covers 310, 410, and 430 as depicted in FIGS. 3A, 4A, and 4B, respectively. In at least some implementations, the concentric baffles 462 and concentric baffles 464 are arranged in an alternating pattern to define a serpentine flow path through the mechanically fluidized particulate bed 20.

The injectors 356a-356n discharge the first gaseous chemical species at one or more central locations in the mechanically fluidized particulate bed 20. The first gaseous chemical species and any diluent(s) follow a radially outward serpentine flow path 466 around the concentric baffles 462 and concentric baffles 464 and through the mechanically fluidized particulate bed 20. Exhaust gases, primarily any diluent(s) present in the gas feed and inert decomposition byproducts escape from the mechanically fluidized particulate bed 20 via the peripheral gap 318 between the cover 450 and the perimeter wall 12c. In at least some implementations, the velocity of the first gaseous chemical species and any diluent(s) through the mechanically fluidized particulate bed 20 establishes a substantially plug or transitional serpentine, radially outward, flow regime through the mechanically fluidized particulate bed 20.

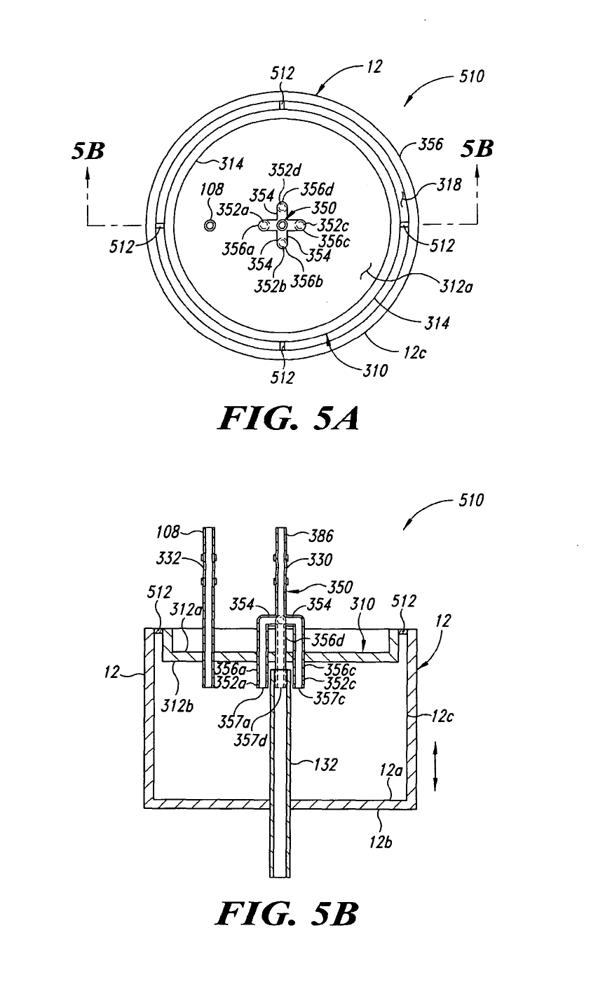

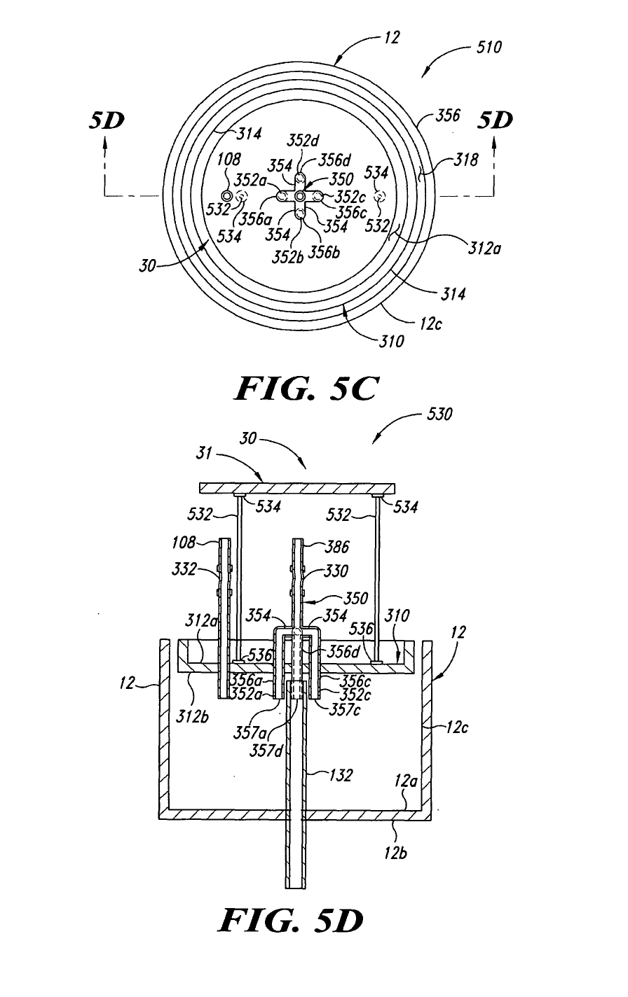

FIG. 5A and FIG. 5B show an illustrative cover arrangement 510 in which the cover 310 is physically affixed to the pan 12 via a number of attachment members 512a-512n (collectively, “attachment members 512”), according to an embodiment. The peripheral gap 318 separates the raised lip 314 (shaded) of the cover 310 from the perimeter wall 12c (shaded) of the pan 12. One or more attachment members 512 physically couple the cover 310 to the perimeter wall 12c. At times, the attachment members 512 may be non-detachably affixed to either the raised lip 314 of the cover 310 or the perimeter wall 12c, or both the raised lip 314 of the cover 310 and the perimeter wall 12c via one or more non-removable methods such as welding. At times, the attachment members 512 may be detachably affixed to either the raised lip 314 of the cover 310 or the perimeter wall 12c of the pan 12, or both the raised lip 314 of the cover 310 and the perimeter wall 12c of the pan 12 via one or more removable fasteners, for example one or more threaded fasteners and/or latches.

The attachment members 512 may include any rigid member capable of supporting the cover 310 and the associated fresh particulate feed hollow member 108 and the gas distribution system 350. In some instances, some or all of the attachment members 512 may include silicon or high-purity silicon (>99% Si, >99.9% Si, or >99.9999% Si) or graphite coated with silicon carbide. Since the cover 310 oscillates with the pan 12, flexible members 330 and 332 are disposed in the gas distribution header 354 and the hollow member 108, respectively.

FIG. 5C and FIG. 5D show an alternative illustrative cover arrangement 530 in which the cover 310 is physically affixed to the reactor vessel 31 via a number of attachment members 532a-532n (collectively, “attachment members 532”), according to an embodiment. In such implementations, the pan 12 retaining the mechanically fluidized particulate bed 20 oscillates while the cover 310 remains stationary. At times, the attachment members 532 may be permanently affixed to either the cover 310 or the reactor vessel 31, or both the cover 310 and the reactor vessel 31 via one or more permanent methods such as welding. At times, the attachment members 532 may be detachably affixed to either the cover 310 or the reactor vessel 31, or both the cover 310 and the reactor vessel 31 via one or more removable fasteners, for example one or more threaded fasteners and/or latches. Note that affixing the cover 310 to the reactor vessel 31 can eliminate the need for flexible connections 330 and 332.

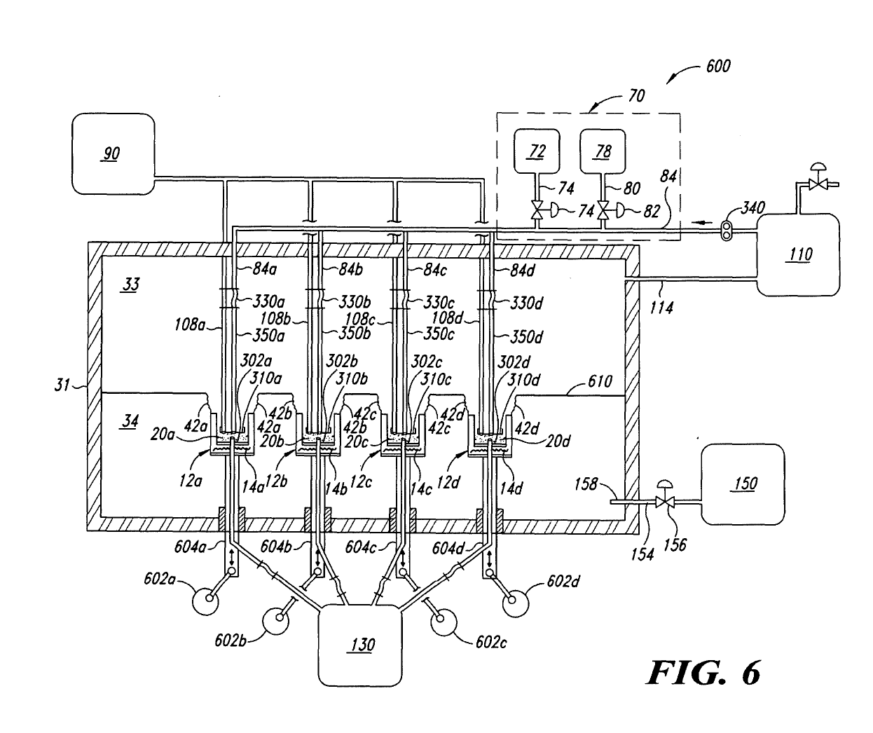

FIG. 6 shows another illustrative mechanically fluidized bed reactor 600 that includes plurality of pans 12a-12n (collectively, “pans 12”), according to an embodiment. For clarity, the gas distribution systems 350a-350n in FIG. 6 are depicted without outer tube member 386, however it should be understood that any or all of the gas distribution systems 350a-350n depicted in FIG. 6 may include any of the insulation or cooling systems depicted in FIGS. 3B-3E. Similar to the mechanically fluidized bed reactor depicted in FIG. 3A, the mechanically fluidized bed reactor 600 is apportioned by a divider plate 610 and a plurality of flexible members 42a-42n into an upper chamber 33 and a lower chamber 34. Each of the plurality of pans 12 is similar in design and function to the pan 12 described in detail with regard to FIG. 3A, and includes a major horizontal surface 302 having an upper surface 12a and a lower surface 12b and a perimeter wall 12c. Each of the pans 12 includes a respective flexible member 42a-42n that is physically coupled to a respective pan 12a-12n and to the divider plate 610. The flexible members 42 hermetically seal the upper chamber 33 from the lower chamber and expose the upper surface 12a of each of the pans 12 to the upper chamber 33 and the lower surface 12b of each of the pans 12 to the lower chamber 34.

Each of the pans 12 includes a respective cover 310a-310n. Each of the covers 310a-310n may be the same as or different from the other covers and may include any of the covers 310, 410, 430, and 450 described in detail with regard to FIGS. 3A, 4A, 4B, and 4C, respectively. Each of the plurality of pans 12a-12n includes a respective gas distribution system 350a-350n. The gas distribution system 350 in each pan may be the same (i.e., centrally located injectors 356 or peripherally located injectors 356) or different (i.e., a mixture of centrally located and peripherally located injectors 356). Although depicted as routed through the upper chamber 33, at times, some or all of the fluid conduits 84a-84n, flexible connections 330a-330n, and gas distribution systems 350a-350n may be routed from below the pans 12a-12n (i.e., through the lower chamber 34).

In some instances, each of the plurality of pans 12a-12n may be driven by a respective cam 602a-602n (collectively “cams 602”) and transmission member 604a-604n (collectively, “transmission members 604”). Each of the cams 602 may be driven by a separate driver or by one or more common drivers. At times, the control system 190 can oscillate or vibrate each of the plurality of pans 12a-12n in a first, synchronous, mode such that all of the plurality of pans 12 has a similar or identical displacement at any instant in time. At other times, the control system 190 can oscillate or vibrate each of the plurality of pans in a second, asynchronous, mode such that some or all of the plurality of pans 12 have different displacements. For example, the control system 190 may oscillate a first half of the plurality of pans such that the displacement of the first half of the pans is 0.1 inch vertical while the displacement of a second half of the pans 12 is at zero (“0”). Such an asynchronous operating mode advantageously minimizes the pressure fluctuation in the upper and lower chambers attributable to the oscillation or vibration of the plurality of the pans 12 (i.e., the volume of the upper chamber and the volume of the lower chamber 34 remain substantially constant throughout the oscillatory or vibratory cycling of the plurality of pans 12).

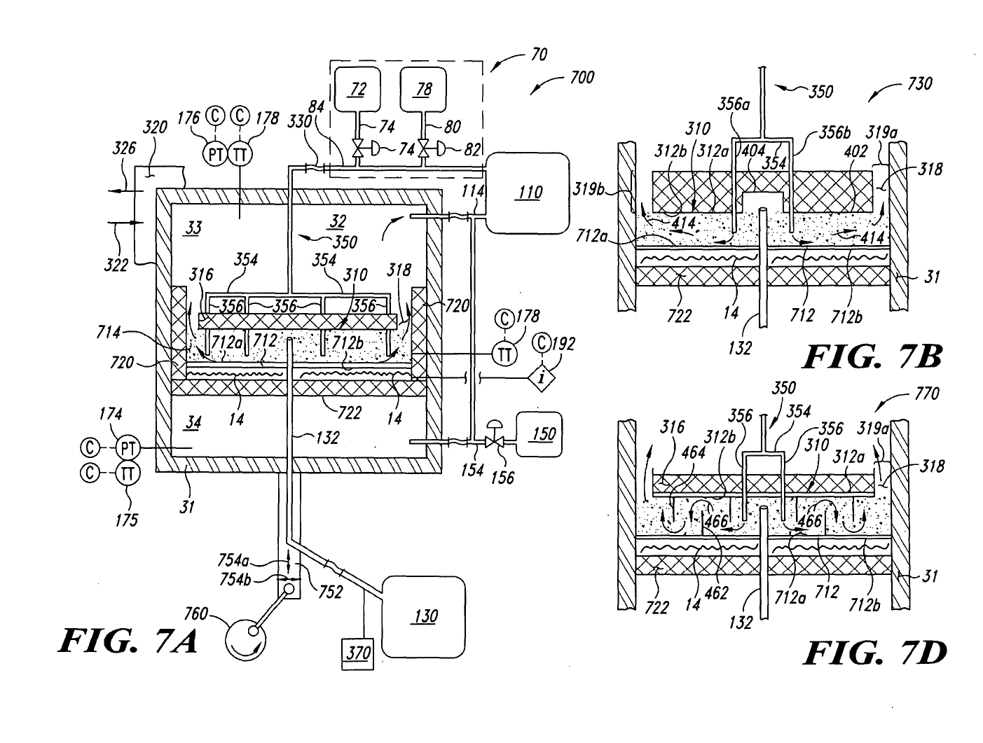

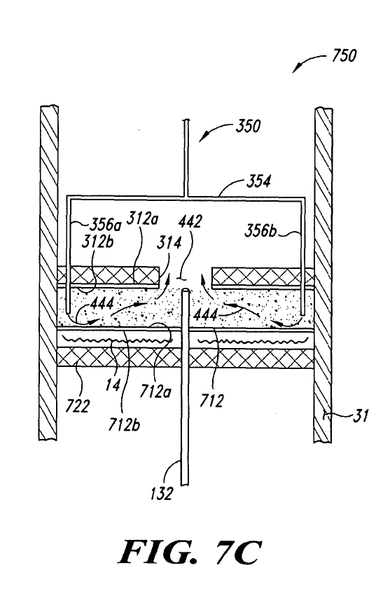

FIG. 7A shows an illustrative mechanically fluidized reactor system 700 in which a major horizontal surface 712 carrying the plurality of particulates extends completely across a cross section of the reactor vessel 31 and the entire vessel 31 is oscillated or vibrated to provide the mechanically fluidized particulate bed 20, according to an embodiment. For clarity, the gas distribution system 350 is depicted without outer tube member 386, however it should be understood that the gas distribution system 350 depicted in FIG. 7A may include any of the insulation or cooling systems depicted in FIGS. 3B-3E. A major horizontal surface 712 extends across the cross section of the interior of the reactor vessel 31, forming the upper chamber 33 and the lower chamber 34. The major horizontal surface 712 includes an upper surface 712a and a lower surface 712b. A cover 310 is disposed a distance from the upper surface 712a of the major horizontal surface 712, forming a retention volume 714 therebetween. The retention volume 714 retains the mechanically fluidized particulate bed 20.

In some implementations, one or more insulative materials 720 may be disposed about the interior and/or exterior of the reactor vessel 31 in locations proximate those areas of the reactor maintained at elevated temperature. For example, one or more insulative materials 720 (e.g., cal-sil, fiberglass, mineral wool, or similar) may be disposed proximate an internal or external portion of the reactor wall 31 proximate the mechanically fluidized particulate bed 20 where a localized concentration of thermal energy can be expected. Where such insulative materials 720 are disposed proximate an internal surface of the reactor wall 31, all or a portion of the insulative materials 720 may be partially or completely covered and/or encapsulated in a non-permeable, non-thermally conductive, layer such as a blanket, rigid cover, semi-rigid cover, or flexible cover. In other implementations, one or more insulative materials 720 may be disposed internally within the reactor vessel 31 in locations proximate those areas of the reactor maintained at elevated temperature, such as the external surfaces of the reactor vessel 31 that are proximate the mechanically fluidized particulate bed 20. One or more cooling features such as extended surface cooling fins, cooling coils, and/or a cooling jacket 320 through which a heat transfer fluid passes may be used to maintain the temperature in the upper chamber 33 below the thermal decomposition temperature of the first gaseous chemical species.

The portions of the major horizontal surface 712 contacting the mechanically fluidized particulate bed 20 are formed of an abrasion or erosion resistant material that is also resistant to chemical degradation by the first chemical species, the diluent(s), and the coated particles in the particulate bed 20 and that forms a barrier to the transmission of metal atoms in the pan assembly into the particulate bed. Use of a major horizontal surface 712 having appropriate physical and chemical resistance reduces the likelihood of contamination of the fluidized particulate bed 20 by contaminants released from the major horizontal surface 712. In some instances, the major horizontal surface 712 can comprise an alloy such as a graphite alloy, a nickel alloy, a stainless steel alloy, or combinations thereof. In some instances, the major horizontal surface 712 can comprise molybdenum or a molybdenum alloy, or a metal alloy of such materials that is coated with a barrier material such as graphite, silicon, quartz, silicon carbide, silicide, molybdenum disilicide, and silicon nitride.

At times, a layer or coating of resilient material that resists abrasion or erosion, reduces unwanted product buildup, or reduces the likelihood of contamination of the mechanically fluidized particulate bed 20 may be deposited on all or a portion of the major horizontal surface 712. In some instances, all or a portion of the major horizontal surface 712 may comprise silicon or high purity silicon (>99% Si, >99.9% Si, >99.9999% Si). It should be understood that the silicon comprising the major horizontal surface 712 is present prior to the first use of the major horizontal surface 712, in other words, the silicon comprising the major horizontal surface 712 is different from the non-volatile second chemical species created by the thermal decomposition of the first gaseous chemical species in the mechanically fluidized particulate bed 20.

In some instances, the layer or coating in all or a portion of the major horizontal surface 712 can include but is not limited to: a graphite layer, a silicon layer, a quartz or fused quartz layer, a silicide layer, a silicon nitride layer, or a silicon carbide layer. In some instances, a metal silicide may be formed in situ by reaction of silane with iron, molybdenum, nickel, and other metals in the major horizontal surface 712. A silicon carbide layer, for example, is durable and reduces the tendency of metal ions such as nickel, chrome, and iron from the metal comprising the pan to migrate into, and potentially contaminate, the plurality of coated particles 22 in the major horizontal surface 712. In one example, the major horizontal surface 712 comprises a 316 stainless steel member with a silicon carbide layer deposited on at least a portion of the upper surface 712a in contact with the mechanically fluidized particulate bed 20. In another example, the major horizontal surface 712 comprises an Inconel member with a silicon layer deposited on at least a portion of the upper surface 712a in contact with the mechanically fluidized particulate bed 20. In yet another example, the major horizontal surface 712 comprises a molybdenum or molybdenum alloy member with a fused quartz layer deposited on at least a portion of the upper surface 712a in contact with the mechanically fluidized particulate bed 20.

At times, the liner or layer may be physically coupled to the major horizontal surface 712 using one or more mechanical fasteners, for example one or more threaded fasteners, bolts, nuts, or the like: At other times, the liner or layer may be physically coupled to the major horizontal surface 712 using one or more spring clips, clamps, or similar devices. At yet other times, the liner or layer may be physically coupled to the major horizontal surface 712 using one or more adhesives or similar bonding agents.

One or more thermal energy emitting devices 14 are disposed proximate the lower surface 712b of the major horizontal surface 712. An insulative layer 722 is disposed proximate the one or more thermal energy emitting devices 714 to reduce the heat radiated to the lower chamber 34. The insulative layer 714 may, for instance be a glass-ceramic material (e.g., Li₂O×Al₂O₃×nSiO₂-System or LAS System) similar that used in “glass top” stoves where the electrical heating elements are positioned beneath a glass-ceramic cooking surface. In some situations, the insulative layer 714 may include one or more rigid or semi-rigid refractory type materials such as calcium silicate. In some implementations, the insulative layer 714 may include one or more removable insulative blankets or similar devices.

In some instances, the cover 310 is smaller in diameter than the reactor vessel 31, thereby creating a peripheral gap 318 between an upturned peripheral edge 314 of the cover 310 and an interior wall surface of the reactor vessel 31. The peripheral gap 318 can have a height 319a and a width 319b that, along with the peripheral gap length, defines a peripheral volume about the cover 310. In at least some implementations, the peripheral volume about the cover 310 can be equal to or greater than the displacement volume of the mechanically fluidized particulate bed 20.

The first gaseous chemical species and any diluent(s) are introduced at any number of locations in the mechanically fluidized particulate bed 20 via the injectors 356. In operation, the first gaseous chemical species and the diluent(s) flow 714 through the mechanically fluidized particulate bed 20. The diluent(s), gaseous decomposition byproducts, and any undecomposed first gaseous chemical species exit the mechanically fluidized particulate bed 20 as an exhaust gas via the peripheral gap 318. The exhaust gas flows into the upper chamber 33.

The reactor vessel 31 is oscillated or vibrated using a mechanical, electrical, magnetic, or electromagnetic system capable of displacing the reactor vessel 31 at a desired oscillatory or vibratory frequency and oscillatory or vibratory displacement. In some implementations, a cam 760 causes a transmission member 752 to oscillate or vibrate the reactor vessel 31 along one or more axes of motion. For example, in some implementations, the transmission member 752 can oscillate the reactor vessel 31 along a single axis of motion 754a that is substantially perpendicular to the major horizontal surface 712. In another example, the transmission member 752 can oscillate or vibrate the reactor vessel 31 along an axis having components that lie along a first axis of motion that is substantially perpendicular to the major horizontal surface 712 and a second axis of motion 754b that is orthogonal to the first axis of motion 754a.

FIG. 7B shows an alternative cover 730 useful with the mechanically fluidized bed reactor 700 depicted in FIG. 7A, according to an embodiment. For clarity, the gas distribution system 350 is depicted without outer tube member 386, however it should be understood that the gas distribution system 350 depicted in FIG. 7B may include any of the insulation or cooling systems depicted in FIGS. 3B-3E. The cover 730 includes a first portion 402 in which the lower surface 312b is positioned a first distance above the upper surface 12a of the major horizontal surface 302. The cover 730 also includes a second “top hat” portion 404 in which the lower surface 312b is positioned a second distance that is greater than the first distance above the upper surface 12a of the major horizontal surface 302. The second portion 404 is disposed about and/or above the coated particle overflow conduit 132. The second portion 404 of the cover 310 permits the mechanically fluidized particulate bed 20 to (e.g., lightly, firmly) contact the lower surface 312b of the first portion 402 of the cover 310 while still permitting the overflow of coated particles 22 into the coated particle overflow conduit 132.

Although not shown in FIG. 7B, in some implementations, a purge gas supplied by the purge gas system 370 is passed through the coated particle overflow conduit 132. The countercurrent flow of purge gas through the coated particle overflow conduit 132 reduces the flow of the first gaseous chemical species through the coated particle overflow conduit 132, thereby improving the yield in the mechanically fluidized bed reactor 700.

The injectors 356a-356n discharge the first gaseous chemical species at one or more central locations in the mechanically fluidized particulate bed 20. The first gaseous chemical species and any diluent(s) follow a radially outward flow path 414 through the mechanically fluidized particulate bed 20. Exhaust gases, including any diluent(s) present in the gas feed, inert decomposition byproducts, and undecomposed first gaseous chemical species escape as an exhaust gas from the mechanically fluidized particulate bed 20 via the peripheral gap 318 between the cover 410 and the perimeter wall 12c. In at least some implementations, the velocity of the first gaseous chemical species and any diluent(s) through the mechanically fluidized particulate bed 20 establishes a substantially plug or transitional radially outward flow regime through the mechanically fluidized particulate bed 20.

FIG. 7C shows another alternative cover system 750 useful with the mechanically fluidized bed reactor 700 depicted in FIG. 7A, according to an embodiment. For clarity, the gas distribution system 350 is depicted without outer tube member 386, however it should be understood that the gas distribution system 350 depicted in FIG. 7C may include any of the insulation or cooling systems depicted in FIGS. 3B-3E. The cover 750 is disposed proximate the perimeter wall 12c of the reactor vessel 31 and the upturned peripheral edge 314 of the cover 310 forms an aperture 442 above a portion of the mechanically fluidized particulate bed 20. For example, an aperture 442 above the central portion of the mechanically fluidized particulate bed 20 about the coated particle overflow conduit 132. In operation, the mechanically fluidized particulate bed 20 contacts the lower surface 312b of cover 750.

The injectors 356a-356n discharge the first gaseous chemical species at one or more peripheral locations in the mechanically fluidized particulate bed 20. The first gaseous chemical species and any diluent(s) follow radially inward flow path 444 through the mechanically fluidized particulate bed 20. Exhaust gases, including any diluent(s) present in the gas feed, inert decomposition byproducts, and undecomposed first gaseous chemical species escape from the mechanically fluidized particulate bed 20 as an exhaust gas via the aperture 442.

FIG. 7D shows another alternative cover system 770 useful with the mechanically fluidized bed reactor 700 depicted in FIG. 7A, according to an embodiment. For clarity, the gas distribution system 350 is depicted without outer tube member 386, however it should be understood that the gas distribution system 350 depicted in FIG. 7D may include any of the insulation or cooling systems depicted in FIGS. 3B-3E. The cover 770 includes a number of concentric baffles 462 physically coupled to the upper surface 12a of the pan 12 and a number of concentric baffles 464 physically coupled to the lower surface 312b of the cover 310. At times, the lower concentric baffles 462 and the upper concentric baffles 464 may be configured concentric with the coated particle overflow conduit 132. At times, at least some of the concentric baffles 462 and at least some of the concentric baffles 464 may be wholly or partially constructed of silicon or high-purity silicon (e.g., >99% Si, >99.9% Si, or >99.9999% Si). At times, at least some of the concentric baffles 462 and at least some of the concentric baffles 464 may comprise silicon having a uniform thickness or a uniform density. In at least some implementations, the concentric baffles 462 and concentric baffles 464 are arranged in an alternating pattern to define a serpentine flow path through the mechanically fluidized particulate bed 20.

The injectors 356a-356n discharge the first gaseous chemical species at one or more central locations in the mechanically fluidized particulate bed 20. The first gaseous chemical species and any diluent(s) follow a radially outward serpentine flow path 466 around the concentric baffles 462 and concentric baffles 464 and through the mechanically fluidized particulate bed 20. Exhaust gases, including diluent(s) present in the gas feed, inert decomposition byproducts, and undecomposed first gaseous chemical species escape from the mechanically fluidized particulate bed 20 as an exhaust gas via the peripheral gap 318 between the cover 450 and the perimeter wall 12c. In at least some implementations, the velocity of the first gaseous chemical species and any diluent(s) through the mechanically fluidized particulate bed 20 establish a substantially plug or transitional serpentine, radially outward, flow regime through the mechanically fluidized particulate bed 20.

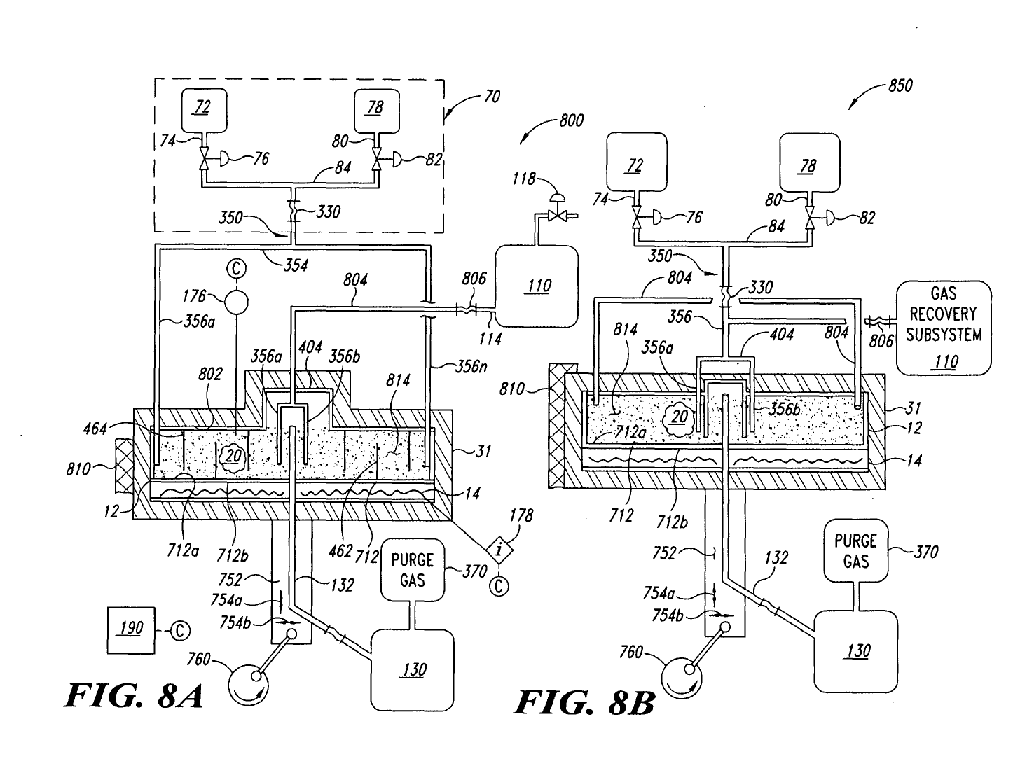

FIG. 8A shows yet another illustrative mechanically fluidized reactor system 800 having a serpentine flow pattern through the mechanically fluidized particulate bed 20 and in which a major horizontal surface 712 carrying the plurality of particulates extends across a cross section of the reactor vessel 31 and the entire vessel 31 is oscillated or vibrated to provide the mechanically fluidized particulate bed 20, according to an embodiment. For clarity, the gas distribution system 350 is depicted without outer tube member 386, however it should be understood that the gas distribution system 350 depicted in FIG. 8A may include any of the insulation or cooling systems depicted in FIGS. 3B-3E. In reactor system 800, a single chamber in the reactor vessel 30 holds the mechanically fluidized particulate bed 20 and no upper chamber or lower chamber exists. Advantageously, in the reactor system 800 many of the components such as the thermal energy emitting devices 14 are externally accessible, simplifying maintenance, repair, and replacement activities.

A major horizontal surface 712 extends across the cross section of the interior of the reactor vessel 30. The one or more thermal energy emitting devices 14 are positioned, proximate the lower surface 712b of the major horizontal surface 712, between the major horizontal surface 712 and the reactor wall 31. The major horizontal surface 712 includes an upper surface 712a and a lower surface 712b. The interior of the reactor walls 31 and the major horizontal surface 712 form an enclosed retention volume 814. The retention volume 814 retains the mechanically fluidized particulate bed 20.

The injectors 356 introduce the first gaseous chemical species and any optional diluent(s) to the mechanically fluidized particulate bed 20 at any number of locations about the periphery of the mechanically fluidized particulate bed 20. In operation, the first gaseous chemical species and any diluent(s) flow through the mechanically fluidized particulate bed 20 into the raised second portion 404. Exhaust gas trapped in the second portion 404 flows via one or more fluid conduits 804 to the gas recovery system 110. In some instances, at least a portion of the one or more components (e.g., the first gaseous chemical species) can be separated from the exhaust gas and recycled to the reactor vessel 30. One or more expansion joints or isolators 806a-806b isolate the gas recovery system 110 from the oscillating reactor vessel 30. In some implementations, a purge gas supplied by the purge gas system 370 flow through the coated particle overflow conduit 132 and into the second portion 404.

The reactor vessel 30 is oscillated or vibrated using a mechanical, electrical, magnetic, or electromagnetic system capable of displacing the reactor vessel 30 at a desired oscillatory or vibratory frequency and displacement. In some implementations, a cam 760 causes a transmission member 752 to oscillate or vibrate the reactor vessel 30 along one or more axes of motion. For example, in some implementations, the transmission member 752 can oscillate the reactor vessel 30 along a single axis of motion 754a that is substantially perpendicular to the major horizontal surface 712. In another example, the transmission member 752 can oscillate or vibrate the reactor vessel 30 along an axis having components that lie along a first axis of motion that is substantially perpendicular to the major horizontal surface 712 and a second axis of motion 754b that is orthogonal to the first axis of motion 754a.

In some instances, insulative material 810 may be disposed about the exterior of the reactor vessel 30 in locations proximate those areas of the reactor maintained at elevated temperature, such as the external surfaces of the reactor vessel 30 proximate the mechanically fluidized particulate bed 20 or thermal energy emitting device 14. In other instances, insulative material may be disposed about the interior of the reactor vessel 30 in locations proximate those areas of the reactor maintained at elevated temperature, such as the external surfaces of the reactor vessel 30 proximate the mechanically fluidized particulate bed 20 or thermal energy emitting device 14.

FIG. 8B shows yet another illustrative mechanically fluidized reactor system 850 in which a major horizontal surface 712 carrying the plurality of particulates extends across a cross section of the reactor vessel 30 and the entire vessel 30 is oscillated or vibrated to provide the mechanically fluidized particulate bed 20, according to an embodiment. For clarity, the gas distribution system 350 is depicted without outer tube member 386, however it should be understood that the gas distribution system 350 depicted in FIG. 8B may include any of the insulation or cooling systems depicted in FIGS. 3B-3E. In reactor system 850, a single chamber in the reactor vessel 30 holds the mechanically fluidized particulate bed 20 and no upper chamber or lower chamber exists. Advantageously, in a reactor system 850 many of the components such as the thermal energy emitting devices 14 are externally accessible, simplifying maintenance activities.

A major horizontal surface 712 extends across the cross section of the interior of the reactor vessel 30. The one or more thermal energy emitting devices 14 are positioned proximate the lower surface 712b of the major horizontal surface 712, between the major horizontal surface 712 and the reactor wall 31. The major horizontal surface 712 includes an upper surface 712a and a lower surface 712b. The interior of the reactor walls 31 and the major horizontal surface 712 form an enclosed retention volume 814. The retention volume 814 retains the mechanically fluidized particulate bed 20.

The injectors 356 introduce the first gaseous chemical species and any diluent(s) to the mechanically fluidized particulate bed 20 at one or more central locations, for example in the second section 404. A cover 852 is disposed a distance from the coated particle overflow conduit 132 to prevent the direct flow of the first gaseous chemical species and any diluent(s) from the injectors 356 to the coated particle overflow conduit 132. Cover 852 also helps improve the utility and efficiency of the upwardly flowing countercurrent purge gas through the coated particle overflow conduit 132. In some instances, the injectors 356 extend into the mechanically fluidized particulate bed 20, below the open end of the coated particle overflow conduit 132. In some instances, the injectors 356 extend below the elevation of the downturned “sides” of the cover 852.

In some implementations the purge gas system 370 supplies an inert purge gas to the particle removal conduit 132. The purge gas flows countercurrent to the coated particles 22 and enters the mechanically fluidized particulate bed 20 via the particle removal conduit 132. Such countercurrent purge gas flow assists in reducing the entry of the first gaseous chemical species into the coated particle overflow conduit 132.

Such countercurrent purge gas also can be used to selectively separate coated particles 22 having one or more desirable properties (e.g., coated particle diameter) from the mechanically fluidized particulate bed 20. For example, increasing the flow of purge gas tends to increase countercurrent gas velocity within the coated particle overflow tube 132 which tends to return smaller diameter coated particles back to the mechanically fluidized particulate bed 20. Conversely, decreasing the flow of purge gas tends to decrease countercurrent gas velocity within the coated particle overflow tube 132 which tends to separate smaller diameter coated particles from the mechanically fluidized particulate bed 20.

In operation, the first gaseous chemical species and any diluent(s) flow through the mechanically fluidized particulate bed 20 to the one or more peripheral fluid conduits 804 that convey gases from the mechanically fluidized particulate bed 20 to the gas recovery system 110. One or more expansion joints or isolators 806a-806b isolate the gas recovery system 110 from the oscillating reactor vessel 30.

The reactor vessel 30 is oscillated or vibrated using a mechanical, electrical, magnetic, or electromagnetic system capable of displacing the reactor vessel 30 at a desired oscillatory or vibratory frequency and displacement. In some implementations, a cam 760 causes a transmission member 752 to oscillate or vibrate the reactor vessel 30 along one or more axes of motion. For example, in some implementations, the transmission member 752 can oscillate the reactor vessel 30 along a single axis of motion 754a that is substantially perpendicular to the major horizontal surface 712. In another example, the transmission member 752 can oscillate or vibrate the reactor vessel 30 along an axis having components that lie along a first axis of motion that is substantially perpendicular to the major horizontal surface 712 and a second axis of motion 754b that is orthogonal to the first axis of motion 754a.

In some instances, insulative material 810 may be disposed about the exterior of the reactor vessel 30 in locations proximate those areas of the reactor maintained at elevated temperature, such as the external surfaces of the reactor vessel 30 proximate the mechanically fluidized particulate bed 20 or thermal energy emitting device 14. In other instances, insulative material may be disposed about the interior of the reactor vessel 30 in locations proximate those areas of the reactor maintained at elevated temperature, such as the external surfaces of the reactor vessel 30 proximate the mechanically fluidized particulate bed 20 or thermal energy emitting device 14.

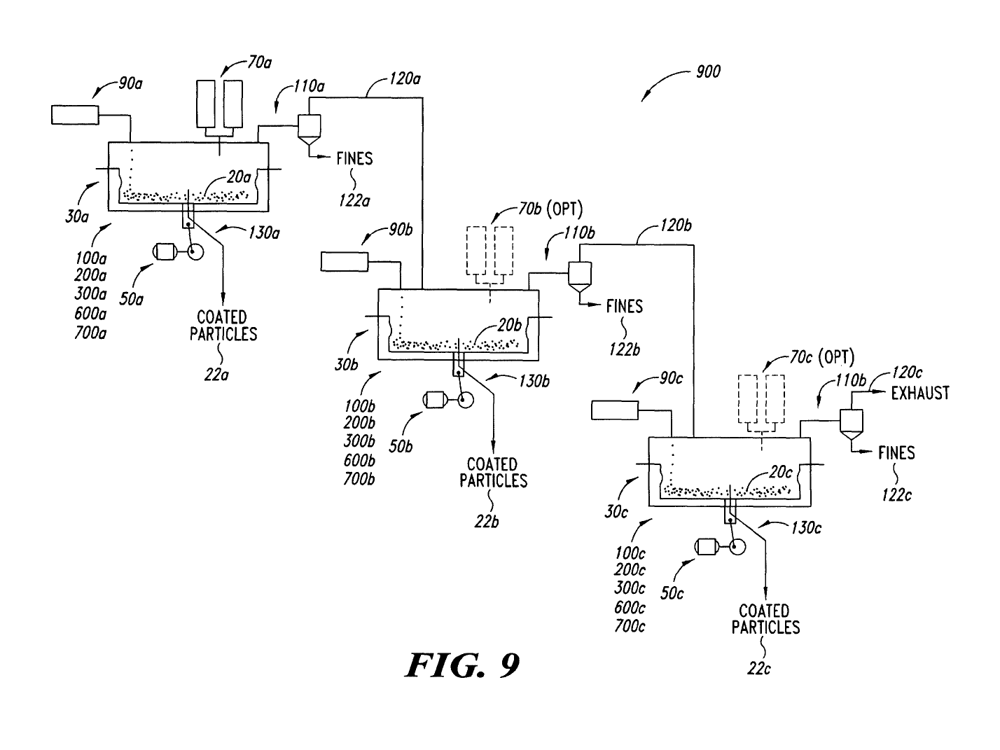

FIG. 9 shows a process 900 useful for the production of second chemical species coated particles, for example polysilicon coated particles, reaction vessels such as the illustrative mechanically fluidized bed reaction systems discussed in detail with regard to FIGS. 1, 2, 3A-3E, 4A-4C, 5A-5D, 6, 7A-7D and 8A-8B. In such an arrangement an exhaust 120a from the first mechanically fluidized bed reaction vessel may contain residual undecomposed first gaseous chemical species, one or more third gaseous chemical species byproducts, and one or more diluent(s). The exhaust 120a is introduced to the second mechanically fluidized bed reaction vessel where an additional portion of the residual first chemical species present in the exhaust 120a thermally decomposes. The exhaust 120b from the second reaction vessel includes residual undecomposed first gaseous chemical species, one or more third gaseous chemical species byproducts, and one or more diluent(s). The exhaust 120b is introduced to a third reaction vessel where an additional portion of the residual first chemical species present in the exhaust 120b further thermally decomposes. Advantageously, the use of such a serial process can provide an overall conversion of the first gaseous chemical species to the second chemical species in excess of 99%.

The first gaseous chemical species and any diluent(s) are added via the gas supply system 70a to the first reaction vessel. A portion of the first gaseous chemical species thermally decomposes within the mechanically fluidized particulate bed 20a in the first reaction vessel. Gas recovery system 110a collects exhaust gas containing undecomposed first gaseous chemical species, one or more third gaseous chemical species byproducts, and any diluent(s) from the first reaction vessel.

Coated particle collection system 130a removes at least a portion of the plurality of coated particles 22a present in the particulate bed 20a that meet one or more defined physical criteria (e.g., particle diameter, density). Product coated particles 22a are removed from the coated particle collection system 130a. In some implementations, coated particles 22a are continuously removed from the particulate bed 20a. If needed, fresh particles 92a may be added to the particulate bed 20a by the particulate supply system 90a.

In the first reaction vessel, the conversion of the first gaseous chemical species to the second chemical species can be greater than about 70%; greater than about 75%; greater than about 80%; greater than about 85%; or greater than about 90%. A portion of the undecomposed first gaseous chemical species, one or more third gaseous chemical species byproducts, and one or more diluent(s) removed from the first reaction vessel via the gas collection system 110a and directed to the second reaction vessel.

In the second reaction vessel, an optional second gas supply system 70b (shown dashed in FIG. 9) may be used to provide additional first gaseous chemical species and/or diluent(s) or a mixture of both the first gaseous chemical species and diluent(s). A portion of the residual first gaseous chemical species present in the exhaust 120a from the first reaction vessel is thermally decomposed within the mechanically fluidized particulate bed 20b. Gas recovery system 110b collects exhaust gas containing undecomposed first gaseous chemical species, one or more third gaseous chemical species byproducts, and any diluent(s) from the second reaction vessel.

Coated particle collection system 130b removes at least a portion of the plurality of coated particles 22b present in the particulate bed 20b that meet one or more defined physical criteria (e.g., particle diameter, density). Product coated particles 22b are removed from the coated particle collection system 130b. In some implementations, coated particles 22b are continuously removed from the particulate bed 20b. If needed, fresh particles 92b may be added to the particulate bed 20b by the particulate supply system 90b.

In the second reaction vessel, the conversion of the first gaseous chemical species to the second chemical species can be greater than about 70%; greater than about 75%; greater than about 80%; greater than about 85%; or greater than about 90%. The overall conversion through the first and second reaction vessels can be greater than about 90%; greater than about 92%; greater than about 94%; greater than about 96%; greater than about 98%; greater than about 99%. A portion of the undecomposed first gaseous chemical species, one or more third gaseous chemical species byproducts, and one or more diluent(s) removed from the second reaction vessel via the gas collection system 110b and directed to the third reaction vessel.

In the third reaction vessel, an optional second gas supply system 70c (shown dashed in FIG. 9) may be used to provide additional first gaseous chemical species and/or diluent(s) or a mixture of both the first gaseous chemical species and diluent(s). A portion of the residual first gaseous chemical species present in the exhaust 120b from the second reaction vessel is thermally decomposed within the mechanically fluidized particulate bed 20c. Gas recovery system 110c collects exhaust gas containing undecomposed first gaseous chemical species, one or more third gaseous chemical species byproducts, and any diluent(s) from the third reaction vessel.

Coated particle collection system 130c removes at least a portion of the plurality of coated particles 22c present in the particulate bed 20c that meet one or more defined physical criteria (e.g., particle diameter, density). Product coated particles 22c are removed from the coated particle collection system 130c. In some implementations, coated particles 22c are continuously removed from the particulate bed 20c. If needed, fresh particles 92c may be added to the particulate bed 20c by the particulate supply system 90c.

In the third reaction vessel, conversion of the first chemical species to the second chemical species can be greater than about 70%; greater than about 75%; greater than about 80%; greater than about 85%; or greater than about 90%. The overall conversion through the first, second, and third reaction vessels can be greater than about 94%; greater than about 96%; greater than about 98%; greater than about 99%; greater than about 99.5%; or greater than about 99.9%. Gas recovery system 110c collects exhaust gas containing undecomposed first gaseous chemical species, one or more third gaseous chemical species byproducts, and any diluent(s) from the third reaction vessel and treated, recycled, or discharged.

The systems and processes disclosed and discussed herein for the production of silicon have marked advantages over systems and processes currently employed. The systems and processes are suitable for the production of either semiconductor grade or solar grade silicon. The use of high purity silane as the first chemical species in the production process allows a high purity silicon to be produced more readily. The system advantageously maintains the silane at a temperature below the thermal decomposition temperature; for example below 400° C., until the silane enters the mechanically fluidized particulate bed. By maintaining temperatures outside of the mechanically fluidized particulate bed below the thermal decomposition temperature of silane, the overall conversion of silane to usable polysilicon deposited on the particles within the mechanically fluidized particulate bed is increased and parasitic conversion losses attributable to decomposition of silane and deposition of polysilicon on other surfaces within the reactor are minimized.

The mechanically fluidized bed systems and methods described herein greatly reduce or eliminate the formation of ultra-fine poly-powder (e.g., 0.1 to several microns in size) external to the mechanically fluidized particulate bed 20 since the temperature of the gas containing the first chemical species is maintained below the auto-decomposition temperature of the first chemical species. Additionally, the temperature within the chamber 32 is also maintained below the thermal decomposition temperature of the first chemical species further reducing the likelihood of auto-decomposition. Further, any small particles formed in the mechanically fluidized bed, by abrasion, physical damage or attrition for example, generally having a diameter significantly greater than 0.1 micron, but less than 250 microns are carried out of the chamber 32 with the exhaust gas. The diameter of the small particles so removed via the exhaust gas may be controlled by varying the width 319b of the opening 318 fluidly coupling the mechanically fluidized bed 20 with the upper chamber 33 as described herein. As a result, the formation of product particles having a desirable size distribution is more readily achieved

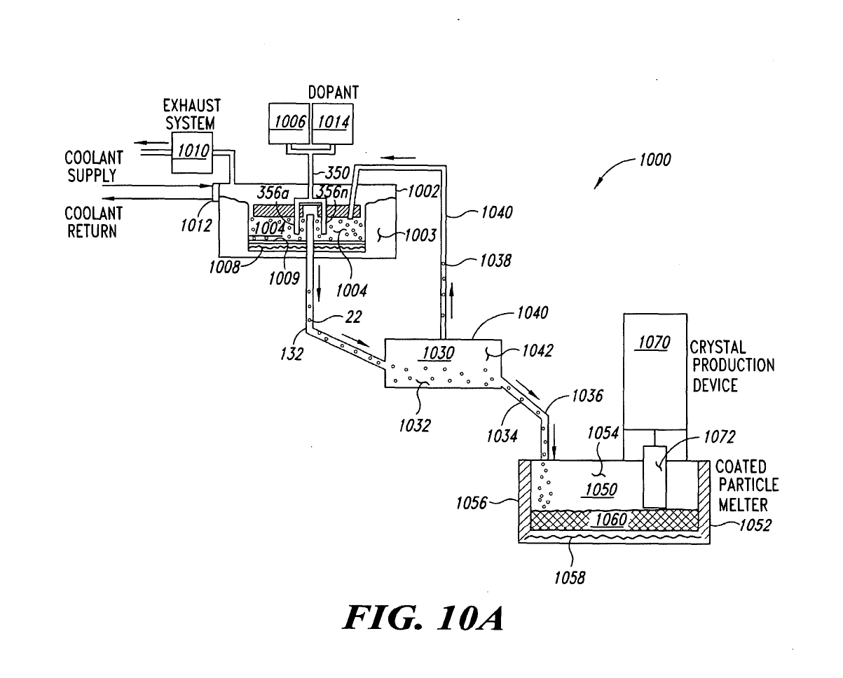

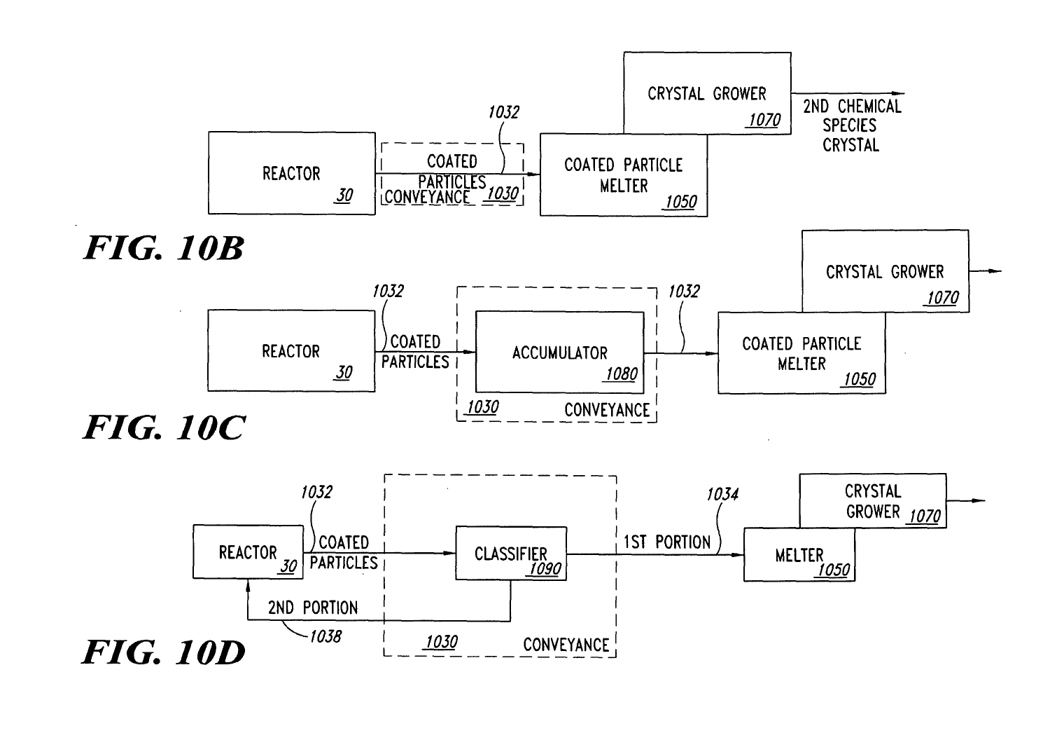

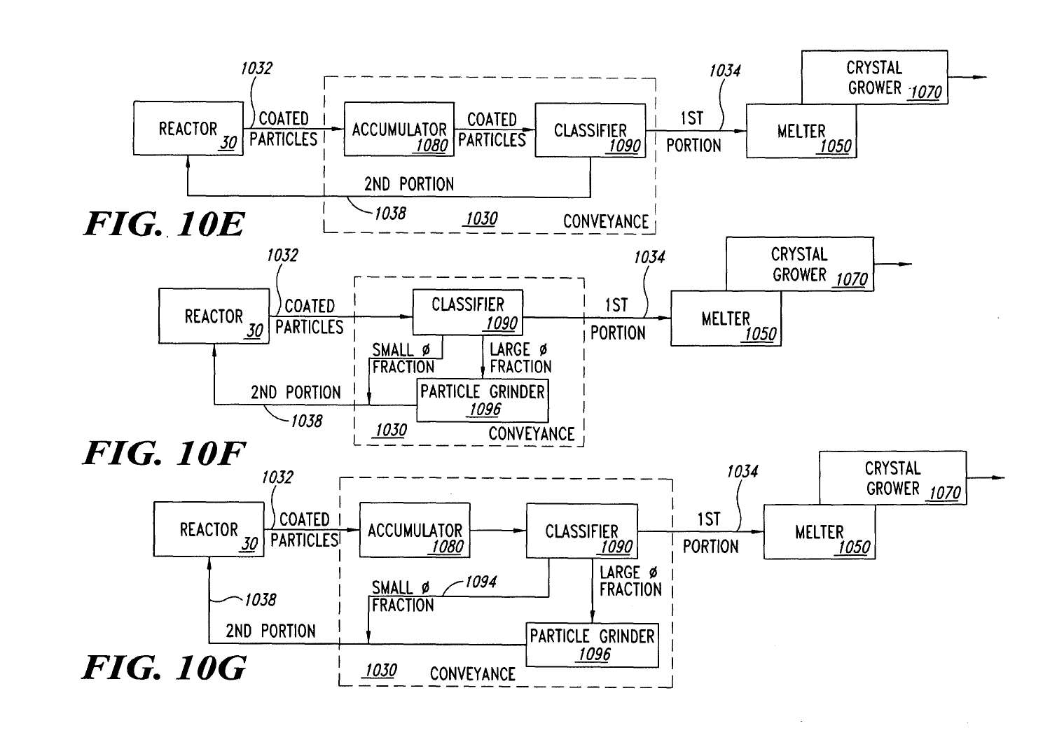

FIG. 10A shows an illustrative crystal production system 1000 that includes one or more systems for separating coated particles 22 from a particulate bed 1004, one or more conveyances 1030 to convey the coated particles 22 from the particulate bed 1004 in an environment having a low oxygen level or a very low oxygen level and an environment containing low levels of contaminants or very low level of contaminants, one or more coated particle melters 1050 to melt the coated particles 22, and one or more optional crystal production devices 1070, according to an embodiment. In at least some implementations, a first gaseous chemical species is introduced to the particulate bed 1004. At least a portion of the first gaseous chemical species is decomposed in the particulate bed 1004 to provide a second chemical species which deposits on at least a portion of the particulates in the particulate bed. The particulates containing the second chemical species provide a plurality of coated particles 22 which, at times, freely circulate throughout the particulate bed 1004. On a periodic, intermittent, or continuous basis, at least a portion of the plurality of coated particles 22 are separated from the particulate bed 1004 and directed to a conveyance 1030. The conveyance 1030 receives some or all of the separated coated particles 1032.

As used herein, the term “low contaminant level” refers to an environment which favors the production of second chemical species crystals having low contamination levels (e.g., “solar grade” silicon, polysilicon, polycrystalline silicon, or monocrystalline silicon crystals) that meet at least one of the following specifications: an oxygen concentration of less than 1.5×10⁻¹⁷ atoms per cubic centimeter (atoms/cc); a carbon concentration of less than about 4.5×10¹⁶ atoms/cc; a benefactor impurities concentration of less than about 7.8 parts per billion atomic (ppba); an acceptor impurities concentration of less than about 2.7 ppba; and total metal impurities (iron, chrome, nickel, copper, zinc) of less than about 0.2 parts per million by weight (ppmw).

As used herein, the term “very low contaminant level” refers to an environment which favors the production of second chemical species crystals having very low contamination levels (e.g., “electronics grade” silicon, polysilicon, polycrystalline silicon, or monocrystalline silicon crystals) that meet or exceed at least one of the following specifications: an oxygen concentration of less than 1.0×10⁻¹⁷ atoms per cubic centimeter (atoms/cc); a carbon concentration of less than about 80 ppba; a donor (phosphorous, arsenic, antimony) impurities concentration of less than about 150 parts per trillion atomic (ppta); an acceptor (boron, aluminum) impurities concentration of less than about 50 ppta; bulk metal impurities (iron, chrome, nickel, copper, zinc) of less than about 1.5 parts per billion by weight (ppbw); surface iron concentration of less than about 2 ppbw; surface copper concentration of less than about 500 parts per trillion by weight (pptw); surface nickel concentration of less than 500 pptw; surface chromium concentration of less than 500 pptw; surface zinc concentration of less than 1000 pptw; and surface sodium concentration of less than about 2000 pptw.

The systems and methods described herein are applicable to a variety of different crystal production methods. For example, all or a portion of the separated coated particles 1032 may be introduced to a Float Zone crystal production process 1070 in which a second chemical species crystal (e.g., a crystal formed by the separated coated particles 1032) is progressively melted and solidified to provide a second chemical species crystal having a high purity. In another embodiment, all or a portion of the separated coated particles 1032 may be introduced to a Bridgman-Stockbarger crystal production process in which a crucible containing the molten second chemical species is cooled at a controlled rate to produce a second chemical species crystal having a high purity.

At times, the conveyance 1030 is a simple transport device or system capable of moving, transporting, or otherwise conveying at least a first portion of the separated coated particles 1034 to the coated particle melter 1030. At other times, the conveyance 1030 can include multiple unit operations, such as separated coated particle storage/accumulation, separated coated particle size classification, and/or separated coated particle size reduction processes. Regardless of the functions provided by the conveyance 1030, at all times the conveyance 1030 maintains the separated coated particles 1032 in an environment having an environment that is maintained at a low oxygen level or a very low oxygen level. Such low oxygen environments advantageously minimize, reduce or even eliminate oxide formation on the surface of the separated coated particles 1032.

At times, the conveyance 1030 can include a one or more apparatuses, systems, or devices that are hermetically sealed to and fluidly couple one or more fluidized bed coated particle production processes to one or more crystal production systems or devices, such as one or more coated particle melters 1050 and crystal production devices 1070. At other times, the conveyance 1030 can include one or more moveable apparatuses, systems, or devices that are capable of being hermetically sealed and fluidly coupled to one or more fluidized bed coated particle production processes and hermetically sealed and fluidly coupled to one or more crystal production systems or devices, such as one or more coated particle melters 1050 and crystal production devices 1070.

The minimization, reduction, or elimination oxide formation on the surface of the separated coated particles 1032 is particularly advantageous when the second chemical species includes silicon, since the formation of silicon oxides can significantly compromise the purity and/or quality of silicon crystals produced using the separated silicon coated particles 1032 and disadvantageously raise the melting point of the smaller diameter silicon coated particles. The presence of silicon oxides on the surface of silicon coated particles detrimentally increases the melt time and energy required to melt such particles when compared to silicon coated particles without a silicon oxide layer. At times, it is believed the presence of silicon oxides on the surface of silicon coated particles 1032 may have melting points that exceed the melting point of pure silicon (i.e., silicon coated particles 1032 lacking the silicon dioxide layer) by at least about 10° C.; at least about 50° C.; or at least about 100° C.

Such effects are particularly evident with smaller diameter silicon coated particles 1032 because—while the thickness of the silicon oxide shell is independent of the silicon coated particle diameter (e.g., the shell may be from 10 to 20 silicon dioxide molecules thick)—the mass ratio of the silicon dioxide layer on the surface of the silicon coated particle 1032 to the mass of the particle is inversely proportional to the diameter of the particle. For example, when the diameter is reduced by one-half the aforementioned mass ratio of silicon dioxide on the surface of a smaller diameter silicon coated particle 1032 to pure silicon in the interior of the smaller diameter silicon coated particle 1032 increases 2 times.

At times, the particulate bed 1004 can be disposed at least partially in a reactor housing 1002 defining a chamber 1003. The chamber 1003 may be maintained at one or more defined temperatures or temperature ranges. The temperature of the particulate bed 1004 may be altered, adjusted, or controlled using one or more thermal energy emitting systems 1008, for example one or more electric resistance heaters or one or more heat transfer surfaces that uses a circulated thermal transfer fluid (e.g., thermal oil) or material (e.g., molten salt). At times, the temperature of the particulate bed 1004 can be controlled to exceed the thermal decomposition temperature of the first gaseous chemical species while the temperature at other points in the chamber 1003 can be controlled to lower than the thermal decomposition temperature of the first gaseous chemical species. In some implementations, one or more thermal energy transfer devices 1012 may be physically and/or thermally conductively coupled to the vessel 1002 to remove thermal energy (i.e., heat) from the chamber 1003.

The thermal energy emitting systems 1008 increase the temperature of the particulate bed 1004 above the thermal decomposition temperature of the first gaseous chemical species. For example, where the first gaseous chemical species includes silane, the thermal energy emitting systems 1008 can increase the temperature of the particulate bed 1004 above 420° C., the thermal decomposition temperature of silane. In at least some implementations, the first gaseous chemical species may be preheated prior to introduction to the particulate bed 1004. Preheating of the first gaseous chemical species beneficially reduces the heat load on the thermal energy emitting systems 1008. The first gaseous chemical species may be preheated to about 100° C.; about 200° C.; about 300° C.; or about 400° C. The first gaseous chemical species may be heated using a feed heater or a heat interchanger where hot gases leaving the particulate bed 1004 are used as the pre-heating medium. The thermal energy emitting systems 1008 may include any number or combination of thermal energy emitting devices, systems, or combinations thereof. The thermal energy emitting systems 1008 can increase the temperature of the surface 1009 supporting the particulate bed 1004, thereby conductively transferring heat to and raising the temperature of the particulate bed 1004. The thermal energy emitting devices 1008 can include any number or combination of electrically powered heating elements such as resistive heaters (e.g., Calrod, Nichrome, and the like), ceramic heating elements (e.g., molybdenum disicilide, PTC ceramics, and the like), and/or radiant heating elements positioned beneath and proximate the surface 1009 supporting the particulate bed 1004. The thermal energy emitting devices 1008 can also include any number or combination of circulated heat transfer fluid systems, for example Dynalene molten salts (Dynalene, Inc. Whitehall, Pa.).

At times, the first gaseous chemical species may be heated to a temperature in the range of from about 50° C. to about 450° C., or about 350° C. Preheating the first gaseous chemical species to a temperature of about 350° C. beneficially reduces the heat load on the thermal energy emitting systems 1008. The thermal energy used to raise the temperature of the first gaseous chemical species can be supplied in whole or in part using one or more external electric heaters. Such thermal energy may be provided by one or more external electric heaters, one or more external fluid heaters, or one or more heat interchanges or exchangers where hot gases are used to heat the incoming feed.

Passing at least a portion of the first gaseous chemical species through the upper zone of the reactor housing 1002 may preheat the first gaseous chemical species to a temperature that is below the thermal decomposition temperature of the first gaseous chemical species. At times, the first gaseous chemical species may be passed through one or more heat exchange stages located in the chamber 1003 of the reactor housing 1002 where the temperature of the first gaseous chemical species is increased to a level that is slightly less than the thermal decomposition temperature of the first gaseous chemical species. Further, the temperature of the gas in chamber 1003 may be controlled below the decomposition temperature of the first gaseous chemical species by means of auxiliary cooling (e.g., a fluid cooler in a cooling coil) positioned in the chamber or upper zone of the chamber 1003. Such an approach provides several benefits:
1. The mixed first gaseous chemical species to the particulate bed 1004 is controlled at an optimum temperature; and
2. The upper zone of the chamber 1003 in the reactor housing 1002 is maintained below the decomposition temperature, minimizing, reducing or even eliminating the thermal decomposition of the first gaseous chemical species at locations in the reactor housing 1002 external to the particulate bed 1004.

The reactor housing 1002 can include one or more thermal energy transfer systems 1012 that maintain the temperature of the chamber 1003 below the thermal decomposition temperature of the first gaseous chemical species. Maintaining the temperature of the chamber 1003 below the thermal decomposition temperature of the first gaseous chemical species advantageously reduces the likelihood of the first gaseous chemical species decomposing in the chamber 1003 in locations external to the particulate bed 1004. In other words, maintaining the temperature of the particulate bed 1004 above the thermal decomposition temperature of the first gaseous chemical species while maintaining the temperature elsewhere in the chamber 1003 below the thermal decomposition temperature of the first gaseous chemical species beneficially favors deposition of the second chemical species in the particulate bed 1004 rather than on surfaces in the chamber 1003. In some implementations, the first gaseous chemical species is maintained at a temperature below the thermal decomposition temperature of the first gaseous chemical species at all times and locations prior to discharge into the particulate bed 1004. The one or more thermal energy transfer systems 1012 can include any number or combination of systems and/or devices suitable for maintaining the chamber 1003 at a temperature below the thermal decomposition temperature of the first gaseous chemical species, including internal cooling coils.

The exhaust gas system 1010 is fluidly coupled to the chamber 1003 to receive exhaust gasses from the chamber 1003. The decomposition of the first gaseous chemical species in the particulate bed 1004 may, at times, produce one or more inert byproducts, for example one or more third gaseous chemical species. Left in the chamber 1003, such gaseous byproducts can accumulate and adversely affect system pressure control and the conversion and/or yield of the first gaseous chemical species to the second chemical species. To limit their accumulation in the chamber, gaseous byproducts are removed via one or more exhaust gas systems 1010.

A first gaseous chemical species feed system 1006 supplies the first gaseous chemical species to the particulate bed 1004. The first gaseous chemical species feed system 1006 can include one or more first gaseous chemical species reservoirs for storing the first gaseous chemical species, a distribution header 350, and any number of injectors 356 fluidly coupled to the distribution header 350 and positioned in the particulate bed 1004. In some instances, the distribution header 350 and/or the number of injectors 356 can be thermally insulated to limit heating of the first gaseous chemical species in the distribution header 350 and/or injectors 356. In such instances, the thermal insulation may limit the temperature of the first gaseous chemical species in the distribution header a 350 and/or injectors 356 to less than the thermal decomposition temperature of the first gaseous chemical species.

In some instances, a dopant feed system 1014 supplies one or more dopants to the chamber 1003 or directly to the particulate bed 1004. At times, the dopant feed system 1014 is fluidly coupled to the first gaseous chemical species feed system 1006 such that the first gaseous chemical species and the dopant are supplied via the number of injectors 356 to the particulate bed 1004. At other times, the dopant feed system 1014 is separately fluidly coupled to the particulate bed 1004 and/or the chamber 1003. The one or more dopants can be added to the particulate bed 1004 contemporaneous with the feed of the first gaseous chemical species to the particulate bed 1004 to produce doped coated particles. Additionally or alternatively, the one or more dopants may be added to the particulate bed 1004 at times when the first gaseous chemical species is not added to the particulate bed 1004. Illustrative dopants may include, but are not limited to, arsenic, germanium, selenium, and/or gallium. An example doped coated particle 22 produced by the reactor system 1000 includes coated particles 22 containing boron or phosphorous doped silicon.

The decomposition of the first gaseous chemical species can include one or more chemical decomposition processes, one or more thermal decomposition processes, or combinations thereof. For example, the first gaseous chemical species can include a silicon-containing gas that thermally decomposes when introduced to a heated particulate bed 1004 held at a temperature in excess of the thermal decomposition temperature of the first gaseous chemical species. The nonvolatile second chemical species is produced by the decomposition of the first gaseous chemical species and may deposit on proximate surfaces (e.g., the surfaces of the particulates in the particulate bed 1004) at the moment of decomposition of the first gaseous chemical species. At times, the first gaseous chemical species can include a silicon containing gas and the second chemical species can include silicon. Non-limiting examples of such silicon containing gases include silane (SiH₄); dichlorosilane (H₂SiCl₂); or trichlorosilane (HSiCl₃). At times one or more byproduct third gaseous species (e.g., hydrogen, hydrogen chloride) may be generated by the thermal decomposition of the first gaseous chemical species in the particulate bed 1004.

The first gaseous chemical species may be supplied to the particulate bed 1004 via the one or more injectors 352, each of which includes one or more outlets 352 positioned in the particulate bed 1004 such that the first gaseous chemical species travels at least a minimum defined distance through the particulate bed 1004 or, alternatively, is retained in the particulate bed 1004 for at least a defined minimum retention time. In addition to depositing the non-volatile second chemical species on at least some of the particulates in the particulate bed 1004, the decomposition of the first gaseous chemical species can produce one or more third gaseous byproducts, such byproducts are typically inert and may, at times, be chemically similar or identical to the one or more diluents used to adjust the concentration of the first gaseous chemical species in the particulate bed 1004.

Coated particles 22 are separated from the particulate bed 1004 using any current or future developed separation system or process including mechanical or hydraulic fluidization of the particulate bed 1004 coupled with one or more devices or systems capable of selectively separating the coated particles 22 from the particulate bed 1004. Coated particles 22 removed from the particulate bed 1004 are collected and directed to the conveyance 1030. At times, the plurality of coated particles 22 removed from the heated particulate bed 1004 can have a dp₅₀ (i.e., the mass of coated particles smaller than the specified size comprising 50% of the total sample) less than or equal to 10000 micrometers (μm); less than or equal to 5000 μm; less than or equal to 3000 μm; less than or equal to 2000 μm; less than or equal to 1000 μm; less than or equal to 500 μm; less than or equal to 300 μm; less than or equal to 100 μm. At times, the plurality of coated particles 22 removed from the heated particulate bed 1004 can have a diameter of about 10 micrometers (μm) or more; about 20 μm or more; about 50 μm or more; about 100 μm or more; about 200 μm or more; about 500 μm or more; or about 1000 μm or more.

At times, the coated particles 22 removed from the heated particulate bed 1004 may have a Gaussian particle size distribution with a minimum size of less than about 10 micrometers (μm); less than about 20 μm; less than about 50 μm; less than about 75 μm; less than about 125 μm; less than about 150 μm; or less than about 200 μm. At times, the coated particles 22 removed from the heated particulate bed 1004 may have a Gaussian particle size distribution with a maximum size of less than about 300 micrometers (μm); less than about 500 μm; less than about 600 μm; less than about 750 μm; less than about 1 millimeter (mm); less than about 1.5 mm; less than about 2 mm; or less than about 5 mm. At times, the coated particles 22 removed from the particulate bed may have a Gaussian particle size distribution with a mean size of about 100 micrometers (μm); about 200 μm; about 400 μm; about 600 μm; about 800 μm; about 1 millimeter (mm); about 1.5 mm; or about 2 mm.

The environment within the chamber 1003 is maintained at a low oxygen level (e.g., less than 20 volume percent oxygen) or a very low oxygen level (e.g., less than 0.001 mole percent oxygen to less than 1 mole percent oxygen). In some instances, the environment within the chamber 1003 is maintained at a low oxygen level that does not expose the coated particles 22 to atmospheric oxygen. In some instances, the environment within the chamber 1003 is maintained at a low oxygen level having an oxygen concentration of less than 20 volume percent (vol %). In some instances, the environment within the chamber 1003 is maintained at a very low oxygen level having an oxygen concentration of less than about 1 mole % (mol %); less than about 0.5 mol %; less than about 0.3 mol %; less than about 0.1 mol %; less than about 0.01 mol %; or less than about 0.001 mol %.

Since the chamber 1003 is maintained at a low oxygen level or a very low oxygen level, oxide formation on the surface of the coated particles 22 is beneficially minimized, reduced, or even eliminated. In one example, silicon coated particles 22 produced in the heated particulate bed 1004 can have an oxygen content as silicon dioxide of less than about 100 parts per million atomic (ppma) oxygen; less than about 50 ppma oxygen; less than about 10 ppma oxygen; or less than about 1 ppma oxygen.

Additionally, since very low levels of contamination exist in the chamber 1003 by virtue of the closed environment therein, and since the opportunity for contamination of the coated particles 22 by impurities is minimized by the low or very low oxygen levels and the low or very low contaminant levels, for example metal atoms or ions, in the environment provided by the enclosed conveyance 1030, coated particle melter 1050, and crystal production device 1070, the production of second chemical species crystals having very low levels of contamination is possible,

The relatively low levels of contamination achievable in such a production and conveyance process facilitates the use of both small and large diameter separated coated particles 1032 in subsequent crystal production processes. Providing the capability to use small and large diameter coated particles for crystal production can advantageously, at times, eliminate the need to classify and remove smaller diameter coated particles via classification—a process that frequently exposes the separated coated particles 1032 to significant contaminants (e.g., metallic contamination from classification screens) and oxygen.

At times, the chamber 1003 is maintained at a low contaminant level environment or a very low contaminant level environment. In some instances, the second chemical species crystals 1072 produced using silicon coated particles 22 produced in such low contaminant level or very low contaminant level environments can meet or exceed electronics grade silicon specifications. In such instances, the second chemical species crystals 1072 produced by the crystal production device 1070 can have a resistivity of greater than about 250 Ohm-centimeters (Ω-cm); an oxygen concentration of less than 1.0×10⁻¹⁷ atoms per cubic centimeter (atoms/cc); a carbon concentration of less than about 80 ppba; a donor (phosphorous, arsenic, antimony) impurities concentration of less than about 150 parts per trillion atomic (ppta); an acceptor (boron, aluminum) impurities concentration of less than about 50 ppta; bulk metal impurities (iron, chrome, nickel, copper, zinc) of less than about 1.5 parts per billion by weight (ppbw); surface iron concentration of less than about 2 ppbw; surface copper concentration of less than about 500 pptw; surface nickel concentration of less than 500 pptw; surface chromium concentration of less than 500 pptw; surface zinc concentration of less than 1000 pptw; and surface sodium concentration of less than about 2000 pptw.

In other instances, the second chemical species crystals 1072 produced using silicon coated particles 22 produced in such low contaminant level or very low contaminant level environments can meet or exceed solar grade silicon specifications. In such instances, the second chemical species crystals 1072 produced by the crystal production device 1070 can have a resistivity of greater than about 20 Ohm-centimeters (Ω-cm); an oxygen concentration of less than 1.5×10⁻¹⁷ atoms per cubic centimeter (atoms/cc); a carbon concentration of less than about 4.5×10¹⁶ atoms/cc; a benefactor impurities concentration of less than about 7.8 parts per billion atomic (ppba); an acceptor impurities concentration of less than about 2.7 ppba; and total metal impurities (iron, chrome, nickel, copper, zinc) of less than about 0.2 parts per million by weight (ppmw).

As the second chemical species deposits on the particulates in the particulate bed 1004, the diameter of the coated particles 22 present in the particulate bed 1004 increases. In some instances, the second chemical species can deposit on the surface of the particulates and coated particles present in the particulate bed 1004 in the form of sub-particles, thereby forming coated particles comprising an agglomeration of smaller second chemical species sub-particles. In some instances, the second chemical species can deposit in layers on the surface of the particulates and coated particles present in the particulate bed 1004. Coated particles 22 meeting one or more physical and/or compositional criteria are separated from the particulate bed 1004. In some instances, the coated particles 22 separated from the particulate bed travel through a hollow particle removal tube 132 and are deposited in the conveyance 1030.

At times, the conveyance 1030 can be as simple as a hollow tube that connects and hermetically seals the chamber 1003 in the reactor 1002 to the coated particle melter 1050. At other times, the conveyance 1030 can include a number of individual unit operations that includes, but is not limited to, one or more of the following: coated particle 1032 storage or accumulation; coated particle 1032 size classification; coated particle 1032 apportioning into at least a first portion of coated particles 1034 and a second portion of the coated particles 1038; or coated particle 1032 size reduction.

At times, the conveyance 1030 may include one or more fixed components, devices, and/or systems that fluidly couple and hermetically seal the chamber 1003 in the reactor 1002 to the coated particle melter 1050. At other times, the conveyance 1030 can include one or more mobile or moveable components, devices, and/or systems that fluidly couple and hermetically seal the conveyance 1030 to the chamber 1003 in the reactor to receive the coated particles 22, and fluidly couple and hermetically seal the conveyance 1030 to the coated particle melter 1050. Regardless of the form of the conveyance 1030, the conveyance 1030 maintains the separated coated particles 1032 in an environment having a low oxygen level (e.g., less than 20 volume percent oxygen) or a very low oxygen level (e.g., less than 1 mole percent oxygen) that limits the exposure of the separated coated particles 1032 to oxygen.

In some instances, the conveyance 1030 can transport a first portion of the separated coated particles 1034 to the coated particle melter 1050 in a low oxygen level environment that does not expose the first portion of the separated coated particles 1034 to atmospheric oxygen. In some instances, the conveyance 1030 can transport the first portion of the separated coated particles 1034 to the coated particle melter 1050 in an environment maintained at a low oxygen level having an oxygen concentration of less than 20 volume percent (vol %). In some instances, the conveyance 1030 can transport the first portion of the separated coated particles 1034 to the coated particle melter 1050 in an environment maintained at a very low oxygen level having an oxygen concentration of less than about 1 mole % (mol %); less than about 0.5 mol %; less than about 0.3 mol %; less than about 0.1 mol %; less than about 0.01 mol %; or less than about 0.001 mol %.

An oxide layer can form on some or all of the exposed surfaces of the separated coated particles 1032 when the particles are exposed to an oxygen-containing environment. In one example, a silicon dioxide layer can form on the surface of separated silicon coated particles 1032. At times, the oxide layer may partially or completely coat or encase the separated coated particles 1032. At times, such oxide layers may be from 10 to 30 silicon dioxide molecules thick. The formation of an oxide layer about the separated coated particles 1032 detrimentally impacts the quality of items produced using the separated coated particles 1032. For example, it can increase the concentration of oxygen in the second chemical species crystals that are produced using the first portion of the separated coated particles 1034. In addition, theoretically, the presence of a silicon dioxide coating across at least a portion of the surface of the first portion of the separated coated particles 1034 elevates the apparent melting point of the coated particles, this elevation is particularly noticeable in smaller diameter coated particles. For example, the melting point of silicon is approximately 1414° C. and the melting point of silicon dioxide is approximately 1700° C. Small diameter separated coated particles 1032 having 10 to 30 molecule thick layer of silicon dioxide may melt less readily at the melting point of pure silicon.

Additionally, smaller diameter coated particles 22 (e.g., coated particles 22 having a diameter of less than 100 micrometers to about 500 micrometers) tend to “float” on the surface of the molten second chemical species, such as the molten second chemical species 1060 present in the coated particle melter 1050. The propensity for such smaller diameter coated particles 22 to float frequently makes it difficult to melt these particles particularly when the small diameter coated particles include an oxide layer (e.g., silicon dioxide) that increases the effective melting point of the coated particles 1032 above the melting point of the second chemical species (e.g., pure silicon).

The physical aspects (e.g., size, density, surface area/mass ratio, and the like) of the coated particles 22 separated from the particulate bed 1004 can form a distribution. In one implementation, diameters of the coated particles 22 removed from the particulate bed 1004 can form a distribution (e.g., a Gaussian distribution) about a mean coated particle diameter or median coated particle diameter. In some implementations, the coated particles in the conveyance 1030 can be further classified into a first portion of coated particles 1034 forwarded to the coated particle melter 1050 and a second portion of coated particles 1038, at least a portion of which are recycled to the particulate bed 1004. In some instances, the physical aspects (e.g., size, density, surface area/mass ratio, and the like) of the first portion of coated particles 1034 can form a first distribution. For example, the diameters of the coated particles 22 in the first portion of coated particles 1034 can form a Gaussian distribution about a first mean coated particle diameter or a first median coated particle diameter. In some instances, the physical aspects (e.g., size, density, surface area/mass ratio, and the like) of the second portion of coated particles 1038 can form a second distribution. For example, the diameters of the coated particles 22 in the second portion of coated particles 1038 can form a first Gaussian distribution about a second mean coated particle diameter or a second median particle diameter. In some instances, some or all of the first distribution and the second distribution may at least partially overlap. In other instances, the first distribution and the second distribution may not overlap.

At times, the first portion of separated coated particles 1034 can include coated particles having one or more desirable physical or compositional properties or characteristics. Such desirable properties or characteristics may, for example, favor melting the first portion of separated coated particles 1034 in the coated particle melter 1050. For example, the mean diameter of the coated particles in the first portion of separated coated particles 1034 may be greater than the mean diameter of the coated particles in a second portion of separated coated particles 1038. In some instances, the first portion of separated coated particles 1034 may include coated particles having a mean or a median diameter of greater than about 10 micrometers (μm); greater than about 20 μm; greater than about 50 μm; greater than about 100 μm; greater than about 200 μm; greater than about 300 μm; greater than about 400 μm; greater than about 500 μm; or greater than about 600 μm. In some instances, the first portion of separated coated particles 1034 may include coated particles having a diameter of greater than about 50 micrometers (μm); greater than about 100 μm; greater than about 200 μm; greater than about 300 μm; greater than about 400 μm; greater than about 500 μm; or greater than about 600 μm. The first portion of the plurality of coated particles 1034 can include oxygen as a metallic oxide of less than: about 6000 parts per billion atomic (ppba); less than about 3000 ppba; less than about 1000 ppba; less than about 600 ppba; less than about 250 ppba; less than about 100 ppba; less than about 50 ppba; less than about 20 ppba; less than about 10 ppba; less than about 5 ppba; less than about 1 ppba; less than about 0.5 ppba; less than about 0.1 ppba. It is believed the lower levels of silicon oxides (e.g., silicon dioxide) present on the exposed surfaces of the first portion of coated particles 1034 and/or the morphology of the first portion of coated particles 1034 advantageously enables the use of smaller diameter coated particles 1032 in the production of second chemical species crystals.

At times, the second portion of separated coated particles 1038 can include coated particles having one or more desirable physical or compositional properties or characteristics. Such desirable physical or compositional properties or characteristics may, for example, favor returning some or all of the second portion of separated coated particles 1038 back to the particulate bed 1004 and/or removing some or all of the second portion of separated coated particles 1038 from the crystal production system 1000 for additional processing. Such additional processing may include, for example, physically reducing the size (e.g., via grinding) some or all of the second portion of separated coated particles 1038 to a smaller diameter for use as “start-up” or seed particulate returned to the particulate bed 1004. In some instances, the second portion of separated coated particles 1038 may include coated particles having a mean or a median diameter of less than about 600 micrometers (μm); less than about 500 μm; less than about 400 μm; less than about 300 μm; less than about 200 μm; less than about 100 μm; or less than about 50 μm. In some instances, the second portion of separated coated particles 1038 may include coated particles having a diameter of less than about 600 micrometers (μm); less than about 500 μm; less than about 400 μm; less than about 300 μm; less than about 200 μm; less than about 100 μm; or less than about 50 μm.

Separated coated particles 1032 can be classified by physical or compositional properties or characteristics in any of several locations. At times, such classification may be performed in one or more unit operations in the conveyance 1030. In one implementation, the separated coated particles 1032 may be classified by physical or compositional properties or characteristics as the coated particles 22 are separated from the particulate bed 1004 in the reactor housing 1002. In another implementation, the separated coated particles 1032 may be classified by physical or compositional properties upon selective separation into the first portion of coated particles 1034 and the second portion of coated particles 1038 in one or more unit operations in the conveyance 1030. By physically or compositionally classifying coated particles in low oxygen level or very low oxygen level environments such as in the reactor 1012 or in the conveyance 1030, oxide formation on the external surface of the separated coated particles 1032 is minimized, reduced, or even eliminated.

By providing a hermetic seal, low oxygen level environment, very low oxygen level environment, or oxygen free environment between the reactor 1002 and the coated particle melter 1050, the conveyance 1030 beneficially and advantageously minimizes, reduces, or even eliminates oxide formation on the exposed surfaces of the separated coated particles 1032. Taking separated silicon coated particles 1032 as an illustrative example; the elimination of an oxide layer (e.g., silicon oxide, silicon dioxide) on the exposed surfaces of the separated coated particles 1032 provides numerous benefits and advantages over systems and methods in which the coated particles 22 separated from the particulate bed 1034 are unavoidably and/or inadvertently exposed to elevated or atmospheric oxygen levels, such as during handling, storage, and/or transfer.

One such advantage is small diameter separated coated particles 1032 can be included in the first portion of separated coated particles 1034 forwarded to the coated particle melter 1050. Smaller diameter separated silicon coated particles 1032 traditionally have been excluded from the coated particle melter 1050 due to difficulties in melting the smaller particles (e.g., causing a possible melting point rise associated with a higher ratio of the mass of the silicon dioxide in the shell to the mass of silicon inside the silicon dioxide shell; dusting issues inside of the coated particle melter 1050; and small diameter coated particles floating on the surface of the molten second chemical species 1060 in the coated particle melter 1050 due to low density) and the detrimental effect on the quality of silicon crystals pulled from the melted silicon (e.g., due to oxygen contamination of the pulled silicon crystal) caused by the oxide layer carried by the small sized particles fed to the melter—because the ratio of oxygen in small particles to particle mass is proportionately greater in small particles than in larger particles. Consequently, the separated coated particle size distribution of the first portion of separated coated particles 1034 can include smaller diameter coated particles 1032, thereby reducing or even eliminating the need for coated particle classification (and potential for subsequent oxygen exposure) in the conveyance 1030. Eliminating classification advantageously eliminates a size classification unit operation and the attendant handling of the coated particles upstream and downstream of the classification unit operation that historically has introduced contaminants (e.g., oxygen, atomic metals, metallic particulates, and others) to the separated coated particles 1032. Further, the ability to feed a wide range of coated particle sizes to the coated particle melter 1050 increases the density of the crucible pack because void spaces within the crucible are reduced.

Dusting (suspension of fine coated particles) in the coated particle melter 1050 has been a problem solved by removing the small diameter coated particles from the feed to coated particle melter 1050. Advantageously, the small diameter coated particles 1032 produced in the particulate bed 1004 have a different morphology and density than the coated particles produced using a hydraulically fluidized bed. Coated particles produced in the particulate bed 1004 and/or the mechanically fluidized particulate bed 20 are believed to be more spherical in shape and, consequently, are believed to have a higher density. The density of the separated coated particles 1032 produced in particulate beds 1004 and/or mechanically fluidized beds 20 may be 10 to 100 times greater than the density of coated particles produced in a hydraulically fluidized bed.

Such small diameter separated coated particles 1032 can measure smaller than 400 micrometers, smaller than 300 micrometers, smaller than 200 micrometers, smaller than 100 micrometers, smaller than 500 micrometers, and smaller than 10 micrometers.

For example, the bulk density of smaller diameter coated particles 22 produced in a particulate bed 1004 and/or a mechanically fluidized particulate bed 20 may be 1 gram per cubic centimeter. In contrast, the density of smaller diameter coated particles produced in a hydraulically fluidized bed may be as low as 0.01 to 0.1 grams per cubic centimeter. Aerodynamic sphericity of coated particles 22 produced in a particulate bed 1004 and/or a mechanically fluidized particulate bed 20 approaches 0.98 compared to an aerodynamic sphericity of 0.5 to 0.6 for coated particles produced in a hydraulically fluidized bed. Due to these differences, small diameter coated particles produced in a mechanically fluidized bed tend to cause fewer observable dusting problems in the crystal production operation. In addition, the coated particles 22 generated in the mechanically fluidized particulate bed 20 have differing physical properties and/or morphological properties from coated particles produced using a hydraulically fluidized bed. For example, it is believed that coated particles 22 produced in a mechanically fluidized particulate bed 20 may be less “sticky” (i.e., may demonstrate lower tendency to adhere to each other and to surfaces) than coated particles generated using a hydraulically fluidized bed. Stated differently, coated particles produced in a hydraulically fluidized particulate have a propensity—likely related to a unique surface chemistry and/or morphology—to cling to surfaces and not flow smoothly. In contrast, coated particles 22 produced in a mechanically fluidized bed 20 tend to demonstrate a lower propensity to cling and have a greater tendency to flow smoothly throughout the production, conveyance, and crystal production processes. In another example, it is believed that the physical structure of coated particles 22 produced in a mechanically fluidized bed reactor may have greater density and/or may be more spherical than particles produced in hydraulically fluidized beds. These physical properties make coated particles 22, including smaller diameter coated particles 22, produced in a mechanically fluidized bed reactor more amenable to melting in a crystal production process.

The coated particle melter 1050 can include any system, device, or combination of systems and devices to heat the first portion of coated particles 1034 to a temperature at or above the melting point of the second chemical species and provide a reservoir of molten second chemical species 1060. At times, the coated particle melter maintains a thermal profile along the depth of the reservoir of molten second chemical species. Such coated particle melters 1050 may form a portion of or may, alternatively, be replaced by one or more crystal production devices 1070. Such crystal production devices may include, but are not limited to, any current or future developed crystal production device amenable for the production of monocrystalline second chemical species (e.g., monocrystalline silicon). Examples of such crystal production devices include crystal pullers, float-zone crystal production devices, and Bridgman-Stockbarger crystal production devices.

Using silicon as an illustrative second chemical species—silicon expands on crystallization and contracts upon melting. Silicon coated particles 22 are covered in crystalline silicon. When an oxide layer (e.g., silicon dioxide) forms on the external surfaces of the silicon coated particles 22 or the separated silicon coated particles 1032 it is hypothesized that the oxide layer can act as a microns thick, relatively impermeable, shell surrounding the crystalline silicon coated particle 22 or crystalline silicon coated separated coated particle 1032. When such silicon dioxide separated coated particles 1032 are included in the first portion of separated coated particles 1034 and heated during a silicon crystal production process, it is possible for the crystalline silicon to melt while the silicon dioxide shell (which has a melting temperature hundreds of degrees Celsius higher than the melting point of silicon) remains intact. In such instances, it is theorized that the contraction of the molten silicon within the silicon dioxide shell creates a vacuum within the silicon dioxide layer that exerts a compressive or implosive force on the silicon dioxide layer.

It is hypothesized that the smaller diameter silicon coated particles 1032 are able to better withstand the resultant compressive force better than larger diameter silicon coated particles 1032 and, as a result, tend to float and are difficult to melt, requiring a significantly greater energy input to melt small diameter silicon coated particles when such particles are included in the first portion of the separated silicon coated particles 1034. Consequently, it is believed that by minimizing, reducing, or eliminating the formation of silicon dioxide on the external surfaces of the separated silicon coated particles 1032, the “meltability” of such particles will be improved and the isolation of small diameter silicon coated particles from the first portion of separated silicon coated particles 1034 is significantly reduced or even eliminated. Since smaller diameter silicon coated particles may be included in the first portion of the separated coated particles 1034 used in crystal production, both capital and operating expenses associated with coated particle classifiers or similar separation devices are beneficially reduced or even eliminated. Additionally, by reducing or eliminating the classification of the separated silicon coated particles 1032, the potential for contamination of the separated silicon coated particles 1032 is reduced.

FIG. 10B shows an illustrative conveyance 1030 that includes only a hermetic coupling between the reactor 30 and the coated particle melter 1050, according to an embodiment. Such a configuration may be alternatively referred to as a “close-coupled” configuration. In such a configuration, the separated coated particles 1032 are transferred directly to the coated particle melter 1050 via the, conveyance 1030. In some implementations, the coated particle melter 1050 may have internal ambient or elevated temperature coated particle storage. At times, the environment in the coated particle storage can be maintained at a low oxygen level having an oxygen concentration of less 1.0 than 20 volume percent (vol %). At other times, the environment in the coated particle storage can be maintained at a very low oxygen level having an oxygen concentration of less than about 1 mole % (mol %); less than about 0.5 mol %; less than about 0.3 mol %; less than about 0.1 mol %; less than about 0.01 mol %; or less than about 0.001 mol %.

FIG. 10C shows an illustrative alternative conveyance 1030 that includes a coated particle accumulator 1080, according to an embodiment. Separated coated particles 1032 are directed to the coated particle accumulator 1080. Separated coated particles 1032 are transferred from the coated particle accumulator 1080 to the coated particle melter 1050 on demand, intermittently, periodically, or continuously.

At times, the environment in the coated particle accumulator 1080 can be maintained at a low oxygen level having an oxygen concentration of less than 20 volume percent (vol %). At other times, the environment in the coated particle accumulator 1080 can be maintained at a very low oxygen level having an oxygen concentration of less than about 1 mole % (mol %); less than about 0.5 mol %; less than about 0.3 mol %; less than about 0.1 mol %; less than about 0.01 mol %; or less than about 0.001 mol %.

FIG. 10D shows an illustrative alternative conveyance 1030 that includes a coated particle classifier 1090, according to an embodiment. The coated particle classifier 1090 can include any number of devices, systems, or combinations of systems and devices suitable for separating, classifying, sorting, or otherwise apportioning the separated coated particles 1032. Such classification may be based at least in part on one or more defined physical properties of the separated coated particles 1032, one or more defined compositional properties of the separated coated particles 1032, or any combination thereof. For example, the coated particle classifier 1090 may apportion the separated coated particles 1032 into a defined number of fractions based on the diameter of the separated coated particle 1032.

At times, the environment in the coated particle classifier 1090 can be maintained at a low oxygen level having an oxygen concentration of less than 20 volume percent (vol %). At other times, the environment in the coated particle classifier 1090 can be maintained at a very low oxygen level having an oxygen concentration of less than about 1 mole % (mol %); less than about 0.5 mol %; less than about 0.3 mol %; less than about 0.1 mol %; less than about 0.01 mol %; or less than about 0.001 mol %.

At times, within the coated particle classifier 1090, all or a portion of the separated coated particles 1032 are apportioned into at least a first portion of separated coated particles 1034 for subsequent transfer to the coated particle melter 1050 and a second portion of separated coated particles 1038, at least a portion of which are subsequently recycled to the particulate bed 1004 in the reactor 1012 or to the mechanically fluidized particulate bed 20 in the mechanically fluidized reactor 30.

FIG. 10E shows an illustrative alternative conveyance 1030 that includes a coated particle accumulator 1080 and a coated particle classifier 1090, according to an embodiment. All or a portion of the separated coated particles 1032 are directed to the coated particle accumulator 1080. Coated particles 1032 are transferred from the coated particle accumulator 1080 to the coated particle classifier 1090 on demand, intermittently, periodically, or continuously.

At times, the environment in the coated particle accumulator 1080 and the coated particle classifier 1090 can be maintained at a low oxygen level having an oxygen concentration of less than 20 volume percent (vol %). At other times, the environment in the coated particle accumulator 1080 and the coated particle classifier 1090 can be maintained at a very low oxygen level having an oxygen concentration of less than about 1 mole % (mol %); less than about 0.5 mol %; less than about 0.3 mol %; less than about 0.1 mol %; less than about 0.01 mol %; or less than about 0.001 mol %.

FIG. 10F shows an illustrative alternative conveyance 1030 that includes a coated particle classifier 1090 and a coated particle grinder 1096, according to an embodiment. The coated particle classifier 1090 can apportion the separated coated particles 1032 into a first portion of separated coated particles 1034 that is subsequently transferred to the coated particle melter 1050 and a second portion of separated coated particles 1038. In at least some implementations, at least some of the second portion of separated coated particles 1038 may include coated particles for recycle to the particulate bed 1004 in reactor 1012 or the mechanically fluidized particulate bed 20 in the mechanically fluidized reactor 30.

However, at times, the diameter of at least some of the second portion of separated coated particles 1038 may be too large for recycle to the particulate bed 1004 or the mechanically fluidized particulate bed 20. In such instances, the coated particle classifier 1090 may further classify the second portion of separated coated particles 1038 into either a first fraction 1092 if the coated particle diameter exceeds a defined threshold (i.e., a large diameter fraction) or a second fraction 1094 if the coated particle diameter is less than the defined threshold (i.e., a small diameter fraction). All or a portion of the first fraction 1092 can be transferred to the coated particle grinder 1096 where the diameter of the coated particles is reduced to a size suitable for recycle to the particulate bed 1004 in reactor 1012 or to the mechanically fluidized particulate bed 20 in the mechanically fluidized reactor 30. In such instances, all or a portion of the reduced diameter coated particles discharged by the coated particle grinder 1096 can be combined with all or a portion of the second (small diameter) fraction 1094 for recycle to the particulate bed 1004 in reactor 1012 or to the mechanically fluidized particulate bed 20 in the mechanically fluidized reactor 30.

All or a portion of the separated coated particles 1032 separated from the particulate bed 1004 are directed to the coated particle classifier 1090 and transferred from the coated particle classifier 1090 to the coated particle grinder 1096 and/or the coated particle melter 1096 on demand, intermittently, periodically, or continuously.

At times, the environment in the coated particle classifier 1090 and the coated particle grinder 1096 can be maintained at a low oxygen level having an oxygen concentration of less than 20 volume percent (vol %). At other times, the environment in the coated particle classifier 1090 and the coated particle grinder 1096 can be maintained at a very low oxygen level having an oxygen concentration of less than about 1 mole % (mol %); less than about 0.5 mol %; less than about 0.3 mol %; less than about 0.1 mol %; less than about 0.01 mol %; or less than about 0.001 mol %.

FIG. 10G shows an illustrative alternative conveyance 1030 that includes a coated particle accumulator 1080, a coated particle classifier 1090, and a coated particle grinder 1096 according to an embodiment. All or a portion of the separated coated particles 1032 separated from the particulate bed 1004 are directed to the coated particle accumulator 1080. Separated coated particles 1032 are transferred from the coated particle accumulator 1080 to the coated particle classifier 1090 on demand, intermittently, periodically, or continuously.

At times, the environment in the coated particle accumulator 1080, the coated particle classifier 1090, and the coated particle grinder 1096 can be maintained at a low oxygen level having an oxygen concentration of less than 20 volume percent (vol %). At other times, the environment in the coated particle accumulator 1080, the coated particle classifier 1090, and the coated particle grinder 1096 can be maintained at a very low oxygen level having an oxygen concentration of less than about 1 mole % (mol %); less than about 0.5 mol %; less than about 0.3 mol %; less than about 0.1 mol %; less than about 0.01 mol %; or less than about 0.001 mol %.

Returning now to FIG. 10A, the production and transport of coated particles 22 in low oxygen content environments such as the reactor 1012 and the conveyance 1030 significantly reduces the likelihood of oxide formation and/or contaminant deposition, adhesion, and/or adsorption on the surfaces of the coated particles 22 removed from the particulate bed 1004 and/or the separated coated particles 1032 in the conveyance 1030, particularly smaller diameter coated particles. Traditionally these smaller diameter coated particles were removed from the separated coated particles 1032 and excluded from the melter 1050 to minimize the issues associated with the (relatively) greater quantity of oxides (and their inherent melt problems discussed above) that they introduced to the coated particle melter 1050. Since the formation of an oxide layer on the separated coated particles 1032 is minimized or even eliminated, isolation of small diameter coated particles is not necessarily required and small diameter separated coated particles 1032 can, contingent upon solving dusting problems and melting problems due to low particle density, be charged to the coated particle melter 1050 without having an adverse effect on final crystal quality and/or composition.

For example, in some crystal production methods, separated coated particles 1032 having diameters of about 400 μm to about 4000 μm may be deemed “desirable” while coated particles 1038 having a diameter of about 400 μm or less are deemed “dust” and undesirable within the melter. The smaller diameter separated coated particles 1032 are problematic for several reasons, including the increase in thermal energy input required to melt smaller diameter separated coated particles 1032 that float within the coated particle melter. It is theorized that smaller diameter particles including an oxide layer require additional thermal energy input due to the presence of the oxide layer.

In another example, small diameter coated particles produced in a hydraulically fluidized bed reactor may have a greater tendency to detrimentally suspend within the environment in the melter 1050 than smaller diameter separated coated particles 1032 produced in a mechanically fluidized bed reactor. The tendency for smaller diameter coated particles produced in a hydraulically fluidized bed reactor to suspend within the melter 1050 may be attributable, at least in part, to the relatively low bulk density of smaller diameter coated particles produced in a hydraulically fluidized bed reactor.

The systems and methods described herein advantageously produce the coated particles 22 and maintain the separated coated particles 1032 in environments having low oxygen levels or very low oxygen levels. Further, the ability to charge smaller diameter separated coated particles 1032 produced in the mechanically fluidized bed reactors described herein directly to the melter 1050 minimizes, reduces, or even eliminates classification and removal of smaller diameter coated particles from the melter charge. Since classification of coated particles (e.g., coated particles produced in a hydraulically fluidized bed) introduces contaminants such as metal atoms and ions to the coated particles, the ability to charge smaller diameter separated coated particles (e.g., coated particles produced in a mechanically fluidized particulate bed) without classification reduces the contaminants carried by the coated particles into the melter making possible the production of second chemical species crystals having low contaminant levels or very low contaminant levels.

Such coated particles 22 and separated coated particles 1032, having minimal or no oxide layer and minimal or no contaminants due to surface contact or exposure in the conveyance 1030, permit the rapid melting of smaller particles in the coated particle melter 1050, thereby enabling the use of even small diameter particles in the crystal production process without the attendant melting and contamination issues associated with more traditional coated particles having an oxide layer and surface contact or exposure in the conveyance 1030. It is possible that, at times, the improved “meltability” or improved melt characteristics of such smaller diameter coated particles 22 and separated coated particles 1032 produced in a mechanically fluidized particulate bed reactor is at least partially attributable to the higher density of the coated particles 22 and separated coated particles 1032, including the small diameter coated particles 22 and small diameter separated coated particles 1032, and the consequent reduced propensity to form dust in the coated particle melter 1050. It is possible that, at times, the “meltability” of such smaller diameter coated particles 22 and separated coated particles 1032 produced in a mechanically fluidized particulate bed reactor 30 is attributable at least in part to the morphology of the coated particles 22 produced in the mechanically fluidized particulate bed.

Additionally, the crystal production system 1000 preferentially generates larger diameter separated coated particles 1032 which have a much lower surface area/mass ratio than comparatively smaller diameter separated coated particles 1032. Consequently, even if an oxide layer forms on the separated coated particles 1032, the effects of such an oxide layer in the coated particle melter 1050 are advantageously mitigated by the significantly greater mass of second chemical species carried by each separated coated particle 1032 included in the first portion of separated coated particles 1034.

One or more exhaust gas systems 1010 removes as an exhaust gas at least a portion of any accumulated gases from the chamber 1003 of the reactor 1012. Such accumulated gases can include, but are not limited to, unconverted first gaseous chemical species, one or more diluents, and/or one or more third gaseous chemical species byproducts resulting from the conversion of the first gaseous chemical species to the second chemical species. The one or more exhaust gas systems 1010 may include one or more gas separators (e.g., selectively permeable membranes, filters, and the like) that selectively separate all or a portion of the unconverted first gaseous chemical species, one or more diluent(s), and/or one or more gaseous byproducts from the exhaust gas. All or a portion of the separated gaseous byproducts may be recycled, for example as one or more diluents added to the first gaseous chemical species.

In addition, the exhaust gas removed from the chamber 1003 may include particulate matter, for example particulates from the particulate bed 1004. The exhaust gas system 1010 may include one or more solids separators (e.g., cyclonic separators, baghouses, and the like) to remove such particulates and/or particles entrained in the exhaust gas. At times, all or a portion of the removed particles or particulates may be recycled to the particulate bed 1004.

The conveyance 1030 can include one or more devices, systems, or combinations of systems and devices suitable for at least transferring at least a portion of the separated coated particles 1032 to the coated particle melter 1050 while maintaining the separated coated particles 1032 in an environment having a low oxygen level or very low oxygen level and, attributable at least in part to the elimination of a classification system, process, or device, a low contaminant level or very low contaminant level. At times, the conveyance 1030 may include additional devices, systems, or combinations of systems and devices for accumulation and/or storage of separated coated particles 1032, classification of separated coated particles 1032, and/or physical size reduction of separated coated particles 1032. The conveyance may be a lined vessel, container, carboy, sack, bag, jug, or similar capable of maintaining the separated coated particles 1032 in the environment having a low oxygen level or very low oxygen level and a low contaminant level or very low contaminant level. At times, the conveyance 1030 may be lined. Such liners may include, but are not limited to: silicon, quartz, graphite, silicon nitride, silicon carbide, molybdenum disilicide, polyethylene, or similar.

The conveyance 1030 can include a housing 1040 having an interior space 1042 defining an environment in which the separated coated particles 1032 at least temporarily reside. At times, the environment in the interior space 1042 is maintained at a low oxygen level having an oxygen concentration of less than 20 volume percent (vol %) oxygen. At other times, the environment in the interior space 1042 is maintained at a very low oxygen level environment having an oxygen concentration of less than about 1 mole % (mol %); less than about 0.5 mol %; less than about 0.3 mol %; less than about 0.1 mol %; less than about 0.01 mol %; or less than about 0.001 mol %.

At times, the conveyance 1030 is simultaneously hermetically sealed to the reactor 1002 and to the coated particle melter 1050. FIGS. 1, 2, 3A, 6, 7A, 8A, and 8B depict such an installation where the coated particle collection system 130 provides at least a portion of the conveyance 1030 and is shown hermetically sealed to the reactor via the coated particle removal tube 132.

Alternatively, the conveyance 1030 can include a moveable or transportable housing 1040 that are hermetically sealable to the reactor 1002 to receive coated particles 22 from the particulate bed 1004. The transportable housing 1040 is moved proximate and hermetically sealed to the coated particle melter 1050 to discharge the first portion of the coated particles 1034 to the coated particle melter 1050.

The coated particle melter 1050 heats the first portion of separated coated particles 1034 received from the conveyance 1030 to a temperature equal to or in excess of the melting temperature of the second chemical species. The coated particle melter 1050 includes a housing 1052 defining an interior space 1054. At times, the melter can include one or more thermal energy emitting devices that are used to heat the first portion of the separated coated particles 1034 to a temperature equal to or in excess of the melting temperature of the second chemical species deposited on the coated particles. At other times, the coated particle melter 1050 can include one or more inductive, radio frequency, microwave, or other electromagnetic energy emitting or producing devices suitable for increasing the temperature of the first portion of the separated coated particles 1034 to a temperature equal to or in excess of the melting temperature of the second chemical species.

In some instances, for example a Czochralski crystal production process, a lined quartz crucible can receive the first portion of coated particles 1034. In such instances, the quartz crucible can include one or more linings or similar coatings (e.g., a barium doped quartz or silicon nitride coating) that advantageously mitigates the dissolution of silicon dioxide from the crucible to the molten second chemical species 1060.

At times, within the coated particle melter 1050, dissolved silicon dioxide (e.g., silicon dioxide dissolved from a quartz crucible or carried into the melt with the separated coated particles 1032) is converted to silicon monoxide, which at typical melt temperatures is in a gaseous state. The silicon oxide tends to migrate toward the surface of the molten second chemical species 1060, and is substantially swept and removed from the melt pool by an inert gas sweep. Oxygen that is not removed from the molten second chemical species 1060 can incorporate into the second chemical species crystal boule 1072 as it is pulled from the molten second chemical species 1060. Oxygen introduced as a layer of silicon dioxide present on at least some of the first portion of the separated coated particles 1034 can significantly add to the oxygen from the crucible, and significantly increase potential for oxygen contamination in the second chemical species silicon boule 1072 with concomitant adverse effect on the quality of the second chemical species crystal 1072. This oxygen contamination may render all or a portion of the second chemical species crystal 1072 unsuitable for use in semiconductor or solar cell fabrication.

Surface contaminants on some or all of the first portion of the separated coated particles 1034, including metal atoms and/or ions, do not volatilize out of the molten second chemical species but instead concentrate in the molten second chemical species present in the crucible. Traditionally, the molten second chemical species 1060 was dumped when contaminants, including surface contaminants carried in by the first portion of the separated coated particles 1034, reached a defined threshold value at which crystal growth and/or quality was adversely impacted.

Minimizing or eliminating the oxide layer and/or surface contaminants on the first portion of the separated coated particles 1034 therefore advantageously permits the extended, even continuous, use of the reservoir of molten second chemical species 1060.

All or a portion of the exterior surfaces of the coated particle melter 1050 can include an insulative layer 1056. One or more thermal or electromagnetic energy emitting devices 1058 can provide all or a portion of the energy used to increase the temperature and melt all or a portion of the first portion of the coated particles 1034. In some instances, the melted coated particles form a pool or reservoir of molten second chemical species 1060 in at least a portion of the coated particle melter.

At times, the environment in the interior space 1054 of the coated particle melter 1050 is maintained at a low oxygen level in which the oxygen concentration is less than 20 volume percent (vol %). At other times, the environment in the interior space 1054 of the coated particle melter 1050 is maintained at a very low oxygen level in which the oxygen concentration is less than about 1 mole % (mol %); less than about 0.5 mol %; less than about 0.3 mol %; less than about 0.1 mol %; less than about 0.01 mol %; or less than about 0.001 mol %.

In some instances, the crystal production device 1070 can be physically coupled and hermetically sealed to the coated particle melter 1050. For example, the crystal production device 1070 can, at times, include a crystal puller or similar device that uses the Czochralski method to form a second chemical species. The Czochralski method uses a second chemical species seed crystal that is inserted into the molten second chemical species 1060 and withdrawn at a controlled rate and, optionally, rotation such that a second chemical species ingot or boule forms (i.e., “grows”) on the seed crystal.

Using silicon as an illustrative example, controlling oxide levels and contamination levels in the reservoir of molten silicon 1060 by limiting the formation of an oxide layer and/or the deposition of contaminants on the surfaces of the first portion of the separated silicon coated particles 1034 provides high quality crystal silicon boules with minimal contamination. When an oxide layer is present on the surface of the first portion of the separated coated particles 1034 the level of oxygen contamination the product monocrystalline silicon boules 1072 can remain unacceptably high for an extended period of time (e.g., in excess of an hour) after start-up of the crystal production device 1070. The presence of contaminants, including but not limited to oxygen atoms, molecules containing oxygen, metal atoms, molecules containing metal atoms, carbon atoms and molecules containing carbon atoms, in a silicon boule compromise the quality of the boule and may render the silicon boule unsatisfactory for use in semiconductor or solar cell fabrication. The systems and methods described herein advantageously minimize or even eliminate the presence of such contaminants in the silicon coated particles used in producing the silicon boules or monocrystalline silicon. Such highly pure coated particles, including coated particles of smaller diameter that traditionally would be excluded from the monocrystalline silicon production process, may be beneficially used in the production of monocrystalline silicon using any current or future developed crystal growing or production process.

For example, it is estimated that the level of oxide contamination attributable to the oxide layer on the first portion of the separated coated particles 1034 introduced to the melter 1050 can be five times the level of oxide contamination attributable to other sources such as dissolution from the quartz crucible in which the first portion of the separated coated particles 1034 are melted. This problem is even more pronounced in continuous process schemes where granules are batch-wise or continuously recharged to the coated particle melter 1050. At other times, the crystal production device 1070 can use the Bridgman-Stockbarger crystal growing method in which a second chemical species seed crystal is introduced to a reservoir containing the molten second chemical species and the reservoir is cooled at a defined rate to crystallize the second chemical species. Such a crystal grower may be particularly advantageous for growing doped second chemical species crystals, for example gallium arsenide doped silicon crystals.

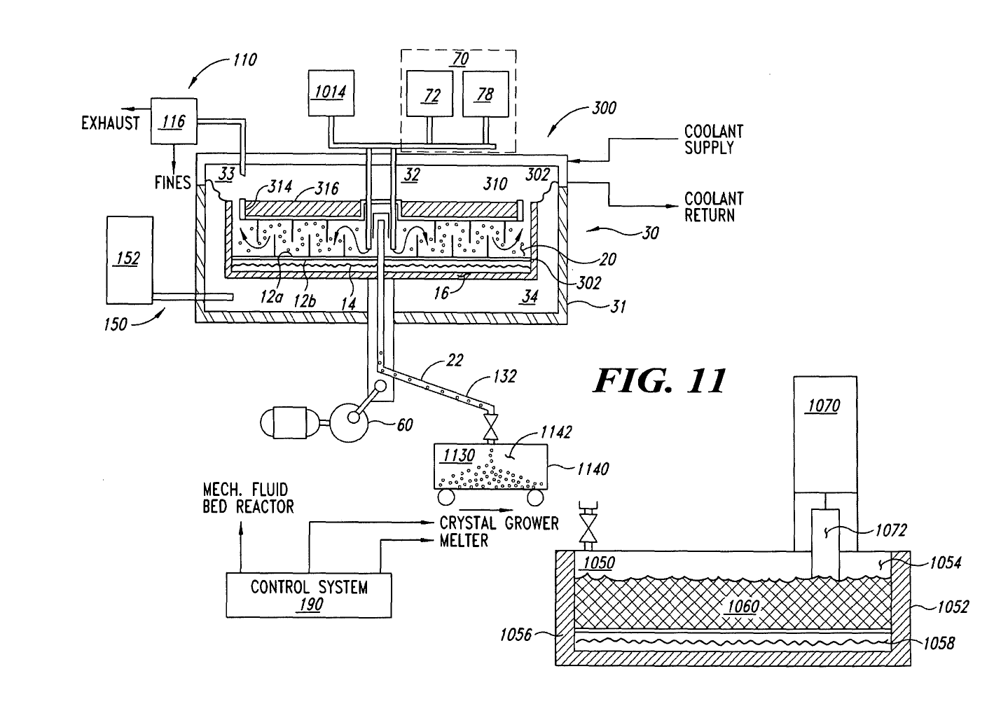

FIG. 11 shows an illustrative crystal production system 1100 that includes a mechanically fluidized bed reactor 300 (described in detail in FIGS. 3A-3E) fluidly coupleable to a portable conveyance 1130, according to an illustrated embodiment. The portable conveyance 1130 is fluidly coupleable to the coated particle melter 1050 and therefore enables the production and transfer of coated particles 1032 while maintaining the coated particles 1032 in an environment having a low oxygen level or a very low oxygen level. Although the a mechanically fluidized bed reactor 300 is illustrated with crystal production system 1100, any of the mechanically fluidized bed reactors described in detail in FIGS. 1-8 may be substituted.

The control system 190 may be communicably and operably coupled to the mechanically fluidized bed reactor 300, the coated particle melter 1050, and the crystal production device 1070. The control system 1110 coordinates the operation of the mechanically fluidized bed reactor 300, the coated particle melter 1050, and the crystal production device 1070. For example, as the level in the reservoir of molten second chemical species 1060 decreases during crystal production, the control system 1110 may cause the transfer of additional coated particles 1034 from the conveyance 1130 to the coated particle melter 1050 to maintain a defined minimum level in the reservoir of molten second chemical species 1060.

The control system 190 may alter, adjust, or control one or more process conditions in the mechanically fluidized bed reactor 300 to alter, adjust, or control the conversion of the first gaseous chemical species to the second chemical species in the heated particulate bed. For example, the control system 1110 may alter, adjust, or control one or more of: the temperature of the particulate bed 20, the temperature in the upper chamber 33 external to the particulate bed 20, the temperature in the lower chamber 34, a gas pressure (first gaseous chemical species, one or more optional diluent(s), dopants, or combinations thereof) in the particulate bed 20, a flow rate of the first gaseous chemical species to the particulate bed 20, the temperature of the gas feed comprising first reactive species to the particulate bed 20, a ratio of the first gaseous chemical species to the one or more optional diluent(s) in the particulate bed 20.

The control system 190 may alter, adjust, or control the oscillatory frequency and/or the oscillatory displacement of the pan 12. Controlling the oscillatory frequency and/or displacement of the pan 12 enables the selective separation of coated particles 22 from the mechanically fluidized particulate bed 20 via the coated particle overflow conduit 132. For example, the control system 190 can alter, control, or adjust an oscillatory displacement and/or an oscillatory frequency along one or more of three orthogonal axes that define a three dimensional space. By varying the oscillatory displacement and/or frequency along two orthogonal axes, circular or elliptical oscillations are possible. By varying the oscillatory displacement and/or frequency along three orthogonal axes, helical, spiral, and similar are possible. At times, at least one of: a horizontal oscillatory displacement component or a vertical oscillatory displacement component to selectively separate coated particles 22 meeting one or more desired physical or compositional thresholds from the mechanically fluidized particulate bed 20. Such advantageously enables the selective retention of particulates and coated particles in the mechanically fluidized particulate bed 20 having a diameter of less than about 600 micrometers (μm); less than about 500 μm; less than about 400 μm; less than about 300 μm; less than about 200 μm; less than about 100 μm; less than about 50 μm; less than about 20 μm; less than about 10 μm; less than about 5 μm; or less than about 1 μm.

The control system 190 can alter, adjust or control the oscillatory frequency of the pan 12 to any frequency within a defined frequency range. For example, the control system 190 can alter, adjust or control the oscillatory frequency of the pan 12 to a defined frequency range that includes frequencies from about 1 cycle per minute; about 5 cycles per minute; about 50 cycles per minute; about 100 cycles per minute; about 500 cycles per minute; about 1000 cycles per minute; or about 2000 cycles per minute to about 50 cycles per minute; about 100 cycles per minute; about 500 cycles per minute; about 1000 cycles per minute; about 2000 cycles per minute; about 3000 cycles per minute; about 4000 cycles per minute; or about 5000 cycles per minute.

The control system 190 can alter, adjust, or control the oscillatory displacement of the pan 12 to have a horizontal component within a defined range. For example, the control system 190 can alter, adjust or control the horizontal oscillatory displacement of the pan 12 to a defined displace range that includes a horizontal displacement from about 0.01 inches; about 0.03 inches; about 0.05 inches; about 0.1 inches; about 0.2 inches; about 0.3 inches; or about 0.5 inches to about 0.01 inches; about 0.05 inches; about 0.1 inches; about 0.3 inches; about 0.5 inches; about 0.9 inches; about 2 inches; or about 5 inches.

The control system 190 can alter, adjust, or control the oscillatory displacement of the pan 12 to have a vertical component within a defined range. For example, the control system 190 can alter, adjust or control the vertical oscillatory displacement of the pan 12 to a defined displace range that includes a vertical displacement from about 0.01 inches; about 0.03 inches; about 0.05 inches; about 0.1 inches; about 0.2 inches; about 0.3 inches; or about 0.5 inches to about 0.01 inches; about 0.05 inches; about 0.1 inches; about 0.3 inches; about 0.5 inches; or about 0.9 inches.

The control system 190 can additionally alter or adjust the flow of a purge gas to the coated particle overflow conduit 132 to alter, adjust, or control the diameter of the coated particles 22 separated from the mechanically fluidized particulate bed 20. For example, the control system 190 may increase the flow of purge gas through the coated particle overflow conduit 132 into the mechanically fluidized particulate bed 20 to selectively increase the diameter of the coated particles 22 separated from the mechanically fluidized particulate bed 20. Conversely, the control system 190 may decrease the flow of purge gas through the coated particle overflow conduit 132 into the mechanically fluidized particulate bed 20 to selectively decrease the diameter of the coated particles 22 separated from the mechanically fluidized particulate bed 20.

The crystal production system 1100 maintains an environment having a low oxygen level or a very low oxygen level and/or a low contaminant level or very low contaminant level in at least the upper chamber 33 of the mechanically fluidized bed reactor 30, the conveyance 1130, and the coated particle melter 1050. In addition, one or more coatings, liners, or layers may be applied to all or a portion of the mechanically fluidized bed reactor 30, the conveyance 1130, and the coated particle melter 1150/crystal production device 1170 to further minimize the migration of oxygen and other contaminants (e.g., metals) from the process equipment to the separated coated particles 1032 and/or the product crystalline second chemical species. The upper chamber 33 of the mechanically fluidized bed reactor 30, the conveyance 1130, and the coated particle melter 1050 are maintained at low oxygen level relative to the ambient environment. Coated particles 1032 in the upper chamber 33 of the mechanically fluidized bed reactor 30, the conveyance 1130, and the coated particle melter 1050 are maintained in an environment having a low oxygen level or a very low oxygen level. At times, the environment in the upper chamber 33 of the mechanically fluidized bed reactor 30, the conveyance 1130, and the coated particle melter 1050 is maintained at a low oxygen level having an oxygen concentration of less than 20 volume percent (vol %). At other times, the environment in the upper chamber 33 of the mechanically fluidized bed reactor 30, the conveyance 1130, and the coated particle melter 1050 is maintained at a very low oxygen level having an oxygen concentration of less than about 1 mole % (mol %); less than about 0.5 mol %; less than about 0.3 mol %; less than about 0.1 mol %; less than about 0.01 mol % oxygen; or less than about 0.001 mol %. Advantageously, by limiting the exposure of the coated particles 22 and the separated coated particles 1032 to oxygen, oxide formation on the external surfaces of the coated particles 22 and the separated coated particles 1032 is beneficially minimized, reduced, or even eliminated.

Minimizing, limiting, or eliminating oxide formation on the external surfaces of the coated particles 22 and the separated coated particles 1032 is believed to beneficially improve the “meltability” of the coated particles by reducing the tendency of small separated coated particles 1032 to melt at elevated temperatures compared to pure silicon, and improves the quality of the molten second chemical species 1060 by reducing oxide contaminants.

Minimizing, limiting, or eliminating oxide formation on the external surfaces of the coated particles 22 and the separated coated particles 1032 beneficially eliminates the need to classify separated coated particles 1032 to limit the introduction of smaller diameter separated coated particles to the coated particle melter 1050 since the smaller particles will not have significant oxide buildup on their surfaces. Furthermore, the ability to selectively separate coated particles from the mechanically fluidized particulate bed 20 such that smaller diameter separated coated particles are retained in the mechanically fluidized particulate bed 20 provides a synergistic effect that further reduces or even eliminates the need to separate smaller diameter coated particles from the first portion of separated coated particles 1034 introduced to the coated particle melter 1050. By eliminating the need to classify separated coated particles, exposure to free oxygen during the classification process is eliminated, beneficially improving the quality of the resultant second chemical species crystals provided by the crystal puller 1070.

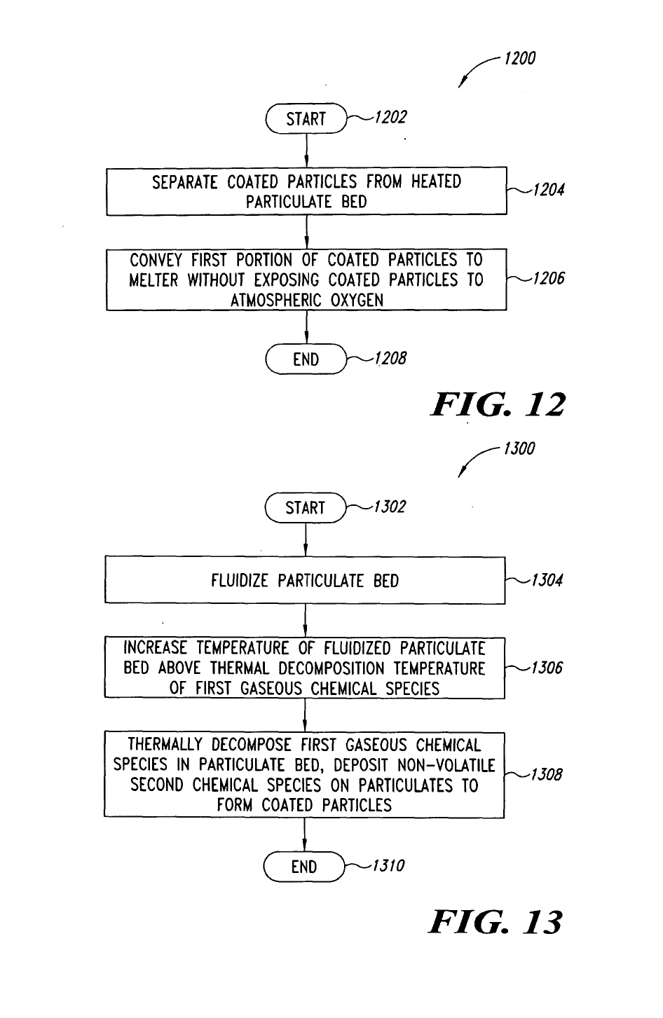

FIG. 12 shows a high-level block flow diagram of an illustrative crystal production method 1200, according to an embodiment. A particulate bed can include coated particles that include a non-volatile second chemical species formed by the thermal and/or chemical decomposition of a first gaseous chemical species in the particulate bed. The non-volatile second chemical species can include any number of elements or compounds, including but not limited to, germanium and germanium silicon mixtures in the form of SiₓGe_{y}, silicon, polysilicon, silicon nitride, silicon carbide, or aluminum oxide (e.g., sapphire glass). At times, an oxide layer or oxide shell can form on some or all of the exposed surfaces of the coated particles upon exposure to a gas that includes free oxygen. For example, a silicon dioxide layer can form on some or all exposed surfaces of polysilicon coated particles simply upon exposure to air. The presence of such oxide layers interferes with subsequent processing of the coated particles, such as melting silicon coated particles during the production of silicon boules. The crystal production method 1200 commences at 1202.

At 1204, coated particles 22 are separated from a heated particulate bed. In some instances, the coated particles 22 may be separated from a heated particulate bed 1004 in a chamber 1003 of a reactor 1012 such as that described in FIG. 10. In such instances, the coated particles 22 may be separated from the particulate bed 1004 using any current or future developed separations technology. Such separations may be based in whole or in part on one or more physical properties of the coated particles 22, such as diameter, density, and the like. Such separations may be based in whole or in part on one or more compositional properties of the coated particles 22.

In other instances, the coated particles 22 may be separated from a fluidized particulate bed 20 in a fluidized bed reactor 30. In such implementations, the fluidized bed reactor 30 can include a mechanically fluidized bed 20 disposed in the chamber 32, such as any of the mechanically fluidized bed reactors described in FIGS. 1-8. In the mechanically fluidized bed reactor 30, the coated particles 22 can be separated by adjusting one or more parameters of the fluidized particulate bed 20. For example, the oscillatory frequency and/or the oscillatory displacement of a pan supporting the mechanically fluidized particulate bed 20 can be altered or adjusted to cause the separation of coated particles 22 having one or more desirable physical or compositional characteristics.

At 1206, a first portion of the separated coated particles 1032 removed from the heated particulate bed are conveyed to a coated particle melter 1050. In some implementations, the transfer of the separated coated particles 1032 is performed via a conveyance 1030 that maintains the separated coated particles 1032 in an environment having either a low oxygen level or a very low oxygen level. At times, the environment in the conveyance 1030 is at a low oxygen level having an oxygen concentration of less than 20 volume percent (vol %). At other times, the environment in the conveyance 1030 is maintained at a very low oxygen level having an oxygen concentration of less than about 1 mole % (mol %); less than about 0.5 mol %; less than about 0.3 mol %; less than about 0.1 mol %; less than about 0.01 mol %; or less than about 0.001 mol %.

Reducing the exposure of the separated coated particles 1032 to oxygen during the transport between the reactor and the coated particle melter 1050 beneficially reduces the formation of an oxide layer on the exposed surfaces of the separated coated particles 1032. Reducing or preventing the formation of an oxide layer on the separated coated particles 1032 provides numerous advantages that include: melting smaller diameter separated coated particles 1032 without the potential for a detrimental melting point temperature increase in the coated particle melter 1050; and reducing, or possibly eliminating, the need for classification of some or all of the separated coated particles 1032 prior to melting. The reduction or elimination of oxide formation and contamination of the separated coated particles 1032 improves the quality and/or consistency of crystals produced using the separated coated particles 1032 due to decreased oxide contaminants and reduced metal contaminants associated with classification systems, equipment, processes and/or methods. The crystal production method 1200 concludes at 1208.

FIG. 13 shows an illustrated crystal production method 1300 in which a first gaseous chemical species is thermally decomposed in a fluidized particulate bed 20 that has been heated to a temperature in excess of a thermal decomposition temperature of the first gaseous chemical species, according to an embodiment. The thermal decomposition temperature of the first gaseous chemical species is the temperature at which the first gaseous chemical species chemically decomposes to provide at least the second chemical species. At times, the thermal decomposition of the first gaseous chemical species also produces one or more third gaseous chemical species reaction byproducts. The thermal decomposition of the first gaseous chemical species can be an endothermic process using thermal energy (i.e., heat) to break chemical bonds and thermally decompose the first gaseous chemical species into a number of constituent components. The crystal production method 1300 commences at 1302.

At 1304, the particulate bed is fluidized to provide a fluidized particulate bed. At times, fluidization of the particulate bed can occur hydraulically via the passage of one or more fluids (i.e., one or more liquids or gases) through the particulate bed at a flow rate (or superficial velocity) sufficient to fluidize the particulates present in the particulate bed. At other times, fluidization of the particulate bed can occur mechanically by oscillating a pan 12 or other major horizontal surface 302 that carries the particulate bed at an oscillatory frequency and oscillatory displacement sufficient to impart fluid like properties to the particulate bed to provide a mechanically fluidized particulate bed 20. When fluidized, the particulates in the fluidized particulate bed demonstrate water like fluid properties such as flowability and circulation.

At 1306, one or more thermal energy emitting devices 14 increase the temperature of the fluidized particulate bed 20 above the thermal decomposition temperature of the first gaseous chemical species. At times, the thermal energy emitting devices 14 may be positioned proximate a pan 12 or a major horizontal surface 302 carrying the fluidized particulate bed 20, in which case the one or more thermal energy emitting devices 14 indirectly heat the particulate bed by heating the pan or major horizontal surface. Such an arrangement is particularly advantageous since the only reactor components above the thermal decomposition temperature are proximate the fluidized particulate bed—where the thermal decomposition of the first gaseous chemical species is highly preferred. At times, the thermal energy emitting devices 14 may be positioned a distance from the fluidized particulate bed 20, for example a convection or radiant heater.

At 1308, coated particles 22 are formed by thermally decomposing the first gaseous chemical species in the heated fluidized particulate bed 20. At times, the first gaseous chemical species is introduced directly to the heated fluidized particulate bed using a distribution header 350 and one or more injectors 356 positioned in the heated fluidized particulate bed 20. In some instances, the one or more injectors 356 can be insulated for example using a vacuum, insulative material, cooling fluid, or combinations thereof described in detail in FIGS. 3A-3E.

The first gaseous chemical species decomposes within the heated fluidized particulate bed and deposits the nonvolatile second chemical species on the surfaces of the particulates, forming the plurality of coated particles 22 in the heated fluidized particulate bed. The coated particles 22 can then be selectively separated from, the heated fluidized particulate bed and transferred to the conveyance 1030. The crystal production method 1300 concludes at 1310.

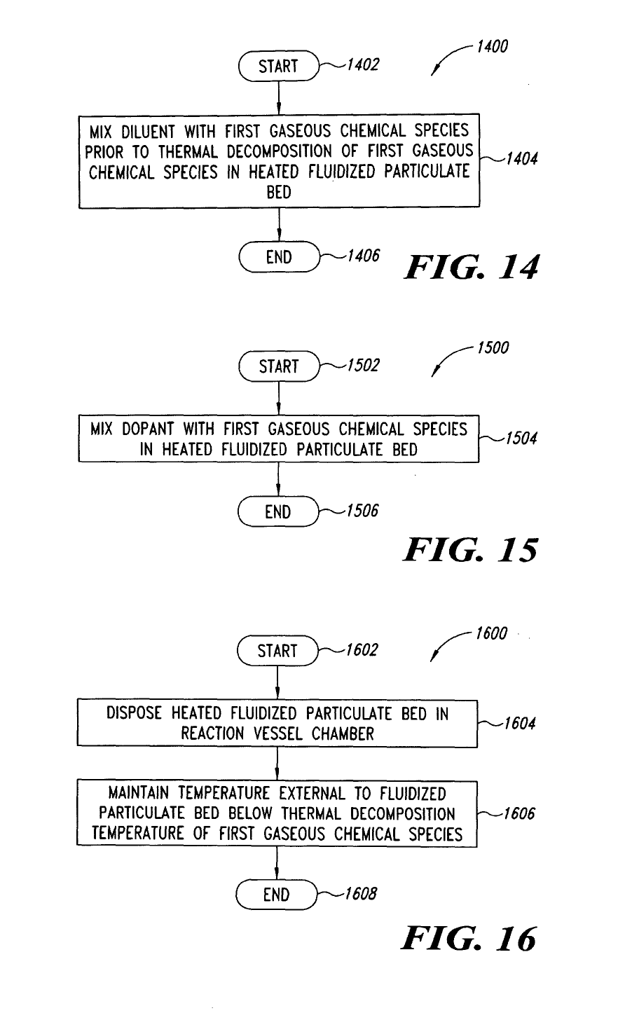

FIG. 14 shows a high level block flow diagram of an illustrative crystal production method 1400 in which one or more optional diluents are provided to the heated fluidized particulate bed contemporaneous with the introduction of the first gaseous chemical species to the heated fluidized particulate bed, according to an embodiment. At times, it is advantageous to provide minimum gas flow to the heated fluidized particulate bed, however feeding solely first gaseous chemical species may adversely impact the conversion to the second chemical species in the heated fluidized particulate bed. In such instances, one or more optional diluents may be used to provide the desired gas flow through the heated fluidized particulate bed while maintaining the conversion of the first gaseous chemical species to the second chemical species at desired levels. The crystal production method 1400 commences at 1402.

At 1404, one or more diluents are mixed with the first gaseous chemical species prior to thermally decomposing the first gaseous chemical species in the heated fluidized particulate bed. At times, the one or more diluents may be premixed with the first gaseous chemical species external to the heated fluidized particulate bed and introduced to the heated fluidized particulate bed via the number of injectors 356 as a mixture containing defined proportions of the one or more diluents and the first gaseous chemical species. At other times, the one or more diluents may be introduced to the heated fluidized particulate bed separate from the first gaseous chemical species. At such times, the circulation of the heated fluidized particulate bed can assist in mixing the one or more diluents and the first gaseous chemical species in the heated fluidized particulate bed.

The one or more diluents can include any chemically inert material that either does not impact the composition or physical characteristics of the second chemical species on the particles in the heated fluidized particulate bed or has an overall positive or desirable effect on the composition or physical characteristics of the second chemical species deposited on the particles in the heated fluidized particulate bed. At times, the one or more diluents may be chemically identical to one or more third gaseous chemical species byproducts. For example, hydrogen may be used as a diluent with a first gaseous chemical species gas such as silane. Silane generates hydrogen as a byproduct upon thermal decomposition in the heated fluidized particulate bed. Other inert gases suitable for use as a diluent include, but are not limited to nitrogen, helium, and argon. The crystal production method 1400 concludes at 1406.

FIG. 15 shows a high level block flow diagram of an illustrative crystal production method 1500 in which one or more optional dopants are provided to the heated fluidized particulate bed, according to an embodiment. At times, the one or more optional dopants may be added to the heated fluidized particulate bed contemporaneous with the introduction of the first gaseous chemical species to produce doped coated particles 22. At other times, the one or more optional dopants may be added to the heated fluidized particulate bed at times when the first gaseous chemical species is not added to produce doped coated particles 22. Dopants, particularly dopants used in the production of silicon crystals, produce desirable molecular flaws in the crystalline structure. Dopants include, but are not limited to boron, arsenic, phosphorus, and gallium. The crystal production method 1500 to produce doped coated particles commences at 1502.

At 1504, one or more dopants are mixed with the first gaseous chemical species in the heated fluidized particulate bed. At times, the one or more dopants may be premixed with the first gaseous chemical species external to the heated fluidized particulate bed and introduced to the heated fluidized particulate bed via a distribution header 350 and a number of injectors 356 as a mixture containing defined proportions of the one or more dopants and the first gaseous chemical species. At other times, the one or more dopants may be introduced to the heated fluidized particulate bed separate from the first gaseous chemical species. At such times, the one or more dopants and the first gaseous chemical species mix in the heated fluidized particulate bed. The crystal production method to produce doped coated particles 22 concludes at 1506.

FIG. 16 shows a high level block flow diagram of an illustrative crystal production method 1600 in which a heated fluidized particulate bed is disposed in a chamber of a reactor vessel and the temperature in the chamber external to the heated fluidized particulate bed and the temperature of the first chemical species while external to the heated fluidized particulate bed are maintained at a temperature or temperatures that are lower than the thermal decomposition temperature of the first gaseous chemical species, according to an embodiment. The production of coated particles 22 in the heated fluidized particulate bed takes advantage of the generation of the non-volatile second chemical species upon exposure of the first gaseous chemical species to a temperature greater than its thermal decomposition temperature. If other surfaces in the chamber housing the heated fluidized particulate bed are greater than the thermal decomposition temperature of the first gaseous chemical species, it is likely that second chemical species deposits will occur on those surfaces. Such deposits external to the heated fluidized particulate bed detrimentally impact yield and may compromise operating efficiency. The crystal production method 1600 commences at 1602.

At 1604, the heated fluidized particulate bed is disposed in a chamber 32 inside a reactor vessel 31. In some instances, the chamber 32 can be apportioned into multiple chambers, for example an upper chamber 33 and a lower chamber 34 created by apportioning the chamber 32 using a flexible member 42. In other instances, the chamber 32 may include a unitary (i.e., undivided) chamber inside the reactor vessel 31. At times, the pan 12 or major horizontal surface 302 supporting the heated fluidized particulate bed inside the chamber 32 is operably coupled to a transmission 50 that is used to oscillate the pan 12 or major horizontal surface 302 at one or more defined oscillatory frequencies or oscillatory displacements.

At 1606, the chamber 32 external to the heated fluidized particulate bed is maintained at a temperature less than the thermal decomposition temperature of the first gaseous chemical species. At times, the temperature of the chamber 32 may be maintained below the thermal decomposition temperature of the first gaseous chemical species via one or more active thermal energy transfer devices (e.g., cooling coils, cooling jackets, and the like), one or more passive thermal energy transfer devices (e.g., extended surface cooling fins and the like), or combinations thereof. At times, the control system 190 may alter or adjust the temperature of the chamber 32 external to the heated fluidized particulate bed using one or more active thermal energy transfer devices. The crystal production method 1600 concludes at 1608.

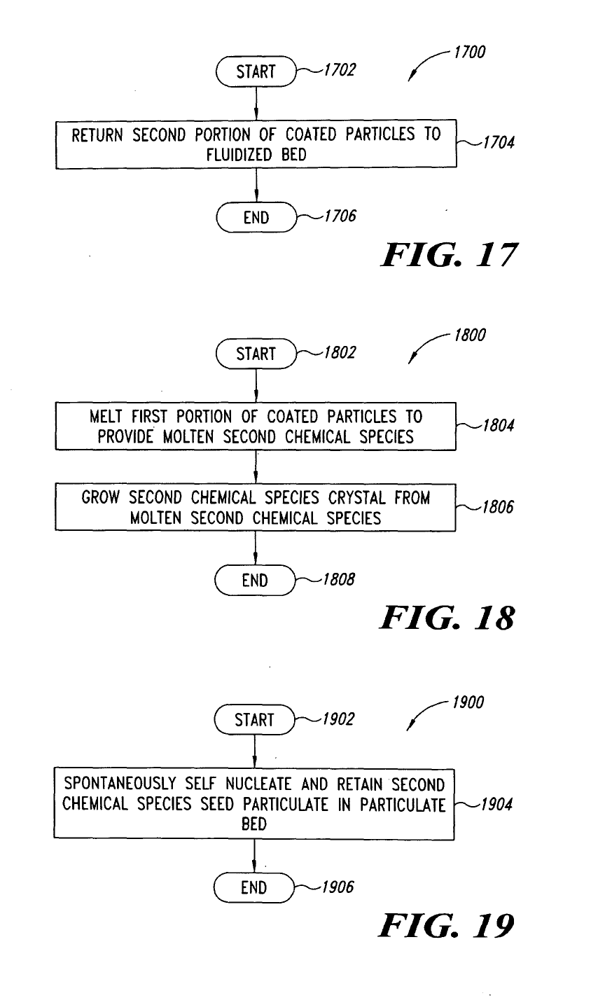

FIG. 17 shows a high level block flow diagram of an illustrative crystal production method 1700 in which a second portion of the separated coated particles 1038 are recycled, as seed particulate, to the heated particulate bed 1004, according to an embodiment. The physical and/or compositional properties of the separated coated particles 1032 can form a distribution (e.g., a Gaussian distribution) about a mean or median value. For example, the separated coated particles 1032 can have a variety of diameters that form a Gaussian distribution about a mean diameter. At times, it may be preferable to forward a first portion of the separated coated particles 1034, for example those having a diameter greater than a defined threshold, to the coated particle melter 1050. At such times, it may be preferable to recycle a second portion of the separated coated particles 1038, for example those having a diameter less than a defined threshold, back to the heated particulate bed 1004. The small diameter coated particles included in the second portion of the separated coated particles 1038 may function as seed particles for the deposition of additional layers of the second chemical species in the heated particulate bed. The crystal production method 1700 commences at 1702.

At 1704, the separated coated particles 1032 are classified, apportioned, sorted, separated or segregated into at least a first portion of separated coated particles 1034 and a second portion of separated coated particles 1038. Such separation or segregation may, at times, occur at least partially within the reactor, the conveyance 1030, or any combination thereof. The classification of the separated coated particles 1032 into the first portion of coated separated particles 1034 and the second portion of separated coated particles 1038 can occur in an environment having a low oxygen level or a very low oxygen level, thereby reducing or even eliminating the formation of an oxide layer or “shell” on the exposed surfaces of the separated coated particles 1032. At times, the classification of the separated coated particles 1032 is performed in a low oxygen level environment having an oxygen concentration of less than 20 volume percent (vol %). At other times, the classification of the separated coated particles 1032 is performed in a very low oxygen level environment having an oxygen concentration of less than about 1 mole % (mol %); less than about 0.5 mol %; less than about 0.3 mol %; less than about 0.1 mol %; less than about 0.01 mol %; or less than about 0.001 mol %.

At times, the second portion of separated coated particles1038 may contain coated particles having diameters too large for use as seed particulates in the heated particulate bed. At such times, some or all of the second portion of separated coated particles 1038 may be further divided into a first (i.e., large diameter) fraction of coated particles 1092 that are subsequently subjected to a size reduction process, for example using a coated particle grinder 1096 prior to recycle to the heated particulate bed, and a second (i.e., smaller diameter) fraction of coated particles 1094 that are recycled directly to the heated particulate bed. The crystal production method 1700 concludes at 1706.

FIG. 18 shows a high level block flow diagram of an illustrative crystal production method 1800 in which the first portion of separated coated particles 1034 is melted in the coated particle melter 1050 and one or more second chemical species crystals are formed using the melted second chemical species, according to an embodiment. The chemical vapor deposition of second chemical species on the particulates in the heated particulate bed creates a substantially pure layer of second chemical species on each of the separated coated particles 1032. The substantially oxygen and contaminant free separated particles 1032 made possible by handling the separated coated particles 1032 in an environment maintained at a low oxygen level or a very low oxygen level and a low contaminant level or very low contaminant level beneficially provides the ability to grow high purity second chemical species crystals in the crystal production device 1070. Advantageously, the high purity separated coated particles 1032 are amenable to use in many different crystal production devices or processes, including, but not limited to the Czochralski crystal production process, the Float Zone (“FZ”) crystal production process, and directional crystal solidification processes such as the Bridgman-Stockbarger production process. The crystal production method 1800 commences at 1802.

At 1804, the conveyance 1030 deposits in or otherwise transfers to the coated particle melter 1050 and/or the crystal production device 1070 at least a portion of the first portion of separated coated particles 1034. The conveyance 1030 is hermetically sealed to the coated particle melter 1050 and/or crystal production device 1070, thus the transfer of the first portion of coated particles 1038 is performed in an environment having a low oxygen level or a very low oxygen level. At times, the environment in the conveyance 1030 is maintained at a low oxygen level having an oxygen concentration of less than 20 volume percent (vol %). At other times the environment in the conveyance 1030 is maintained at a very low oxygen level having an oxygen concentration of less than about 1 mole % (mol %); less than about 0.5 mol %; less than about 0.3 mol %; less than about 0.1 mol %; less than about 0.01 mol %; or less than about 0.001 mol %. Handling the first portion of the separated coated particles 1034 in an environment maintained at a low oxygen level or a very low oxygen level beneficially reduces or eliminates the formation of an oxide layer on the external surfaces of the first portion of separated coated particles 1034.

In some implementations, the coated particle melter 1050 heats the first portion of separated coated particles 1034 above the melting temperature of the second chemical species. In such implementations, the melted coated particles form a reservoir of molten second chemical species 1060 in the coated particle melter 1050. In such implementations, the molten second chemical species 1060 may be maintained in a reduced free oxygen and a reduced contaminant environment in the coated particle melter 1050 to reduce the undesirable formation of oxides. At times, given the relatively high purity of the molten second chemical species 1060, one or more dopants may be added to the molten second chemical species 1060 in the coated particle melter 1050 and/or crystal production device 1070.

At 1806 the reservoir of molten second chemical species 1060 is used to produce or grow one or more second chemical species crystals 1072. At times, the one or more second chemical species crystals 1072 are substantially pure, crystalline second chemical species which may or may not contain one or more dopants dependent upon whether dopants were introduced to the molten second chemical species 1060. At times, the one or more second chemical species crystals 1072 are drawn, pulled, or otherwise formed from the reservoir molten second chemical species 1060 using any current or future crystal production process, for example the Czochralski process in which crystals are drawn from the molten second chemical species 1060. At other times, one or more second chemical species crystals 1072 may be formed using the first portion of the separated coated particles 1034 in one or more directional solidification crystallization processes such as the Bridgman-Stockbarger or Float Zone processes in which the molten second chemical species reservoir is cooled at a defined rate and in a defined directional pattern to create the crystalline second chemical species. The crystal production method 1800 concludes at 1808.

FIG. 19 shows a high level block flow diagram of an illustrative crystal production method 1900 in which at least a portion of the first gaseous chemical species added to the heated particulate bed spontaneously self nucleates, propagating the particulate bed, and reducing or even eliminating the need for seed particulate addition to the heated particulate bed, according to an embodiment. Typically, fluidized beds require the addition of seed particulates to replace particulates lost through production (i.e., removed from the bed as coated particles) and particulates that escape the bed (e.g., particulates that become entrained in a fluid passed through the bed).

A mechanically fluidized particulate bed advantageously offers significantly lower superficial gas velocities than a comparable hydraulically fluidized particulate bed because the gas (i.e., the first gaseous chemical species with or without diluent) in the mechanically fluidized particulate bed is not relied upon to fluidize the bed. Consequently, smaller diameter particulates are advantageously retained in the mechanically fluidized particulate bed and are able to serve as seed particles for the deposition of the second chemical species. In fact, process conditions in the mechanically fluidized particulate bed 20 may be adjusted to preferentially cause the spontaneous self-nucleation of at least a portion of the first gaseous chemical species introduced to the particulate bed, thereby reducing or even eliminating the need for seed particulate addition to the mechanically fluidized particulate bed. The crystal production method 1900 commences at 1902.

At 1904, one or more process conditions within a mechanically fluidized particulate bed 20 are adjusted, altered, or controlled to advantageously and preferentially cause the spontaneous self-nucleation second chemical species seed particulates using the first gaseous chemical species introduced to the mechanically fluidized particulate bed 20. Such process conditions may include the pressure and/or temperature maintained in the mechanically fluidized particulate bed 20. Such process conditions may include the oscillatory frequency and/or oscillatory displacement of the mechanically fluidized particulate bed 20. Such process conditions may include a ratio of the first gaseous chemical species to one or more diluents added to the mechanically fluidized particulate bed 20.

The spontaneous formation of self-nucleated seed particulates in the mechanically fluidized particulate bed 20 advantageously reduces or even eliminates the need for the external addition of seed particulates to the mechanically fluidized particulate bed 20. Eliminating the need for the external addition of seed particulates advantageously permits the operation of the mechanically fluidized particulate bed 20 in a closed, reduced free oxygen, environment. The ability to operate the fluidized bed in a closed environment advantageously makes possible the production of high purity coated particles and also makes possible the addition of one or more dopants to the mechanically fluidized particulate bed 20 to produce doped coated particles in the mechanically fluidized particulate bed 20—both of which offer significant advantages over conventional hydraulic fluidized bed production methods. The crystal production method 1900 concludes at 1906.

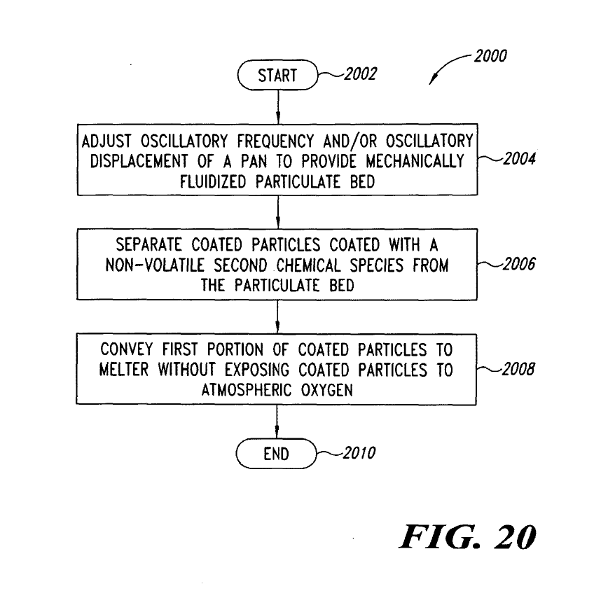

FIG. 20 shows a high level block flow diagram of an illustrative crystal production method 2000 in which a mechanically fluidized particulate bed 20 generates second chemical species coated particles which are separated from the mechanically fluidized particulate bed 20 and conveyed to a melter without exposing the coated particles to atmospheric oxygen, according to an embodiment. The crystal production method 2000 commences at 2002.

At 2004, an oscillatory frequency and/or an oscillatory displacement of a retention volume 317 containing a mechanically fluidized particulate bed 20 are adjusted to maintain the mechanically fluidized particulate bed 20 and also to separate coated particles 22 having one or more desirable or preferable physical and/or compositional characteristics from the mechanically fluidized particulate bed 20. For example, the oscillatory displacement of the retention volume 317 may be adjusted along a single component axis of motion (e.g., along a horizontal component axis of displacement or along a vertical component axis of displacement) or along two or more component axes of motion (e.g., along a horizontal component axis of displacement and along a vertical component axis of displacement). In another example the oscillatory frequency of the retainment volume 317 may be adjusted either upwards or downwards to achieve a desired coated particle separation.

At 2006, second chemical species coated particles 22 are separated from the mechanically fluidized particulate bed 20. At times, such separation may be achieved by overflowing at least a portion of the second chemical species coated particles 22 into one or more hollow coated particle overflow tubes 132, each having at least one respective inlet positioned in the retainment volume 317. At other times, such separation may be achieved by overflowing at least a portion of the second chemical species coated particles 22 over a perimeter wall or weir of the retainment volume (e.g., a peripheral wall or weir of a pan that forms at least a portion of the retainment volume 317). At times, the separated coated particles 1032 are collected in the conveyance 1030 for transport to the coated particle melter 1050. At other times, as depicted in FIG. 10B, a coated particle melter 1050 is hermetically sealed to the reactor 30 such that the coated particle melter 1050 directly receives the separated coated particles 1032.

At 2008, the conveyance 1030 moves or otherwise transports, in a reduced free oxygen environment, at least a first portion of the separated coated particles 1034 to the coated particle melter 1050. At times, the environment in the conveyance 1030 is maintained at a low oxygen level having an oxygen concentration of less than 20 volume percent (vol %). At other times the environment in the conveyance 1030 is maintained at a very low oxygen level having an oxygen concentration of less than about 1 mole % (mol %); less than about 0.5 mol %; less than about 0.3 mol %; less than about 0.1 mol %; less than about 0.01 mol %; or less than about 0.001 mol %. Handling the first portion of the separated coated particles 1034 in an environment maintained at a low oxygen level or a very low oxygen level beneficially reduces or eliminates the formation of an oxide layer on the external surfaces of the first portion of separated coated particles 1034. The crystal production method 2000 concludes at 2010.

The systems and processes disclosed and discussed herein for the production of silicon have marked advantages over systems and processes currently employed. The systems and processes are suitable for the production of either semiconductor grade or solar grade silicon. The use of high purity silane as the first chemical species in the production process allows a high purity silicon to be produced more readily. The system advantageously maintains the silane at a temperature below the 400° C. thermal decomposition temperature until the silane enters the mechanically fluidized particulate bed. By maintaining process and equipment surface temperatures outside of the mechanically fluidized particulate bed below the thermal decomposition temperature of silane, the overall conversion of silane to usable polysilicon deposited on the particles within the mechanically fluidized particulate bed is increased, and parasitic conversion losses and operational problems attributable to decomposition of silane and deposition of polysilicon on other surfaces within the reactor are minimized.

The mechanically fluidized bed systems and methods described herein greatly reduce or eliminate the formation of ultra-fine poly-powder (e.g., 0.1 micron in size) external to the mechanically fluidized particulate bed 20 since the temperature of the gas containing the first chemical species is maintained below the auto-decomposition temperature of the first chemical species until injected into the mechanically fluidized bed. Additionally, the temperature within the chamber 32 is also maintained below the thermal decomposition temperature of the first chemical species further reducing the likelihood of auto-decomposition. Silane also provides advantages over dichlorosilane, trichlorosilane, and tetrachlorosilane for use in making high purity polysilicon. Silane is much easier to purify and has fewer contaminants than dichlorosilane, trichlorosilane, or tetrachlorosilane. Because of the relatively low boiling point of silane, it can be readily purified which reduces the tendency to entrain contaminants during the purification process as occurs in the preparation and purification of dichlorosilane, trichlorosilane, or tetrachlorosilane. Further, certain processes for the production of trichlorosilane utilize carbon or graphite, which may carry along into the product or react with chlorosilanes to form carbon-containing compounds. Further, the silane-based decomposition process such as that described herein produces only a hydrogen by-product. The hydrogen byproduct may be directly recycled to the silane production process, reducing or eliminating the need for an off-gas treatment system. The elimination of off-gas treatment and the efficiencies of the mechanically fluidized bed process greatly reduce capital and operating cost to produce polysilicon. Savings of 40% in each are possible.

The above description of illustrated embodiments, including what is described in the Abstract, is not intended to be exhaustive or to limit the embodiments to the precise forms disclosed. Although specific embodiments and examples are described above for illustrative purposes, various equivalent modifications can be made without departing from the spirit and scope of the disclosure, as will be recognized by those skilled in the relevant art. The teachings provided above of the various embodiments can be applied to other systems, methods and/or processes for producing silicon, not only the exemplary systems, methods and devices generally described above.

For instance, the detailed description above has set forth various embodiments of the systems, processes, methods and/or devices via the use of block diagrams, schematics, flow charts and examples. Insofar as such block diagrams, schematics, flow charts and examples contain one or more functions and/or operations, it will be understood by those skilled in the art that each function and/or operation within such block diagrams, schematics, flowcharts or examples can be implemented, individually and/or collectively, by a wide range of system components, hardware, software, firmware, or virtually any combination thereof.

In certain embodiments, the systems used or devices produced may include fewer structures or components than in the particular embodiments described above. In other embodiments, the systems used or devices produced may include structures or components in addition to those described herein. In further embodiments, the systems used or devices produced may include structures or components that are arranged differently from those described herein. For example, in some embodiments, there may be additional heaters and/or mixers and/or separators in the system to provide effective control of temperature, pressure, or flow rate. Further, in implementation of procedures or methods described herein, there may be fewer operations, additional operations, or the operations may be performed in different order from those described herein. Removing, adding, or rearranging system or device components, or operational aspects of the processes or methods, would be well within the skill of one of ordinary skill in the relevant art in light of this disclosure.

The operation of methods and systems for making polysilicon described herein may be under the control of automated control systems. Such automated control systems may include one or more of appropriate sensors (e.g., flow sensors, pressure sensors, temperature sensors), actuators (e.g., motors, valves, solenoids, dampers), chemical analyzers and processor-based systems which execute instructions stored in processor-readable storage media to automatically control the various components and/or flow, pressure and/or temperature of materials based at least in part on data or information from the sensors, analyzers and/or user input.

Regarding control and operation of the systems and processes, or design of the systems and devices for making polysilicon, in certain embodiments the present subject matter may be implemented via Application Specific Integrated Circuits (ASICs). However, those skilled in the art will recognize that the embodiments disclosed herein, in whole or in part, can be equivalently implemented in standard integrated circuits, as one or more computer programs running on one or more computers (e.g., as one or more programs running on one or more computer systems), as one or more programs running on one or more controllers (e.g., microcontrollers) as one or more programs running on one or more processors (e.g., microprocessors), as firmware, or as virtually any combination thereof. Accordingly, designing the circuitry and/or writing the code for the software and or firmware would be well within the skill of one of ordinary skill in the art in light of this disclosure.

U.S. Provisional Patent Application No. 62/097,972, filed Dec. 30, 2014 is incorporated herein by reference in its entirety. The various embodiments described above can be combined to provide further embodiments. Aspects of the embodiments can be modified, if necessary to employ concepts of various patents, applications and publications to provide yet further embodiments.

These and other changes can be made to the embodiments in light of the above-detailed description. In general, in the following claims, the terms used should not be construed to limit the claims to the specific embodiments disclosed in the specification and the claims, but should be construed to include all possible embodiments along with the full scope of equivalents to which such claims are entitled. Accordingly, the claims are not limited by the disclosure.

1. A crystal production method, comprising:
selectively separating a plurality of coated particles from a heated particulate bed;
conveying, in an environment having a low oxygen level and a low contaminant level, at least a first portion of the plurality of coated particles separated from the heated particulate bed to a coated particle melter; and
prior to separating the plurality of coated particles from the heated particulate bed;
heating the particulate bed to at least a thermal decomposition temperature of a first gaseous chemical species; and
thermally decomposing the first gaseous chemical species in the heated particulate bed to provide the plurality of coated particles.

2-3. (canceled)

4. The crystal production method claim 1, further comprising:
conveying, in an environment having a low oxygen level, a second portion of the plurality of coated particles removed from the heated particulate bed back to the heated particulate bed.

5. The crystal production method of claim 4 wherein conveying, in an environment having a low oxygen level, a second portion of the plurality of coated particles removed from the heated particulate bed to the heated particulate bed comprises:
conveying, in an environment having a low oxygen level, the second portion of the plurality of coated particles removed from the heated particulate bed, the second portion of the plurality of coated particles including coated particles having a dp₅₀ less than or equal to 1000 micrometers (μm).

6. The crystal production method of claim 1 wherein conveying, in an environment having a low oxygen level, a first portion of the plurality of coated particles removed from the heated particulate bed to a melter comprises:
conveying, in an environment having a low oxygen level, the first portion of the plurality of coated particles removed from the mechanically fluidized particulate bed to a close coupled melter, the close coupled melter hermetically sealed to a vessel containing the heated particulate bed.

7. The crystal production method of claim 1 wherein conveying, in an environment having a low oxygen level, a first portion of the plurality of coated particles separated from the heated particulate bed to a coated particle melter comprises:
conveying the first portion of the plurality of coated particles separated from the mechanically fluidized particulate bed to the coated particle melter via at least one hermetically sealed intermediate vessel that includes an environment having a low oxygen level.

8-10. (canceled)

11. The crystal production method of claim 8 wherein thermally decomposing the first gaseous chemical species in the heated particulate bed to provide the plurality of coated particles comprises:
thermally decomposing the first gaseous chemical species in the heated particulate bed to provide a non-volatile second chemical species, at least a portion of which deposits on a surface of the particulates to provide the plurality of coated particles, the second chemical species including at least one of: germanium, compounds containing silicon and germanium, silicon, silicon nanoparticles, silicon carbide, silicon nitride, or aluminum oxide sapphire glass.

12. The crystal production method of claim 8 wherein heating the particulate bed to at least a thermal decomposition temperature of the first gaseous chemical species comprises:
disposing the particulate bed in a reaction vessel, the reaction vessel defining a chamber containing the heated particulate bed and an environment external to the heated particulate bed;
heating the particulate bed to at least the thermal decomposition temperature of the first gaseous chemical species via one or more heaters thermally coupled to the particulate bed; and
maintaining all points in the environment external to the particulate bed at a temperature below the thermal decomposition temperature of the first gaseous chemical species.

13. The crystal production method of claim 8, further comprising:
causing a temperature of the first portion of the plurality of coated particles separated from the particulate bed to exceed a melting temperature of the non-volatile second chemical species to form a reservoir of molten second chemical species;
growing at least one second chemical species crystal using at least a portion of the reservoir of molten second chemical species.

14. (canceled)

15. The crystal production method of claim 13 wherein growing at least one second chemical species crystal using at least a portion of the reservoir of molten second chemical species comprises:
growing at least one monocrystalline second chemical species via a crystal production device that is hermetically sealed to the coated particle melter and operably coupled to the reservoir of molten second chemical species.

16. The crystal production method of claim 8, further comprising:
causing a thermal decomposition and a spontaneous self-nucleation of at least a portion of the first gaseous chemical species in the heated particulate bed to generate a plurality of seed particulates to replace at least a portion of the plurality of coated particles removed from the heated particulate bed.

17. The crystal production method of claim 16 wherein causing a thermal decomposition and a spontaneous self-nucleation of at least a portion of the first gaseous chemical species in the heated particulate bed to generate a plurality of seed particulates comprises:
causing a thermal decomposition and a spontaneous self-nucleation of at least a portion of the first gaseous chemical species in the heated particulate bed to generate in situ a plurality of seed particulates having a diameter of less than 600 micrometers (μm).

18-21. (canceled)

22. The crystal production method of claim 1 wherein conveying a first portion of the plurality of coated particles separated from the heated particulate bed to a coated particle melter comprises:
conveying the first portion of the plurality of coated particles separated from the heated particulate bed to the coated particle melter, the first portion of the plurality of coated particles having less than 6000 parts per billion atomic oxygen as a metal oxide.

23. The crystal production method of claim 1 wherein conveying a first portion of the plurality of coated particles separated from the heated particulate bed to a coated particle melter comprises:
conveying the first portion of the plurality of coated particles separated from the heated particulate bed to the coated particle melter, the first portion of the plurality of coated particles having less than 600 parts per billion atomic oxygen as a metal oxide.

24. The crystal production method of claim 1, further comprising:
causing a flow of at least one dopant to the heated particulate bed to provide a plurality of doped coated particles.

25-26. (canceled)

27. The crystal production method of claim 1 wherein conveying a first portion of the plurality of coated particles separated from the heated particulate bed to a coated particle melter comprises:
collecting the plurality of separated coated particles in a coated particle collector maintained at a low oxygen level; and
conveying in a low oxygen environment and at a defined rate, a first portion of the plurality of coated particles separated from the coated particle collector to the coated particle melter.

28. (canceled)

29. A crystal production system, comprising:
a reactor housing that encloses at least one chamber;
a pan that includes a major horizontal surface having an upper surface and a lower surface that at least partially defines a retainment volume disposed in the at least one chamber;
a transmission that cyclically oscillates the pan at one or more defined frequencies and one or more defined displacements to produce a mechanically vibrated particulate bed in the retainment volume, the vibrated particulate bed including a plurality of coated particles, each of the plurality of coated particles including a non-volatile second chemical species deposited as a result of a thermal decomposition of a first gaseous chemical species in the mechanically vibrated particulate bed;
a hermetically sealed second chemical species crystal production device that, in operation, causes the temperature of a first portion of the plurality of coated particles separated from the mechanically vibrated particulate bed to exceed a melting temperature of the non-volatile second chemical species to form at least one second chemical species crystal; and
a hermetically sealed conveyance that couples the chamber to the second chemical species crystal production device such that, in operation, at least the first portion of the plurality of coated particles are conveyed from the mechanically vibrated particulate bed to the second chemical species crystal production device in an environment having a low oxygen level and a low contaminant level.

30. The crystal production system of claim 29, wherein the second chemical species crystal production device includes a coated particle melter that is operably coupled and hermetically sealed to the second chemical species crystal production device.

31. The crystal production system of claim 29 wherein the second chemical species crystal production device includes a Float Zone crystal production device.

32-33. (canceled)

34. The crystal production system of claim 29, further comprising:
a cover having an upper surface, a lower surface, and a peripheral edge, the cover disposed above the major horizontal surface of the pan with the peripheral edge of the cover spaced inwardly of a perimeter wall of the pan and a peripheral gap defined between the peripheral edge of the cover and the peripheral wall of the pan, the peripheral gap to, in operation, fluidly coupling the retainment volume to an exterior space about the pan; and
a coated particle overflow conduit sealingly coupled to and projecting from the major horizontal surface of the pan, the coated particle overflow conduit to collect via overflow at least a portion of the plurality of coated particles from the mechanically vibrated particulate bed, the coated particle overflow conduit having an inlet and a passage extending therethrough from the inlet to a distal portion of the coated particle overflow conduit, the inlet of the coated particle overflow conduit positioned in the retainment volume.

35. The crystal production system of claim 34, further comprising:
a plurality of baffles including at least one of: a plurality of baffles extending upward from the upper surface of the major horizontal surface at least partially into the retainment volume or extending downward from the lower surface of the cover at least partially into the retainment volume, each of the plurality of baffles disposed at least partially about the coated particle overflow conduit, spaced outwardly from the coated particle overflow conduit.

36. The crystal production system of claim 35, further comprising:
a plurality of baffles including a plurality of baffles having a first portion of baffles that extend upward from the upper surface of the major horizontal surface at least partially into the retainment volume alternated with a second portion of baffles that extend downward from the lower surface of the cover at least partially into the retainment volume, the plurality of baffles defining a radial serpentine flow path through the retainment volume.

37-70. (canceled)
